(19) United States
(12) Patent Application Publication
(10) Pub. No.: US 2015/0380681 A1
(43) Pub. Date: Dec. 31, 2015

(54) ORGANIC ELECTROLUMINESCENT ELEMENT AND LIGHTING DEVICE

(71) Applicant: KONICA MINOLTA, INC., Tokyo (JP)

(72) Inventors: Keiichi FURUKAWA, Hachioji-shi, Tokyo (JP); Tsukasa YAGI, Higashinada-ku, Kobe-shi, Hyogo (JP)

(21) Appl. No.: 14/763,048

(22) PCT Filed: Feb. 10, 2014
(86) PCT No.: PCT/JP2014/053028

§ 371 Date: Jul. 23, 2015

(30) Foreign Application Priority Data
Feb. 12, 2013 (JP) 2013-024641

(51) Int. Cl. H01L 51/52

(52) U.S. Cl. CPC H01L 51/5253; H01L 51/5268

(57) ABSTRACT

An object of the present invention is to provide an organic electroluminescent element, which has a light emitting efficiency improved by suppressing the deterioration of storage property under a high temperature-high humidity atmosphere due to the recess-projection state of a surface of a gas barrier layer or a light scattering layer, or the like that is in contact with a light emitting unit, and by suppressing the occurrence of a short-circuit. The organic electroluminescent elements 100 and 400 in the present invention are each characterized by including a film substrate 4, and at least, a gas barrier layer 5, a smooth layer 1, and a light emitting unit 3 that is sandwiched between a pair of electrodes 2, 6 and has an organic functional layer, which are stacked in this order on the film substrate, wherein the gas barrier layer 5 is constituted by at least two kinds of gas barrier layers 5 that are different from each other in the composition or distribution state of the constitutional elements.

### TECHNICAL FIELD

The present invention relates to an organic electroluminescent element. Furthermore, the present invention relates to a lighting device including said organic electroluminescent element. More specifically, the present invention relates to an organic electroluminescent element and a lighting device each having an improved light extraction efficiency.

### BACKGROUND ART

In recent years, in the field of electron devices, demands such as long term reliability, degree of freedom of forming and possibility of display on a curved surface have been added in addition to demands such as weight saving and increase in size, and thus film substrates such as transparent plastics are beginning to be adopted instead of glass substrates, which are heavy, easily cracked and difficult to be increased in surface area.

However, film substrates such as transparent plastics have problems that they have poorer gas barrier properties than those of glass substrates.

It has been clarified that, when a substrate having a poor gas barrier property is used, there is a problem that water vapor and oxygen permeate into the substrate and deteriorate the functions in an electron device, or the like.

Therefore, it is generally known that a film having a gas barrier property is formed on a film substrate and used as a gas barrier film. For example, as gas barrier films that are used for packaging materials for products that require a gas barrier property and for liquid crystal display elements, film substrates with silicon oxide deposited thereon and film substrates with aluminum oxide deposited thereon are known.

Furthermore, it is also known that a light extracting structure in which a light scattering layer is disposed is effective so as to improve the light emitting efficiency in a lighting device and a display device each having an organic electroluminescent element (for example, see Patent Literature 1).

However, there are problems that recess-projection is formed on the surface by forming a gas barrier layer and a light scattering layer on a film substrate, and that deterioration of the storage property under a high temperature-high humidity atmosphere and short-circuit (electrical short-circuit) easily occur by forming a light emitting unit having an organic functional layer on the upper layer thereof.

### CITATION LIST

### Patent Literature

Patent Literature 1: JP 2004-296437 A

### SUMMARY OF INVENTION

### Technical Problem

The present invention has been made in view of the above-mentioned problems and circumstances, and the problem to be solved by the invention is to provide an organic electroluminescent element that has a light emitting efficiency improved by suppressing the deterioration of storage property under a high temperature-high humidity atmosphere due to the recess-projection state of a surface of a gas barrier layer or a light scattering layer, or the like that is in contact with a light emitting unit and by suppressing the occurrence of a short-circuit, and a lighting device having the organic electroluminescent element.

### Solution to Problem

The present inventors have considered about the causes of the above-mentioned problems, and the like so as to solve the above-mentioned problems, and found that the problems of the present invention can be solved in the case when a film substrate, and at least, a gas barrier layer, a smooth layer, and a light emitting unit that is sandwiched between a pair of electrodes and has an organic functional layer are stacked in this order on the film substrate, and the gas barrier layer is constituted by at least two kinds of gas barrier layers that are different from each other in the composition or distribution state of the constitutional elements, and attains the present invention.

Specifically, the above-mentioned problem of the present invention is solved by the following means.

1. An organic electroluminescent element, including a film substrate, and at least, a gas barrier layer, a smooth layer, and a light emitting unit that is sandwiched between a pair of electrodes and has an organic functional layer, which are stacked in this order on the film substrate, wherein the gas barrier layer is constituted by at least two kinds of gas barrier layers that are different from each other in the composition or distribution state of the constitutional elements.

2. The organic electroluminescent element according to Item. 1, wherein the surface on the side of the light emitting unit of the smooth layer has an arithmetic average roughness Ra in the range of from 0.5 to 50 nm.

3. The organic electroluminescent element according to Item. 1 or 2, which has a light scattering layer between the gas barrier layer and the smooth layer.

4. The organic electroluminescent element according to any one of Items. 1 to 3, wherein the average refractive index of the smooth layer is 1.65 or more at the shortest light emitting local maximum wavelength among the light emitting local maximum wavelengths of the light emitted from the light emitting unit.

5. The organic electroluminescent element according to any one of Items. 1 to 4, wherein the smooth layer contains titanium dioxide.

6. The organic electroluminescent element according to any one of Items. 3 to 5, wherein the average refractive index of the light scattering layer is 1.6 or more at the shortest light emitting local maximum wavelength among the light emitting local maximum wavelengths of the light emitted from the light emitting unit.

7. The organic electroluminescent element according to any one of Items. 3 to 6, wherein the light scattering layer contains a binder that has a refractive index of 1.6 or less and inorganic particles that have a refractive index of 1.8 or more, at the shortest light emitting local maximum wavelength among the light emitting local maximum wavelengths of the light emitted from the light emitting unit.

8. The organic electroluminescent element according to any one of Items. 1 to 7, wherein one kind of gas barrier layer of the at least two kinds of gas barrier layers contains silicon dioxide that is a reaction product of an inorganic silicon compound.

9. The organic electroluminescent element according to any one of Items. 1 to 8, wherein either gas barrier layer of the at least two kinds of gas barrier layer contains a reaction product of an organic silicon compound.

10. A lighting device including the organic electroluminescent element according to any one of Items. 1 to 9.

### Advantageous Effects of Invention

By the above-mentioned means of the present invention, an organic electroluminescent element that has a light emitting efficiency improved by suppressing the deterioration of storage property under a high temperature-high humidity atmosphere due to the recess-projection state of a surface of a gas barrier layer or a light scattering layer, or the like that is in contact with a light emitting unit, and by suppressing the occurrence of a short-circuit, can be provided.

The mechanism of expression of the effect and the action mechanism of the present invention have not been clarified, but are conjectured as follows.

Specifically, in an organic electroluminescent element using a film substrate, a gas barrier layer having a high gas barrier property against water vapor or oxygen is essential, but the recess-projection of the surface formed by providing the gas barrier layer leads to defects such as short-circuit; therefore, the inventors have found that it is effective for suppressing defects such as short-circuit and improving light emitting efficiency to provide a smooth layer having a controlled surface roughness.

### BRIEF DESCRIPTION OF DRAWINGS

FIG. 1 is a cross-sectional view showing a schematic constitution of an organic electroluminescent element.

FIG. 2 is a schematic view showing an example of a device for producing a gas barrier film.

FIG. 3 is a schematic view of the setting of a position of a gas feeding inlet.

FIG. 4 is a graph showing the respective element profiles of the layers in the thickness direction by a composition analysis in the depth direction using XPS of the gas barrier layer according to the present invention.

FIG. 5 is a graph showing the respective element profiles of the layers in the thickness direction by a composition analysis in the depth direction using XPS of the gas barrier layer according to the present invention.

FIG. 6 is a graph showing the respective element profiles of the layers in the thickness direction by a composition analysis in the depth direction using XPS of a comparative gas barrier layer.

FIG. 7 is a cross-sectional view showing the schematic constitution of the light emitting panel made in Examples.

### DESCRIPTION OF EMBODIMENTS

The organic electroluminescent element of the present invention is characterized by being an organic electroluminescent element including a film substrate, and at least, a gas barrier layer, a smooth layer, and a light emitting unit that is sandwiched between a pair of electrodes and has an organic functional layer, which are stacked in this order on the film substrate, wherein the gas barrier layer is constituted by at least two kinds of gas barrier layers that are different from each other in the composition or distribution state of the constitutional elements. This characteristic is a technical characteristic that is common in claim 1 to claim 10.

As an embodiment of the present invention, it is preferable that the surface on the side of the light emitting unit of the smooth layer has an arithmetic average roughness Ra in the range of from 0.5 to 50 nm, in that the effect of the present invention can further be expressed. By this way, increase in a leak current and generation of a short-circuit defect due to generation of concentration of electric fields by the recess-projection against the light emitting unit formed on the upper part of the smooth layer can be prevented. Furthermore, the recess-projection of the electrodes can be decreased by making the respective films of the light emitting unit flat, whereby decrease in the efficiency due to the surface plasmon absorbance generated by the recess-projection can be prevented.

Furthermore, in the present invention, it is preferable to have a light scattering layer between the above-mentioned gas barrier layer and the above-mentioned smooth layer. By this way, the light emitted in the light emitting unit can be extracted efficiently.

Furthermore, in the present invention, it is preferable that the average refractive index of the above-mentioned smooth layer is 1.65 or more at the shortest light emitting local maximum wavelength among the light emitting local maximum wavelengths of the light emitted from the above-mentioned light emitting unit. It is considered that the average refractive index can be made close to the refractive index of the adjacent light emitting unit by this way, whereby a phenomenon that the light emitted from the light emitting unit is fully reflected at the interface and enclosed can be eliminated or decreased.

Furthermore, in the present invention, it is preferable that the above-mentioned smooth layer contains titanium dioxide. By using titanium dioxide having a high-refractive index, it is possible to increase the average refractive index of the entirety of the smooth layer. Furthermore, it is easy to adjust to a desired refractive index by adjusting the content of the titanium dioxide.

Furthermore, in the present invention, it is preferable that the average refractive index of the above-mentioned light scattering layer is 1.6 or more at the shortest light emitting local maximum wavelength among the light emitting local maximum wavelengths of the light emitted from the above-mentioned light emitting unit. By this way, it is possible to increase the average refractive index of the smooth layer and the average refractive index of the light scattering layer to the same degree, and thus it is possible to guide the light that has come from the light emitting unit via the smooth layer into the smooth layer with the minimum loss.

Furthermore, in the present invention, it is preferable that the above-mentioned light scattering layer contains a binder that has a refractive index of 1.6 or less and inorganic particles that have a refractive index of 1.8 or more, at the shortest light emitting local maximum wavelength among the light emitting local maximum wavelengths of the light emitted from the above-mentioned light emitting unit. By this way, it becomes easy to satisfy the conditions of the above-mentioned difference in the refractive indices and the average refractive index.

Furthermore, in the present invention, it is preferable that one kind of gas barrier layer from the above-mentioned at least two kinds of gas barrier layers contains silicon dioxide, which is a reaction product of an inorganic silicon compound. By this way, it is possible to effectively prevent the entering of moisture, which leads to the extension of the lifetime of the light emitting device.

Furthermore, in the present invention, it is preferable that either gas barrier layer of the above-mentioned at least two kinds of gas barrier layer contains a reaction product of an organic silicon compound. By this way, the entering of moisture can be prevented effectively, which leads to the extension of the lifetime of the light emitting device. Furthermore, the organic silicon compound has an effect of filling the defect parts of the above-mentioned inorganic-based gas barrier layer, which leads to more effective improvement of the lifetime in combination.

Hereinafter the present invention and the constitutional factors thereof, and the forms and aspects for carrying out the present invention will be explained in detail. In the present application, “to” is used to mean that the numerical values described before and after the term are encompassed as the lower limit value and upper limit value.

<Constitution of Organic EL Element>

The organic electroluminescent element (hereinafter also referred to as organic EL element) of the present invention is an organic EL element containing a film substrate, and at least, a gas barrier layer, a smooth layer, and a light emitting unit that is sandwiched between a pair of electrodes and has an organic functional layer, which are stacked in this order on the film substrate, wherein the gas barrier layer is constituted by at least two kinds of gas barrier layers that are different from each other in the composition or distribution state of the constitutional elements.

In the present application, “light emitting unit” refers to a light emitting body (unit) that is mainly constituted by at least organic functional layers such as a light emitting layer, a hole transport layer and an electron transport layer containing the respective organic compounds mentioned below. The light emitting body is sandwiched between a pair of electrodes including an anode and a cathode, and emits light by the re-bonding of holes (holes) that are fed from the anode and electrons fed from the cathode in the light emitting body.

The organic electroluminescent element of the present invention may have a plurality of light emitting units depending on the desired color of light emission.

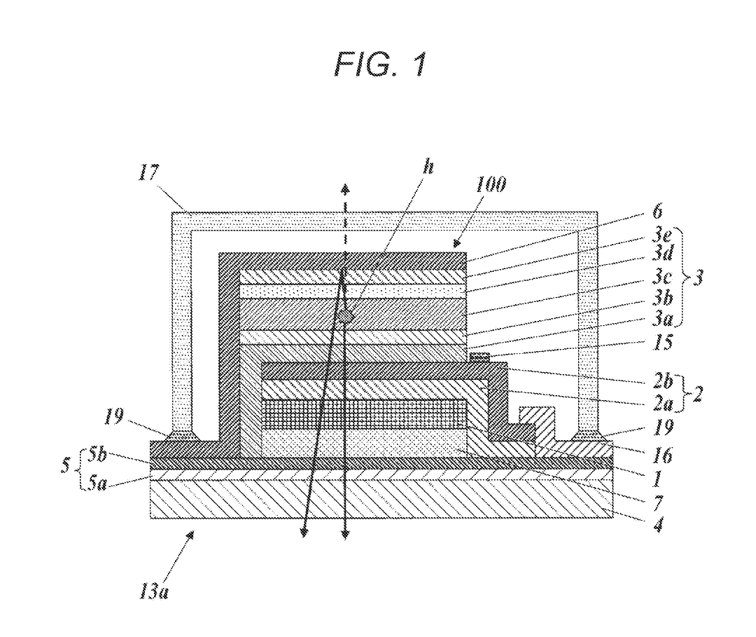

Specifically, as shown in FIG. 1, an organic EL element 100 in the present invention is disposed on a film substrate 4, and preferably has a gas barrier layer 5, a light scattering layer 7, a smooth layer 1, an anode (transparent electrode) 2, a light emitting unit 3 constituted by using an organic material and the like, and a cathode (counter electrode) 6 in this order from the side of the film substrate 4, and is stacked in this order in a preferable aspect. It is preferable that the light scattering layer 7 is disposed on the organic EL element of the present invention, but is not an essential constitutional factor. An extraction electrode 16 is disposed on the end part of the transparent electrode 2 (an electrode layer 2b). The transparent electrode 2 and an outer power source (not illustrated) are electrically connected through the extraction electrode 16. The organic EL element 100 is constituted so that the generated light (emitted light h) is extracted from at least the side of the film substrate 4.

Furthermore, the layer structure of the organic EL element 100 is not limited and may be a general layer structure. It is deemed herein that the transparent electrode 2 functions as an anode (i.e., an anode) and the counter electrode 6 functions as a cathode (i.e., a cathode). In this case, for example, as the light emitting unit 3, a constitution in which a hole injection layer 3a/a hole transport layer 3b/a light emitting layer 3c/an electron transport layer 3d/an electron injection layer 3e are stacked in this order from the side of the transparent electrode 2 as an anode is exemplified, and it is essential to have at least the light emitting layer 3c constituted by using an organic material among these layers. The hole injection layer 3a and hole transport layer 3b may also be disposed as a hole transport-injection layer. The electron transport layer 3d and electron injection layer 3e may also be disposed as an electron transport-injection layer. Furthermore, among these light emitting units 3, for example, the electron injection layer 3e may be constituted by an inorganic material.

Furthermore, a hole blocking layer, an electron blocking layer and the like may be stacked on necessary positions as necessary besides these layers in the light emitting unit 3. Furthermore, the light emitting layer 3c may have a structure having light emitting layers of respective colors that generate emitted lights in the respective wavelength areas, wherein these light emitting layers of respective colors are stacked via non-light emitting intermediate layers. The intermediate layers may function as hole blocking layers or electron blocking layers. Furthermore, the counter electrode 6, which is a cathode, may have a stacked structure as necessary. In such constitution, only the part where the light emitting unit 3 is sandwiched between the transparent electrode 2 and the counter electrode 6 becomes a light emitting area in the organic EL element 100.

Furthermore, in the layer constitution as mentioned above, an auxiliary electrode 15 may be disposed in contact with the electrode layer 2b of the transparent electrode 2 for the purpose of aiming at decreasing the resistance of the transparent electrode 2.

The organic EL element 100 having the constitution as mentioned above is sealed with a sealing material 17 mentioned below on the film substrate 4, for the purpose of preventing the deterioration of the light emitting unit 3, which is constituted by using an organic material and the like. This sealing material 17 is fixed on the side of the film substrate 4 through an adhesive 19. However, the terminal parts of the transparent electrode 2 (extraction electrode 16) and the counter electrode 6 are disposed in the state that they are exposed from the sealing material 17 in the state that the insulation property is retained from each other by the light emitting unit 3 on the film substrate 4.

The major factors for constituting the above-mentioned organic EL element 100 will be explained below in the order of the smooth layer, the light scattering layer, the gas barrier layer, the film substrate, the electrodes and the light emitting unit, and the production methods therefor will also be explained.

<Smooth Layer>

The major object of the smooth layer 1 in the present invention is that, in the case when the light emitting unit 3 is disposed on the gas barrier layer 5 or light scattering layer 7, harmful effects such as deterioration of the storage property under a high temperature-high humidity atmosphere, and an electric short-circuit (short-circuit), which are caused by the recess-projection of the surface of the gas barrier layer 5 or light scattering layer 7, are prevented.

It is important that the smooth layer 1 in the present invention has flatness for finely forming the transparent electrode 2 thereon, and the surface property is preferably such that the arithmetic average roughness Ra is within the range of from 0.5 to 50 nm. The arithmetic average roughness is further preferably 30 nm or less, specifically preferably 10 nm or less, and even more preferably 5 nm or less. By setting the arithmetic average roughness Ra to be within the range of from 0.5 to 50 nm, the defects such as a short-circuit of an organic EL element to be stacked can be suppressed. In addition, although the arithmetic average roughness Ra is preferably 0 nm, 0.5 nm is deemed as the lower limit value as the limit value at a practical level.

Furthermore, in the present application, the arithmetic average roughness Ra of the surface represents an arithmetic average roughness based on JIS B0601-2001.

In addition, the surface roughness (arithmetic average roughness Ra) was calculated from an average roughness relating to the amplitude of the fine recess-projection by using an AFM (Atomic Force Microscope: manufactured by Digital Instruments), from a cross-sectional surface curve of the recess-projection which was continuously measured by a detector with a stylet having a quite small tip radius, by measuring three times in an area with a measurement direction of 30 μm by the stylet having a quite small tip radius.

The light emitted from the light emitting unit 3 enters into the smooth layer 1. Therefore, it is preferable that the average refractive index of the smooth layer 1 has a value that is close to the refractive index of the organic functional layer included in the light emitting unit 3. Specifically, since an organic material having a high-refractive index is generally used in the light emitting unit 3, it is preferable that the smooth layer 1 is a high-refractive index layer having an average refractive index nf of 1.5 or more, specifically more than 1.65 and less than 2.5, at the shortest light emitting local maximum wavelength among the light emitting local maximum wavelengths of the light emitted from the light emitting unit. If the average refractive index nf is more than 1.65 and less than 2.5, the smooth layer may be formed of a single material, or may be formed of a mixture. In the case of such mixed system, a calculated refractive index that is calculated by a combined value obtained by multiplying the refractive indices that are inherent to the respective materials by a mixing ratio is used as the average refractive index nf of the smooth layer 1. Furthermore, in this case, the refractive index of each material may be 1.65 or less or 2.5 or more, and the mixed film may have an average refractive index nf of more than 1.65 and less than 2.5.

In the case when the smooth layer 1 is formed of a single material, the “average refractive index nf” herein is the refractive index of the single material, and in the case when the smooth layer 1 is a mixed system, the “average refractive index nf” is a calculated refractive index that is calculated by a combined value by multiplying the refractive indices that are inherent to the respective materials by the mixing ratio.

The refractive index is measured by irradiating with a ray at the shortest light emitting local maximum wavelength among the light emitting local maximum wavelengths of the light emitted from the light emitting unit under an atmosphere at 25° C. and using an Abbe refractive index meter (manufactured by ATAGO CO., LTD., DR-M2).

As the binder used for the smooth layer 1, known resins can be used without specific limitation, and examples include resin films of acrylic acid esters, methacrylic acid esters, polyethylene telephthalates (PET), polybutyrene telephthalates, polyethylene naphthalates (PEN), polycarbonates (PC), polyarylates, polyvinyl chlorides (PVC), polyethylenes (PE), polypropylenes (PP), polystyrenes (PS), nylons (Ny), aromatic polyamides, polyether ether ketones, polysulfones, polyethersulfones, polyimides, polyetherimides and the like, heat-resistant transparent films having a silsesquioxane having an organic-inorganic hybrid structure as an elemental backbone (product name: Sila-DEC, manufactured by Chisso Corporation), perfluoroalkyl group-containing silane compounds (for example, (heptadecafluoro-1,1,2,2-tetradecyl)triethoxysilane), and fluorine-containing copolymers containing a fluorine-containing monomer and a monomer for imparting a crosslinkable group as constitutional units, and the like. These resins can be used by mixing two or more kinds. Among these, those having an organic-inorganic hybrid structure are preferable.

Furthermore, it is also possible to use the following hydrophilic resin. Examples of the hydrophilic resin include water-soluble resins, water-dispersible resins, colloid dispersion resins or mixtures thereof. Examples of the hydrophilic resins include resins such as acrylic-based, polyester-based, polyamide-based, polyurethane-based and fluorine-based resins, and for example, a polymer such as polyvinyl alcohol, gelatin, polyethylene oxide, polyvinyl pyrrolidone, casein, starch, agar, carrageenan, polyacrylic acid, polymethacrylic acid, polyacrylamide, polymethacrylamide, polystyrene sulfonic acid, cellulose, hydroxylethyl cellulose, carboxymethyl cellulose, hydroxylethyl cellulose, dextran, dextrin, pullulan and water-soluble polyvinyl butyral can be exemplified, and among these, polyvinyl alcohol is preferable.

The polymers used as the binder resin may be used singly, or may be used by mixing two or more kinds as necessary.

Furthermore, similarly, conventionally-known resin particles (emulsions) and the like can also be preferably used as binders.

Furthermore, as the binder, resins that are cured by mainly an ultraviolet/electron ray, specifically, an ionization radiation curable resin mixed with a thermoplastic resin and a solvent, and a thermosetting resin, can also be preferably used.

Such binder resin is preferably a polymer having a saturated hydrocarbon or a polyether as a main chain, more preferably a polymer having a saturated hydrocarbon as a main chain.

Furthermore, it is preferable that the binder is crosslinked. The polymer having a saturated hydrocarbon as a main chain is preferably obtained by a polymerization reaction of an ethylenically unsaturated monomer. In order to obtain a crosslinked binder, it is preferable to use a monomer having two or more ethylenically unsaturated groups.

The microparticular sol contained in the binder contained in the smooth layer 1 can be also preferably used.

Furthermore, the lower limit of the diameter of the particles dispersed in the binder contained in the high-refractive index smooth layer 1 is generally preferably 5 nm or more, more preferably 10 nm or more, and further preferably 15 nm or more. Furthermore, the upper limit of the diameter of the particles dispersed in the binder is preferably 70 nm or less, more preferably 60 nm or less, and further preferably 50 nm or less. That the diameter of the particles dispersed in the binder is within the range of from 5 to 60 nm is preferable since high transparency can be obtained. The distribution of the particle diameters is not limited as long as the effect of the present invention is not deteriorated, and may be either broad or narrow, or may have a plurality of distributions.

As the particles to be contained in the smooth layer 1 in the present invention, TiO₂ (titanium dioxide sol) is more preferable from the viewpoint of stability. Furthermore, among TiO₂, a rutile type is more specifically preferable than an anatase type since the rutile type has a low catalyst activity, and thus the weather resistance of the smooth layer 1 and the adjacent layers become high, and the refractive index is high.

As the method for preparing a titanium dioxide sol which can be used in the present invention, for example, JP 63-17221 A, JP 7-819 A, JP 9-165218 A, JP 11-43327 A and the like can be referred to.

The thickness of the smooth layer 1 needs to be thick to the some extent so as to alleviate the surface roughness of the light scattering layer, but needs to be thin to the extent that energy loss due to absorption does not occur. Specifically, the thickness is preferably in the range of from 0.1 to 5 μm, further preferably in the range of from 0.5 to 2 μm.

<Light Scattering Layer>

It is preferable that the organic EL element 100 of the present invention has a light scattering layer 7. The average refractive index ns of the light scattering layer is preferably such that the refractive index is close to those of the organic functional layer and smooth layer 1 since the emitted light on the organic functional layer of the light emitting unit 3 enters through the smooth layer 1. It is preferable that the light scattering layer 7 is a high-refractive index layer that has an average refractive index ns within the range of 1.5 or more, specifically 1.6 or more and less than 2.5, at the shortest light emitting local maximum wavelength among the light emitting local maximum wavelengths of the light emitted from the light emitting unit 3. In this case, the light scattering layer 7 may be such that a film is formed from a single material having an average refractive index ns of 1.6 or more and less than 2.5, or a film having an average refractive index ns of 1.6 or more and less than 2.5 may be formed by mixing with two or more kinds of compounds. In the case of such mixed system, as the average refractive index ns of the light scattering layer 7, a calculated refractive index that is calculated by a combined value that is obtained by multiplying the refractive indices that are inherent to the respective materials with a mixing ratio is used. Furthermore, in this case, the refractive index of each material may be less than 1.6 or 2.5 or more, or it is sufficient that the average refractive index ns of the mixed film satisfies 1.6 or more and less than 2.5.

In the case when the light scattering layer 7 is formed of a single material, “average refractive index ns” herein is the refractive index of the single material, and in the case when the light scattering layer 7 is a mixed system, “average refractive index ns” is a calculated refractive index that is calculated by a combined value by multiplying the refractive indices that are inherent to the respective materials by a mixing ratio.

Furthermore, the light scattering layer 7 is preferably a light scattering film that utilizes a refractive index difference by a mixture of a binder having a low-refractive index, which is a layer medium, and particles having a high-refractive index contained in the layer medium.

The light scattering layer 7 is a layer for improving a light extraction efficiency, and is preferably formed on the outermost surface at the side of the transparent electrode 2 of the gas barrier layer 5 on the film substrate 4.

In the binder having a low-refractive index, the refractive index nb is less than 1.9, specifically preferably less than 1.6.

In the case when the binder is formed of a single material, the “refractive index nb of the binder” herein is the refractive index of the single material, and in the case when the binder is a mixed system, the “refractive index nb of the binder” is a calculated refractive index that is calculated by a combined value by multiplying the refractive indices that are inherent to the respective materials by the mixing ratio.

Furthermore, the refractive index np of the particles having a high-refractive index is 1.5 or more, preferably 1.8 or more, specifically preferably 2.0 or more.

In the case when the binder is formed of a single material, the “refractive index np of the particles” herein is the refractive index of the single material, and in the case when the binder is a mixed system, the “refractive index np of the particles” is a calculated refractive index that is calculated by a combined value by multiplying the refractive indices that are inherent to the respective materials by the mixing ratio.

Furthermore, the roles of the particles having a high-refractive index in the light scattering layer 7 include a function to scatter a waveguide light, and it is necessary to improve the scattering property for this purpose. In order to improve the scattering property, it is considered that the difference in the refractive indices of the particles having a high-refractive index and the binder is increased, the layer thickness is increased, and the particle density is increased. Among these, the property in which the trade-off with other performances is the minimum is to increase the difference in the refractive indices of the inorganic particles and the binder.

The refractive index difference |nb−np| between the resin material (binder), which is a layer medium, and the particles having a high-refractive index contained therein is preferably 0.2 or more, specifically preferably 0.3 or more. When the refractive index difference |nb−np| between the layer medium and the particles is 0.03 or more, a scattering effect generates at the interface of the layer medium and the particles. A larger difference in refractive indices |nb−np| is more preferable since the refraction at the interface becomes higher and the scattering effect is improved more.

Specifically, a high-refractive index layer such that the average refractive index ns of the light scattering layer 7 is within the range of 1.6 or more and less than 2.5 is preferable, and thus, for example, it is preferable that the refractive index nb of the binder is less than 1.6, and the refractive index np of the particles having a high-refractive index is more than 1.8.

Meanwhile, the refractive index is measured, in a similar manner to that for the smooth layer, by irradiating with a ray at the shortest light emitting local maximum wavelength among the light emitting local maximum wavelengths of the lights emitted from the light emitting unit under an atmosphere at 25° C. and using an Abbe refractive index meter (manufactured by ATAGO CO., LTD., DR-M2).

As mentioned above, the light scattering layer 7 is a layer that diffuses light by the difference in the refractive indices of the layer medium and particles. Therefore, the particles to be contained are required to scatter the light emitted from the light emitting unit 3 without adversely affecting the other layers.

The scatter as used herein represents a state in which a single film of the light scattering layer shows a haze value (a ratio of a scatter transmittance against a total ray transmittance) of 20% or more, more preferably 25% or more, specifically preferably 30% or more. If the haze value is 20% or more, the light emitting efficiency can be improved.

The haze value is a physical property value that is calculated by undergoing (a) an effect due to the refractive index difference of the compositions in the film, and (b) an effect due to a surface shape. Namely, by measuring the haze value with suppressing the surface roughness to be less than a predetermined extent, a haze value from which the effect by the above-mentioned (b) has been excluded is measured. Specifically, the haze value can be measured by using a haze meter (manufactured by Nippon Denshoku Industries Co., Ltd., NDH-5000) or the like.

For example, the scattering property can be improved by adjusting the particle diameter, whereby defects such as short-circuit can be suppressed. Specifically, transparent particles having a particle diameter that is equal to or more than a region at which Mie scatter in the visible light region is caused are preferable. Furthermore, the average particle diameter thereof is preferably 0.2 μm or more.

On the other hand, in the case when the particle diameter is larger, it is also necessary to increase the layer thickness of the smooth layer 1 that planarizes the roughness of the light scattering layer 7 containing particles, and this is not advantageous from the viewpoints of the loading of the steps and the absorbance of the film; therefore, the upper limit of the average particle diameter is preferably less than 10 μm, more preferably less than 5 μm, specifically preferably less than 3 μm, and the most preferably less than 1 μm.

Furthermore, in the case when plural kinds of particles are used in the light scattering layer 7, it is preferable that the average particle diameter contains at least one kind of particles within the range of from 100 nm to 3 μm, and does not contain particles of 3 μm or more, and it is specifically preferable to contain at least one kind of particles within the range of from 200 nm to 1 μm, and does not contain particles of 1 μm or more.

Here, the average particle diameter of the high-refractive index particles can be measured by an device utilizing a dynamic light scattering process such as Nanotrack UPA-EX150 manufactured by Nikkiso Co., Ltd., and image processing of an electromicroscopic photograph.

Such particles are not specifically limited and can be suitably selected according to the purpose, and may be either organic microparticles or inorganic microparticles, and inorganic microparticles having a high-refractive index are especially preferable.

As the organic microparticles having a high-refractive index, for example, polymethyl methacrylate beads, acrylic-styrene copolymer beads, melamine beads, polycarbonate beads, styrene beads, crosslinked polystyrene beads, polyvinyl chloride beads, benzoguanamine-melamine formaldehyde beads and the like are exemplified.

As the inorganic microparticles having a high-refractive index, for example, inorganic oxide particles formed of at least one oxide selected from zirconium, titanium, aluminum, indium, zinc, tin, antimony and the like are exemplified. The inorganic oxide particles specifically include ZrO₂, TiO₂, BaTiO₃, Al₂O₃, In₂O₃, ZnO, SnO₂, Sb₂O₃, ITO, SiO₂, ZrSiO₄, zeolite and the like, and among these, TiO₂, BaTiO₃, ZrO₂, ZnO and SnO₂ are preferable, and TiO₂ is the most preferable. Furthermore, among TiO₂, a rutile type is more preferable than an anatase type since the rutile type has a low catalyst activity, and thus the weather resistance of the high-refractive index layer and the adjacent layers become high, and the refractive index is high.

Furthermore, either of particles that have undergone a surface treatment or particles that have not undergone a surface treatment can be selected as these particles, from the viewpoint of improvement of the dispersibility and stability in the case when the particles are formed into the dispersion liquid mentioned below so as to be incorporated in the high-refractive index light scattering layer 7.

In the case when a surface treatment is conducted, examples of the specific materials for the surface treatment include heterogenous inorganic oxides such as silicon oxide and zirconium oxide, metal hydroxides such as aluminum hydroxide, organic acids such as organosiloxane and stearic acid, and the like. These surface treating materials may be used singly by one kind, or in combination of plural kinds. Among these, heterogenous inorganic oxides and/or metal hydroxides are preferable, and metal hydroxides are more preferable as the surface treating materials from the viewpoint of the stability of the dispersion liquid.

In the case when the inorganic oxide particles have undergone a surface coating treatment with a surface treating material, the coating amount thereof (generally, this coating amount is shown by the mass ratio of the surface treating material used on the surfaces of the particles with respect to the mass of the particles) is preferably 0.01 to 99% by mass. By setting the coating amount to be within this range, effects of improving dispersibility and stability by the surface treatment can be sufficiently obtained, and a light extraction efficiency can be improved by the high-refractive index of the light scattering layer 7.

Furthermore, as the material having a high-refractive index, the quantum dots described in WO 2009/014707 A and U.S. Pat. No. 6,608,439 A and the like can also be preferably used.

It is preferable that the above-mentioned particles having a high-refractive index are disposed at the thickness of one layer of the particles so that the particles are brought into contact with or put in the vicinity of the interface between the light scattering layer 7 and the smooth layer 1. By this way, evanescent light that exudes out of the light scattering layer 7 when total reflection occurs in the smooth layer 1 can be scattered by the particles, whereby the light extraction efficiency is improved.

The content of the high-refractive index particles in the light scattering layer 7 is preferably within the range of from 1.0 to 70%, more preferably within the range of from 5 to 50% by a volume packing factor. By this way, coarseness and fineness of the refractive index distribution can be made at the interface between the light scattering layer 7 and the smooth layer 1, and thus the light extraction efficiency can be improved by increasing the amount of light scattering.

As the method for forming the light scattering layer 7, for example, in the case when the layer medium is a resin material, the formation is conducted by dispersing the above-mentioned particles in the resin material (polymer) solution as a medium (as the solvent, a solvent in which no particles are dissolved is used), and applying the dispersion onto a film substrate.

Since these particles are actually polydispersed particles and are difficult to be regularly disposed, these particles locally have a diffraction effect, but many of these change the direction of light by diffusion to thereby improve the light extraction efficiency.

Furthermore, as the binder that can be used in the light scattering layer 7, resins that are similar to those for the smooth layer 1 are exemplified.

Furthermore, in the light scattering layer 7, a compound that can forma metal oxide, a metal nitride or a metal oxide nitride by irradiation of an ultraviolet ray under a specific atmosphere is used specifically and preferably. As the compound that is suitable for the present invention, the compounds that can undergo a modification treatment at a relatively low temperature described in JP 8-112879 A is preferable.

Specifically, polysiloxanes having Si—O—Si bonds (including polysilsesquioxanes), polysilazanes having Si—N—Si bonds, polysiloxazanes containing both Si—O—Si bonds and Si—N—Si bonds, and the like can be exemplified. These can be used by mixing two or more kinds. Furthermore, these can also be used by sequentially stacking or simultaneously stacking different compounds.

The thickness of the light scattering layer 7 is required to be thick to the some extent so as to ensure a light path length for causing scattering, whereas the thickness is required to be thin to the extent that energy loss by absorption is not caused. Specifically, the thickness is preferably within the range of from 0.1 to 5 μm, further preferably within the range of from 0.2 to 2 μm.

(Polysiloxanes)

The polysiloxanes used in the light scattering layer 7 can contain [R₃SiO_{1/2}], [R₂SiO], [RSiO_{3/2}] and [SiO₂] as general structural units. Rs are each independently selected from the group consisting of a hydrogen atom, alkyl groups containing 1 to 20 carbon atoms (for example, methyl, ethyl, propyl and the like), aryl groups (for example, phenyl and the like) and unsaturated alkyl groups (for example, vinyl and the like). Examples of the specific polysiloxane groups include [PhSiO_{3/2}], [MeSiO_{3/2}], [HSiO_{3/2}], [MePhSiO], [Ph₂SiO], [PhViSiO], [ViSiO_{3/2}] (Vi represents a vinyl group), [MeHSiO], [MeViSiO], [Me₂SiO], [Me₃SiO_{1/2}] and the like. Furthermore, mixtures and copolymers of polysiloxanes can also be used.

(Polysilsesquioxanes)

In the light scattering layer 7, polysilsesquioxanes are preferably used among the above-mentioned polysiloxanes. The polysilsesquioxanes are compounds containing silsesquioxanes in the structural units. “Silsesquioxanes” are compounds represented by [RSiO_{3/2}], and are generally polysiloxanes that are synthesized by the hydrolysis-polycondensation of a RSiX₃-type compound (wherein R is a hydrogen atom, an alkyl group, an alkenyl group, an aryl group, an araalkyl group (also referred to as an aralkyl group) or the like, and X is a halogen, an alkoxy group or the like). As the forms of the molecular sequences of polysilsesquioxanes, an amorphous structure, a ladder-like structure, a basket-like structure, and partially cleaved structures thereof (a structure in which a basket-like structure lacks one silicon atom, and a structure in which a part of silicon-oxygen bonds in a basket-like structure have been cleaved), and the like are typically known.

Among these polysilsesquioxanes, it is preferable to use so-called hydrogen silsesquioxane polymers. The hydrogen silsesquioxane polymers include hydride siloxane polymers represented by HSi (OH)ₓ(OR)_{y}O_{z/2}. Each R is an organic group or a substituted organic group, and in the case when R binds to silicon by an oxygen atom, it forms a hydrolysable substituent. x=0 to 2, y=0 to 2, z=1 to 3, and x+y+z=3. Examples of R include alkyl groups (for example, methyl, ethyl, propyl, butyl and the like), aryl groups (for example, phenyl and the like) and alkenyl groups (for example, allyl, vinyl and the like). These resins can be wholly condensed (HSiO_{3/2})ₙ, or only partially hydrolyzed (i.e., a part of Si—ORs are contained) and/or partially condensed (i.e., a part of Si—OHs are contained).

(Polysilazanes)

The polysilazanes used in the light scattering layer 7 are polymers having silicon-nitrogen bonds, and are inorganic precursor polymers such as intermediate solid-solutions SiOₓN_{y} (x: 0.1 to 1.9, y: 0.1 to 1.3) of SiO₂, Si₃N₄ and both, which are formed of Si—N, Si—H, N—H and the like.

The polysilazanes that are preferably used for the light scattering layer 7 are represented by the following general formula (A).

The “polysilazanes” in the present invention are polymers having silicon-nitrogen bonds in the structure and are polymers that become precursors of silicon nitrate, and those having the structure of the following general formula (A) are preferably used.

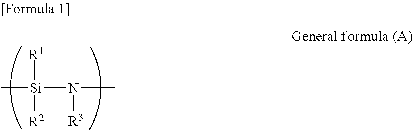

In the formula, R¹, R² and R³ each represents a hydrogen atom, an alkyl group, an alkenyl group, a cycloalkyl group, an aryl group, an alkylsilyl group, an alkylamino group or an alkoxy group.

In the present invention, perhydropolysilazane in which R¹, R² and R³ are all hydrogen atoms is specifically preferable from the viewpoint of the denseness as a film of the obtained light scattering layer.

The perhydropolysilazane is assumed to have a structure in which straight chain structures and ring structures mainly having a six-membered ring and an eight-membered ring are present, and has a molecular weight of about 600 to 2,000 by a number average molecular weight (Mn) (polystyrene conversion by gel permeation chromatography) and is a liquid or solid substance.

Polysilazanes are commercially available in a state of a solution dissolved in an organic solvent, and commercially available products can be directly used as polysilazane-containing application liquids. Examples of the commercially available products of polysilazane solutions include NN120-20, NAX120-20 and NL120-20 manufactured by AZ Electronic Materials, and the like.

As the binder, an ionization radiation curable resin composition can be used, and as a method for curing the ionization radiation curable resin composition, the curing can be carried out by a general method for curing an ionization radiation curable resin composition, i.e., irradiation of an electron beam of a ultraviolet ray.

For example, in the case of curing by an electron ray, an electron beam having an energy of 10 to 1,000 keV, preferably 30 to 300 keV released from various electron beam accelerators of a Cockcroft-Walton type, a Van de Graaff type, a resonant transformer type, an insulating core transformer type, a linear type, a dynamitron type and a high frequency type, and the like are used, and in the case of curing with a ultraviolet ray, a ultraviolet ray emitted from a ray from a ultra high pressure mercury lamp, a high pressure mercury lamp, a low pressure mercury lamp, carbon arc, xenon arc or a metal halide lamp, or the like can be utilized.

(Vacuum Ultraviolet Ray Irradiation Device Having Excimer Lamp)

As a preferable ultraviolet irradiation device in the present invention, a rare gas excimer lamp that emits a vacuum ultraviolet ray within the range of from 100 to 230 nm is specifically exemplified.

Since atoms of rare gases such as Xe, Kr, Ar and Ne do not make molecules by chemical bonding, they are referred to as inert gases. However, atoms that have obtained energy by discharging or the like (excited atoms) of a rare gas can make molecules by binding with other atoms.

For example, in the case when the rare gas is Xe (xenon), as shown in the following reaction formulas, excimer light of 172 nm is emitted when Xe₂*, which is an excited excimer molecule, transits to a ground state.

e+Xe→Xe*

Xe*+2Xe→Xe₂*+Xe

Xe₂*→Xe+Xe+hν (172 nm)

The characteristics of the excimer lamp include that the excimer lamp has a high efficiency since radiations are concentrated in one wavelength, and lights other than the necessary lights are radiated little. Furthermore, since excess lights are not radiated, the temperature of an object can be kept relatively low. In addition, a long time is not necessary for starting and restarting, instant lighting and blinking are possible.

As a light source that efficiently irradiates an excimer light, a dielectric barrier discharge lamp is exemplified.

The constitution of the dielectric barrier discharge lamp is such that discharging is caused between electrodes through a dielectric, and generally, it is sufficient that at least one of electrodes is disposed on a discharging container formed of a dielectric and the outside thereof. As the dielectric barrier discharge lamp, for example, a dielectric barrier discharge lamp including a double-cylindrical discharging container formed of a thick tube and a thin tube constituted by quartz glass, and a rare gas such as xenon enclosed therein, a first net-shaped electrode disposed on the outer part of the discharging container, and another electrode disposed on the inside of the inner tube is exemplified. The dielectric barrier discharge lamp generates dielectric barrier discharging inside of the discharging container by applying a high frequency voltage or the like to between the electrodes, and generates an excimer light during the disassociation of excimer molecules such as xenon which have been generated by the discharging.

Since the light generation efficiency is high in the excimer lamp, it is possible to light by injecting a low electrical power. Furthermore, since the excimer lamp does not emit a light having a long wavelength, which cause temperature rising, but irradiates an energy at a single wavelength in the ultraviolet region, the excimer lamp has a characteristic that it can suppress the temperature rising of an object to be irradiated by the irradiated light itself.

Meanwhile, in order to further incorporate the light that has been taken into the smooth layer 1 into the light scattering layer 7, it is preferable that the difference in the refractive indices of the binders of the light scattering layer 7 and of the smooth layer 1 is small. Specifically, it is preferable that the difference in the refractive indices of the binders of the light scattering layer 7 and of the smooth layer 1 is 0.1 or less. Furthermore, it is preferable to use the same material for the binder contained in the smooth layer 1 and for the binder contained in the light scattering layer 7.

Furthermore, by adjusting the layer thickness when the light scattering layer 7 is added to the smooth layer 1, wiring defects due to bumps of edges in the cases of entering of moisture and patterning are suppressed, whereby the scattering property can be improved. Specifically, the layer thickness when the light scattering layer 7 is added to the smooth layer 1 is preferably within the range of from 100 nm to 5 μm, specifically preferably within the range of from 300 nm to 2 μm.

<Gas Barrier Layer>

The gas barrier layer in the present invention is characterized by being constituted by at least two kinds of gas barrier layers that are different from each other in the composition or distribution state of the constitutional elements. By providing such constitution, permeation of oxygen and water vapor can be efficiently prevented.

The gas barrier layers are preferably barrier property films (barrier films or the like) each having a water vapor permeation degree measured based on the method of JIS K 7129-1992 (25±0.5° C., relative humidity 90±2% RH) of 0.01 g/m²·24 h or less. Furthermore, the gas barrier layers are preferably high barrier property films each having an oxygen permeation degree measured based on the method of JIS K 7126-1987 of 1×10⁻³ ml/m²·24 h·atm or less, and a water vapor permeation degree of 1×10⁻⁵ g/m²·24 h or less.

As an embodiment of the present invention, it is preferable that one kind of gas barrier layer from the above-mentioned at least two kinds of gas barrier layers contains silicon dioxide, which is a reaction product of an inorganic silicon compound.

Furthermore, it is preferable that either gas barrier layer of the above-mentioned at least two kinds of gas barrier layer contains a reaction product of an organic silicon compound. Specifically, it is preferable that at least one kind of gas barrier layer contains elements derived from an organic silicon compound such as oxygen, silicon and carbon as constitutional elements.

In addition, the compositions or distribution states of the elements constituting the gas barrier layers in the gas barrier layers may be homogeneous or different in the thickness direction. As the method for making the compositions or distribution states of the constitutional elements different, it is preferable to use different methods for forming the gas barrier layers or different formation materials, as mentioned below.

Hereinafter an example of the gas barrier layer in the present invention will be explained, and among the at least two kinds of gas barrier layers constituting the gas barrier layer, one kind will be referred to as a first gas barrier layer, and the other kind will be referred to as a second gas barrier layer.

<<First Gas Barrier Layer>>

The constitutional elements of the first gas barrier layer in the present invention may be any ones as long as they contain at least elements that constitute a compound that prevents the permeation of oxygen and water vapor and are different from the constitutional elements of the second gas barrier layer mentioned below.

For example, a first gas barrier layer 5a can be provided as a layer containing silicon, oxygen and carbon as constitutional elements on one surface of a film substrate. In this case, an aspect in which all of the following requirements (i) to (iv) are satisfied in distribution curves of the respective constitutional elements based on the measurement of the element distributions in the depth direction by an X-ray photoelectron spectroscopy about the first gas barrier layer 5a is preferable from the viewpoint of improvement of the gas barrier property.

(i) The silicon atomic ratio, oxygen atomic ratio and carbon atomic ratio have the following magnitude relationship from the surface to the area at a distance of 90% or more in the layer thickness direction of the above-mentioned first gas barrier layer 5a.

(Carbon atomic ratio)<(silicon atomic ratio)<(oxygen atomic ratio)

(ii) The carbon distribution curve has at least two extremal values.

(iii) The absolute value of the difference between the maximum value and minimum value of the carbon atomic ratio in the carbon distribution curve is 5 at % or more.

(iv) In the oxygen distribution curve, the local maximum value of the oxygen distribution curve that is the closest to the surface of the first gas barrier layer 5a at the side of the film substrate is the maximum value among the local maximum values of the oxygen distribution curve in the gas barrier layer 5.

The first gas barrier layer 5a in the present invention is preferably a thin film layer formed on a film substrate having a band-like flexibility, by a plasma chemical vapor phase growth process in which the film substrate is transported to between a pair of film formation rollers in contact with the film formation rollers by using the film substrate, and plasma discharging is conducted while a film formation gas is fed to between the pair of film formation rollers.

The above-mentioned extremal values in the present invention refers to the local maximum value or local minimum value of the atomic ratio of each element with respect to the distance from the surface of the first gas barrier layer 5a in the layer thickness direction of the first gas barrier layer 5a.

<Definitions of Local Maximum Value and Local Minimum Value>

In the present invention, the local maximum value refers to a point where the value of the atomic ratio of the element changes from increasing to decreasing in the case when the distance from the surface of the first gas barrier layer 5a is changed, and where the value of the atomic ratio of the element of the position where the distance from the surface of the first gas barrier layer 5a in the layer thickness direction of the first gas barrier layer 5a from the above-mentioned point is further changed by 20 nm from the value of the atomic ratio of the element of the above-mentioned point decreases by 3 at % or more.

Furthermore, in the present invention, the local minimum value is a point where the value of the atomic ratio of the element changes from decreasing to increasing in the case when the distance from the surface of the first gas barrier layer 5a is changed, and where the value of the atomic ratio of the element of the position where the distance from the surface of the first gas barrier layer 5a in the layer thickness direction of the first gas barrier layer 5a from the above-mentioned point is further changed by 20 nm from the value of the atomic ratio of the element of the above-mentioned point increases by 3 at % or more.

<Average Value of Carbon Atomic Ratio, and Relationship of Maximum Value and Minimum Value>

It is preferable from the viewpoint of flexibility that the carbon atomic ratio in the first gas barrier layer 5a in the present invention is within the range of from 8 to 20 at % as an average value of the entirety of the layers. More preferably, the carbon atomic ratio is within the range of from 10 to 20 at %. By adjusting to be within this range, the first gas barrier layer 5a that sufficiently satisfies the gas barrier property and flexibility can be formed.

Furthermore, such first gas barrier layer 5a is further preferably such that the absolute value of the difference between the maximum value and minimum value of the carbon atomic ratio in the above-mentioned carbon distribution curve is 5 at % or more. Furthermore, in such the first gas barrier layer 5a, the absolute value of the difference between the maximum value and minimum value of the carbon atomic ratio is more preferably 6 at % or more, specifically preferably 7 at % or more. When the above-mentioned absolute value is 5 at % or more, the gas barrier property in the case when the obtained first gas barrier layer 5a is bent becomes sufficient.

<Positions of Extremal Values of Oxygen Atomic Ratio and Relationship of Maximum Value and Minimum Value>

In the present invention, as mentioned above, from the viewpoint of prevention of the entering of water molecules from the side of the film substrate, it is preferable that, in the oxygen distribution curve of the first gas barrier layer 5a, the local maximum value of the oxygen distribution curve that is the closest to the surface of the first gas barrier layer 5a at the side of the film substrate is the maximum value among the local maximum values of the oxygen distribution curve in the gas barrier layer 5a.

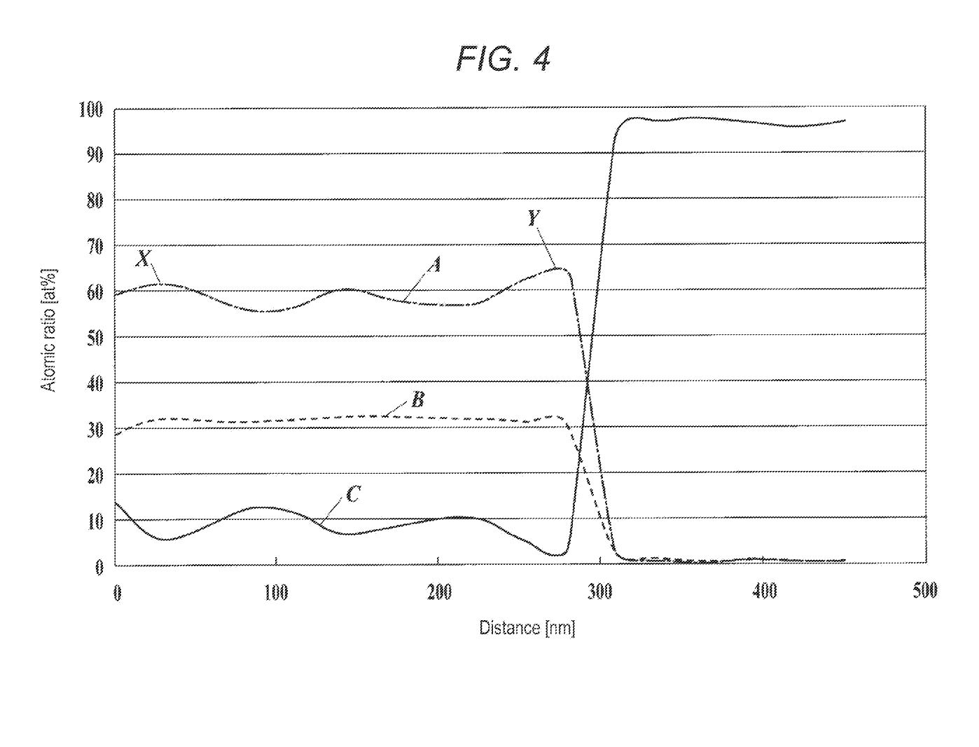

FIG. 4 is a graph showing the respective element profiles of the layers in the thickness direction by a XPS depth profile (distribution in the depth direction) of the first gas barrier layer 5a in the present invention.

In FIG. 4, the oxygen distribution curve is represented as A, the silicon distribution curve is represented as B, and the carbon distribution curve is represented as C.

The atomic ratio of each element continuously changes from the surface of the first gas barrier layer 5a (distance: 0 nm) to the surface of the film substrate 4 (distance: about 300 nm), and when the local maximum value of the oxygen atomic ratio which is the closest to the surface of the first gas barrier layer 5a of the oxygen distribution curve A is set as X, and the local maximum value of the oxygen atomic ratio which is the closest to the surface of the film substrate 4 is set as Y, it is preferable that the value of the oxygen atomic ratio is Y>X from the viewpoint of prevention of the entering of water molecules from the side of the film substrate 4.

The oxygen atomic ratio in the present invention is preferably such that the oxygen atomic ratio Y, which is the local maximum value of the oxygen distribution curve which is the closest to the surface of the first gas barrier layer 5a at the side of the above-mentioned film substrate 4, is 1.05 times or more of the oxygen atomic ratio X, which is the local maximum value of the above-mentioned oxygen distribution curve which is closest to the surface of the gas barrier layer which is opposite to the film substrate 4 across the gas barrier layer. In other words, it is preferable that 1.05≦Y/X.

Although the upper limit is not specifically limited, Y/X is preferably within the range of 1.05≦Y/X≦1.30, more preferably within the range of 1.05≦Y/X≦1.20. In this range, the entering of water molecules can be prevented, no deterioration of the gas barrier property under a high temperature and a high humidity is seen, and the range is preferable also from the viewpoints of producibility and cost.

Furthermore, in the above-mentioned oxygen distribution curve of the first gas barrier layer 5a, the absolute value of the maximum value and minimum value of the oxygen atomic ratio is preferably 5 at % or more, more preferably 6 at % or more, and specifically preferably 7 at % or more.

<Relationship of Maximum Value and Minimum Value of Silicon Atomic Ratio>

In the present invention, the absolute value of the maximum value and minimum value of the silicon atomic ratio in the silicon distribution curve of the above-mentioned first gas barrier layer 5a is preferably less than 5 at %, more preferably less than 4 at %, specifically preferably less than 3 at %. If the above-mentioned absolute value is within the above-mentioned range, the gas barrier property of the obtained first gas barrier layer 5a and the mechanical strength of the gas barrier layer become sufficient.

<Regarding Composition Analysis of Gas Barrier Layer in Depth Direction by XPS>

The carbon distribution curve, oxygen distribution curve and silicon distribution curve in the layer thickness (depth) direction of the gas barrier layer 5 can be prepared by measuring a so-called XPS depth profile (distribution in depth direction), in which surface composition analyses are sequentially conducted while exposing the inside of a sample, by using measurement of an X-ray photoelectron spectroscopy (XPS: X-ray Photoelectron Spectroscopy) and ion sputtering of a rare gas such as argon in combination. The distribution curve obtained by such XPS depth profile measurement can be prepared, for example, by setting the longitudinal axis as the atomic ratios (unit: at %) of the respective elements and the horizontal axis as an etching time (sputtering time).

In a distribution curve of an element in which the horizontal axis is set as an etching time by this way, since the etching time approximately relates to the distance from the surface of the above-mentioned gas barrier layer 5 in the layer thickness direction of the above-mentioned gas barrier layer 5 in the layer thickness direction, the distance from the surface of the gas barrier layer 5 calculated from the relationship of the etching velocity and etching time adopted during the measurement of the XPS depth profile can be adopted as “the distance from the surface of the gas barrier layer in the layer thickness direction of the gas barrier layer”.

Furthermore, as a sputtering process to be adopted in such XPS depth profile measurement, it is preferable to adopt a rare gas ion sputtering process using argon (Ar⁺) as an etching ion species, and set the etching velocity (etching rate) to be 0.05 nm/sec (SiO₂ thermal-oxidized film converted value).

Furthermore, in the present invention, from the viewpoint that the gas barrier layer 5 that is homogeneous through the surface of the first gas barrier layer 5a and has an excellent gas barrier property is formed, it is preferable that the gas barrier layer 5 is substantially even in the surface direction of the above-mentioned first gas barrier layer 5a (the direction that is in parallel with the surface of the gas barrier layer 5).

In this specification, that the gas barrier layer 5 is substantially even in the surface direction refers to that, in the case when the above-mentioned oxygen distribution curves and the above-mentioned carbon distribution curves are prepared on optional two measurement portions on the surface of the gas barrier layer 5 by the measurement of XPS depth profiles, the numbers of the extremal values possessed by the carbon distribution curves on the optional two measurement portions are the same, and the absolute values of the difference between the maximum value and minimum value of the atomic ratio of the carbon in the respective carbon distribution curves are identical with each other or different within 5 at %.

It is preferable that the gas barrier film of the present invention include at least one layer of the gas barrier layer 5 that satisfies all of the above-mentioned conditions (i) to (iv), and may also have two or more layers that satisfy such condition.

Furthermore, in the case when the gas barrier film includes two or more layers of such gas barrier layers 5, the materials of the plural gas barrier layers 5 may be the same or different. Furthermore, in the case when the gas barrier film includes two or more layers of such gas barrier layers 5, such gas barrier layers 5 may be formed on one surface of the above-mentioned film substrate 4, or may be formed on both surfaces of the above-mentioned film substrate 4.

Furthermore, in the case when the silicon atomic ratio, oxygen atomic ratio and carbon atomic ratio satisfy the condition represented by the above-mentioned formula (1) at the area of 90% or more of the layer thickness of the first gas barrier layer 5a in the above-mentioned silicon distribution curve, the above-mentioned oxygen distribution curve and the above-mentioned carbon distribution curve, the silicon atomic ratio in the above-mentioned gas barrier layer 5 is preferably in the range of from 25 to 45 at %, more preferably in the range of from 30 to 40 at %.

Furthermore, the oxygen atomic ratio in the above-mentioned first gas barrier layer 5a is preferably in the range of from 33 to 67 at %, more preferably in the range of from 45 to 67 at %.

Furthermore, the carbon atomic ratio in the above-mentioned first gas barrier layer 5a is preferably in the range of from 3 to 33 at %, more preferably in the range of from 3 to 25 at %.

<Thickness of First Gas Barrier Layer>

The thickness of the above-mentioned first gas barrier layer 5a is preferably in the range of from 5 to 3,000 nm, more preferably in the range of from 10 to 2,000 nm, more preferably in the range of from 100 to 1,000 nm, specifically preferably in the range of from 300 to 1,000 nm. If the thickness of the first gas barrier layer 5a is within the above-mentioned range, the gas barrier properties such as oxygen gas barrier property and water vapor barrier property are excellent, and decrease in the gas barrier properties due to bending is not seen.

<Method for Forming First Gas Barrier Layer>

The first gas barrier layer 5a of the present invention is preferably a layer formed by a plasma chemical vapor phase growth process. More specifically, the first gas barrier layer formed by such plasma chemical vapor phase growth process is preferably a layer formed by a plasma chemical vapor phase growth process, in which the above-mentioned film substrate 4 is transported to the above-mentioned pair of film formation rollers in contact with the rollers, and plasma discharging while feeding a film formation gas to between the above-mentioned pair of film formation rollers.

Furthermore, in discharging between the pair of film formation rollers in such way, it is preferable to alternately reverse the polarities of the above-mentioned pair of film formation rollers. Furthermore, as the above-mentioned film formation gas used in such plasma chemical vapor phase growth process, a film formation gas containing an organic silicon compound and oxygen is preferable, and the content of the oxygen in the film formation gas to be fed is preferably equal to or less than a theoretical oxygen amount that is required for completely oxidizing all of the above-mentioned organic silicon compound in the above-mentioned film formation gas. Furthermore, in the present invention, the above-mentioned first gas barrier layer 5a is preferably a layer that is formed by a continuous film formation process on the film substrate 4.

It is preferable that a plasma chemical vapor phase growth process (plasma CVD process) is adopted to the first gas barrier layer in the present invention from the viewpoint of gas barrier property, and the above-mentioned plasma chemical vapor phase growth process may be a plasma chemical vapor phase growth process of a Penning discharging plasma system.

In order to form a layer in which the above-mentioned carbon atomic ratio has a concentration gradient and the gradient changes in the layer as in the first gas barrier layer in the present invention, it is preferable to generate plasma discharging in the spaces of the plurality of film formation rollers in generating plasma in the above-mentioned plasma chemical vapor phase growth process, and it is preferable in the present invention to use a pair of film formation rollers, to transport the above-mentioned film substrate 4 while bringing the film substrate 4 into contact with the respective film formation rollers, and to generate plasma by discharging into the gap of the pair of film formation rollers.

By using a pair of film formation rollers, transporting the above-mentioned film substrate 4 while bringing the film substrate 4 into contact with the pair of film formation rollers, and generating plasma by discharging into the gap of the pair of film formation rollers by this way, the distance between the film substrate 4 and the plasma discharging position between the film formation rollers is changed, whereby it becomes possible to form the gas barrier layer 5 wherein the above-mentioned carbon atomic ratio has a concentration gradient and the gradient continuously changes in the layer.

Furthermore, since it becomes possible to conduct film formation on the surface part of the film substrate 4 that is present on one film formation roller during the film formation, and it also becomes possible to simultaneously conduct film formation on the surface part of the film substrate 4 that is present on the other film formation roller, whereby a thin film can be produced efficiently, the film formation rate can be doubled, and a film having the same structure can be formed. Therefore, it becomes possible to make the extremal values in the above-mentioned carbon distribution curve at least twice, and thus a layer that satisfies all of the above-mentioned conditions (i) to (iv) in the present invention can be formed efficiently.

Furthermore, in the gas barrier film in the present invention, it is preferable to form the above-mentioned gas barrier layer 5 on the surface of the above-mentioned film substrate 4 by a roll-to-roll system from the viewpoint of producibility.

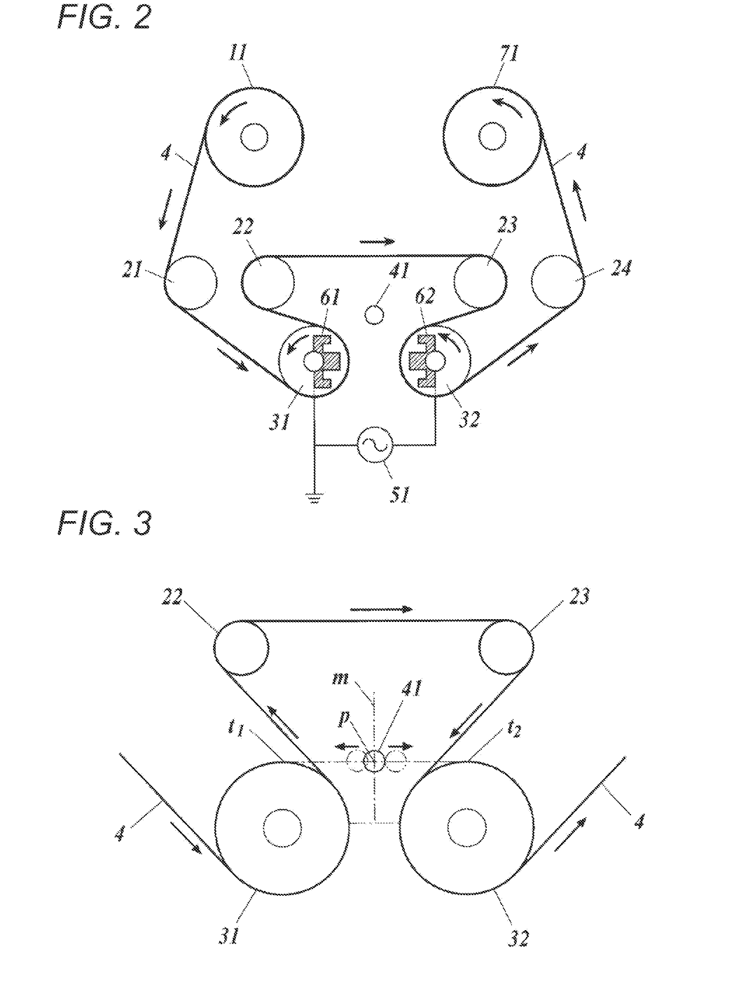

Furthermore, the device that can be used in producing a gas barrier film by such plasma chemical vapor phase growth process is not specifically limited, and an device having a constitution including at least a pair of film formation rollers and a plasma power source, and capable of discharging between the above-mentioned pair of film formation rollers is preferable, and for example, in the case when the production device shown in FIG. 2 is used, it is also possible to produce by a roll-to-roll system by utilizing a plasma chemical vapor phase growth process.

The method for forming the first gas barrier layer in the present invention will be explained below in more detail with referring to FIG. 2. FIG. 2 is a schematic view that shows an example of a production device that can be preferably utilized for forming the first gas barrier layer in the present invention on the film substrate.

The production device shown in FIG. 2 includes a sending roller 11, transportation rollers 21, 22, 23 and 24, film formation rollers 31 and 32, a gas feeding inlet 41, a power source for plasma generation 51, magnetic field generating devices 61 and 62 that are installed inside of the film formation rollers 31 and 32, and a winding roller 71.

Furthermore, in such production device, at least the film formation rollers 31 and 32, the gas feeding inlet 41, the power source for plasma generation 51, and the magnetic field generating devices 61 and 62 formed of permanent magnets are disposed in a vacuum chamber, for which illustration is omitted. Furthermore, in such production device, the above-mentioned vacuum chamber is connected to a vacuum pump, for which illustration is omitted, and thus it becomes possible to suitably adjust the pressure in the vacuum chamber by such vacuum pump.

In such production device, a pair of film formation rollers (the film formation roller 31 and the film formation roller 32) are respectively connected to the power source for plasma generation 51 so that the film formation rollers can be allowed to function as a pair of counter electrode. Therefore, in such production device, it is possible to discharge into the space between the film formation roller 31 and the film formation roller 32 by supplying an electrical power by the power source for plasma generation 51, whereby plasma can be generated in the space between the film formation roller 31 and the film formation roller 32.

In addition, in the case when the film formation roller 31 and the film formation roller 32 are also utilized as electrodes in such way, it is only necessary to suitably change the material and design of the film formation rollers so that they can also be used as electrodes. Furthermore, in such production device, it is preferable that the pair of film formation rollers (film formation rollers 31 and 32) are disposed so that the central axises thereof are approximately in parallel on an identical plane. By disposing the pair of film formation rollers (film formation rollers 31 and 32) in such way, the film formation rate can be doubled, and a film having the same structure can be formed, and thus the extremal values in the above-mentioned carbon distribution curve can be made at least twice.

Furthermore, magnetic field generating devices 61 and 62 that are fixed so that they do not rotate when the film formation rollers 31 and 32 rotate, are respectively disposed on the insides of the film formation rollers 31 and 32.

Furthermore, as the film formation roller 31 and film formation roller 32, suitable known rollers can be used. As such film formation rollers 31 and 32, those having the same diameter are preferably used from the viewpoint that a thin film is formed more efficiently. Furthermore, as the diameter of such film formation rollers 31 and 32, a diameter in the range of from 300 to 1,000 mm in diameter, specifically in the range of from 300 to 700 mm in diameter is preferable from the viewpoints of the conditions for discharging and the space of the chamber. When the diameter is 300 mm in diameter or more, it is preferable since the plasma discharging space is not decreased and the producibility is not deteriorated, and thus the application of the entire heat quantity to the film by plasma discharging within a short time can be avoided, and damages on the film substrate 4 can be decreased. On the other hand, when the diameter is 1,000 mm in diameter or less, it is preferable since practicality in the design of the device, which includes the evenness of the plasma discharging space, and the like, can be retained.

Furthermore, as the sending roller 11 and the transportation rollers 21, 22, 23 and 24 for use in such production device, suitable known rollers can be used. Furthermore, the winding roller 71 is not specifically limited as long as it can wind the film substrate 4 on which the gas barrier layer 5 has been formed, and a suitable known roller can be used.

As the gas feeding inlet 41, a gas feeding inlet that can feed or eject the raw material gas and the like at a predetermined velocity can be suitably used. Furthermore, as the power source for plasma generation 51, a suitable known power source for a plasma generating device can be used. Such power source for plasma generation 51 feeds an electrical power to the film formation roller 31 and the film formation roller 32 that are connected to the power source to thereby enable utilization of these film formation rollers as counter electrodes for discharging.

As such power source for plasma generation 51, it is preferable to utilize a power source that can alternately invert the polarities of the above-mentioned pair of film formation rollers (an alternate current power source or the like) since it becomes possible to carry out a plasma CVD process more efficiently.

Furthermore, as such power source for plasma generation 51, a power source that can set an applied electrical power to be within the range of from 100 W to 10 kW and a wave frequency of an alternate current to be within the range of from 50 Hz to 500 kHz, since it becomes possible to carry out a plasma CVD process more efficiently. Furthermore, as the magnetic field generating devices 61 and 62, known magnetic field generating devices can be suitably used.

By using such production device shown in FIG. 2, for example, by suitably adjusting the kind of the raw material gas, the electrical power of the electrode drum in the plasma generating device, the pressure in the vacuum chamber, the diameters of the film formation rollers, and the transportation velocity of the film substrate 4, the gas barrier film in the present invention can be produced.

Specifically, by generating plasma discharging between the pair of film formation rollers (film formation rollers 31 and 32) while feeding a film formation gas (raw material gas or the like) into a vacuum chamber by using such production device shown in FIG. 2, the above-mentioned film formation gas (raw material gas or the like) is decomposed by plasma, and the above-mentioned gas barrier layer 5 is formed by a plasma CVD process on the surface of the film substrate 4 on the film formation roller 31 and the surface of the film substrate 4 on the film formation roller 32. In addition, in such film formation, since the film substrate 4 is transported by the sending roller 11, the film formation roller 31 and the like, respectively, the above-mentioned first gas barrier layer 5a is formed on the surface of the film substrate 4 by a continuous film formation process of a roll-to-roll system.

The first gas barrier layer 5a in the present invention is preferably such that the local maximum value of the oxygen distribution curve which is the closest to the surface of the gas barrier layer 5 on the side of the film substrate 4 has the maximum value among the local maximum values of the oxygen distribution curve in the first gas barrier layer 5a, in the oxygen distribution curve.

Furthermore, the oxygen atomic ratio in the present invention is such that the oxygen atomic ratio that is the local maximum value of the oxygen distribution curve which is the closest to the surface of the first gas barrier layer 5a on the side of the film substrate 4 is 1.05 times or more of the oxygen atomic ratio that is the local maximum value of the above-mentioned oxygen distribution curve which is the closest to the surface of the gas barrier layer 5 on the side opposite to the film substrate 4 across the gas barrier layer 5.

The formation method so that the above-mentioned oxygen atomic ratio has a desired distribution in the first gas barrier layer 5a in such way is not specifically limited, and the formation is possible by a method in which the concentration of the film formation gas is changed during film formation, a method in which the position of the gas feeding inlet is changed, a method in which gas feeding is conducted at plural portions, a method in which a baffle is disposed beside the gas feeding inlet to thereby control the flow of the gas, and a method in which plural times of plasma CVD are conducted with changing the concentration of the film formation gas, and the like, and a method in which plasma CVD is conduced while moving the position of the gas feeding inlet 41 close to either of the film formation roller 31 or 32 between the film formation rollers is preferable since the method is easy and the fine reproducibility is fine.

FIG. 3 is a schematic view that explains the transfer of the position of the gas feeding inlet of the CVD device.

The CVD device can be controlled so as to satisfy the extremal value condition of the oxygen distribution curve by moving the gas feeding inlet 41 close to the side of the film formation roller 31 or 32 within the range of from 5 to 20% from a perpendicular bisector m of the line that links the film formation rollers 31 and 32, when the distance from the gas feeding inlet to the film formation roller 31 or 32 is deemed as 100%.

Specifically, this means that, when the distance between (t₁−p) or the distance between (t₂−p) is deemed as 100% in the direction from a point p on the perpendicular bisector m of the line that links the film formation roller 31 and 32 to t₁ or t₂, the gas feeding inlet 41 is moved close to the side of the film formation rollers in a manner of parallel displacement within the range of from 5 to 20% from the position of the point p.

In this case, the magnitude of the extremal value of the oxygen distribution curve can be controlled by the distance on which the gas feeding inlet 41 is transferred. For example, in order to increase the extremal value of the oxygen distribution curve on the surface of the gas barrier layer 5 that is the closest to the side of film substrate 4, it is possible to form by moving the gas feeding inlet 41 closer to the film formation roller 31 or 32 at a transfer distance close to 20%.

It is preferable that the range of the transfer of the gas feeding inlet is moved close within the above-mentioned range of from 5 to 20%, and more preferably within the range of from 5 to 15%, and unevenness and the like are difficult to generate in the oxygen distribution curve in the plane and other limitation distribution curves within the above-mentioned range, and thus it is possible to form a desired distribution homogeneously with fine reproducibility.

FIG. 4 shows examples of the respective element profiles in the thickness direction of the layer by XPS depth profiles in the film formation of the first gas barrier layer 5a of the present invention by moving the gas feeding inlet 41 close by 5% in the direction of the film formation roller 31.

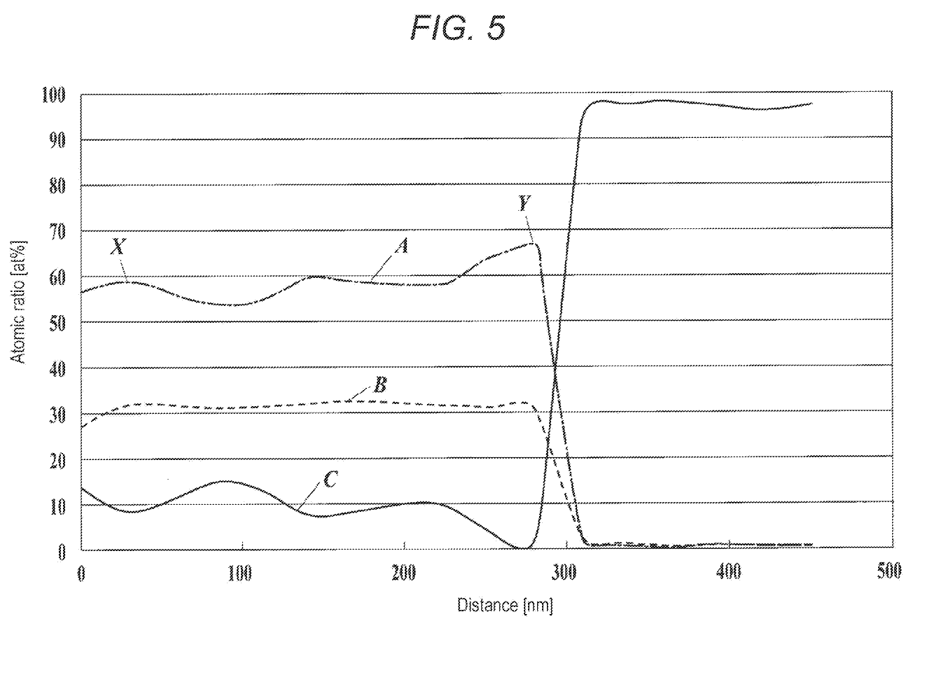

Furthermore, FIG. 5 shows examples of the respective element profiles in the thickness direction of the layer by XPS depth profiles in the film formation by moving the gas feeding inlet 41 close by 10% in the direction of the film formation roller 32.

In both cases, it is understood that the values of the oxygen atomic ratios are Y>X, when the local maximum value of the oxygen atomic ratio which is the closest to the surface of the gas barrier layer 5 in the oxygen distribution curve A is deemed as X and the local maximum value of the oxygen atomic ratio which is the closest to the surface of the film substrate 4 is deemed as Y.

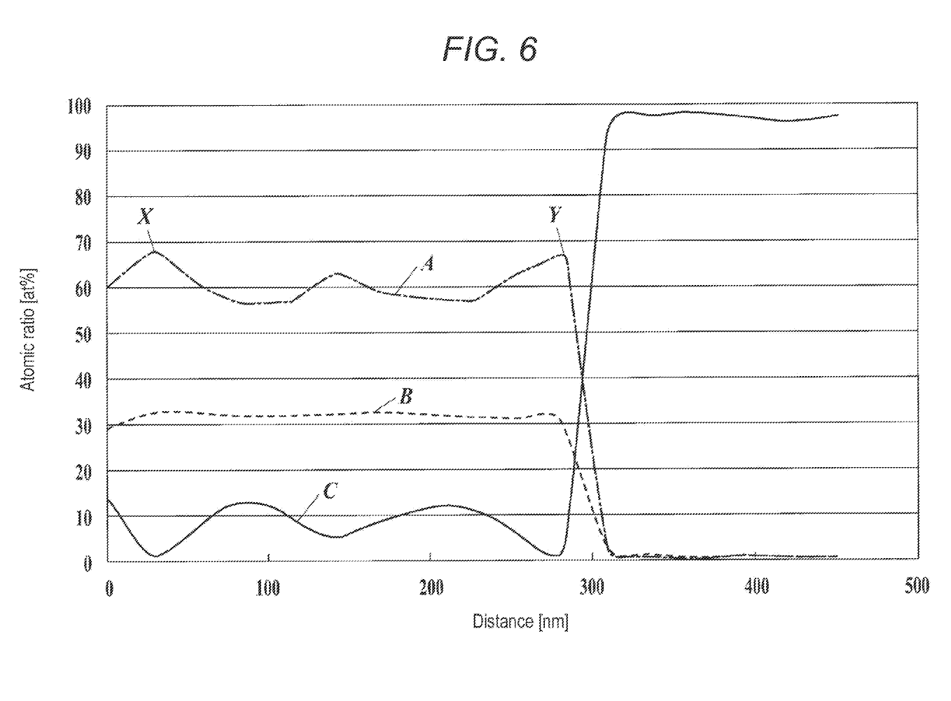

On the other hand, FIG. 6 is an example of the respective element profiles in the thickness direction of the layer by XPS depth profiles of a comparative gas barrier layer. This gas barrier layer is such that the gas barrier layer is formed by disposing the gas feeding inlet 41 on the perpendicular bisector m of the line that links the film formation rollers 31 and 32, and the oxygen atomic ratio that is the local maximum value X of the oxygen distribution curve which is the closest to the surface of the gas barrier layer on the side of the film substrate is approximately the same as the oxygen atomic ratio that is the local maximum value Y of the oxygen distribution curve which is the closest to the surface of the gas barrier layer which is on the opposite side of the film substrate across the gas barrier layer, and it is understood that the extremal value of the oxygen distribution curve of the surface of the gas barrier layer which is the closest to the side of the film substrate is not the maximum value in the layer.

<Raw Material Gas>

The raw material gas in the above-mentioned film formation gas that is used in the formation of the first gas barrier layer 5a in the present invention can be suitably selected and used depending on the material of the gas barrier layer 5 to be formed. As such raw material gas, for example, it is preferable to use an organic silicon compound containing silicon.

Examples of such organic silicon compound include hexamethyldisiloxane, 1,1,3,3-tetramethyldisiloxane, vinyltrimethylsilane, methyltrimethylsilane, hexamethyldisilane, methylsilane, dimethylsilane, trimethylsilane, diethylsilane, propylsilane, phenylsilane, vinyltriethoxysilane, vinyltrimethoxysilane, tetramethoxysilane, tetraethoxysilane, phenyltrimethoxysilane, methyltriethoxysilane, octamethylcyclotetrasiloxane and the like.

Among these organic silicon compounds, hexamethyldisiloxane and 1,1,3,3-tetramethyldisiloxane are preferable from the viewpoints of properties such as the handling in the film formation and the gas barrier property of the obtained gas barrier layer 5. Furthermore, these organic silicon compounds can be used singly by one kind or in combination of two or more kinds.

Furthermore, as the above-mentioned film formation gas, a reaction gas may also be used besides the above-mentioned raw material gas. As such reaction gas, a gas that reacts with the above-mentioned raw material gas to become an inorganic compound such as an oxide or a nitride can be suitably selected and used.

As the reaction gas for forming an oxide, for example, oxygen and ozone can be used. Furthermore, as the reaction gas for forming a nitride, for example, nitrogen and ammonia can be used.

These reaction gases can be used singly by one kind or in combination of two or more kinds, and for example, in the case when an acid nitride is to be formed, a reaction gas for forming an oxide and a reaction gas for forming a nitride can be used in combination.

As the above-mentioned film formation gas, a carrier gas may also be used as necessary so as to feed the above-mentioned raw material gas into the vacuum chamber. Furthermore, as the above-mentioned film formation gas, a gas for discharging may also be used as necessary so as to generate plasma discharging. As such carrier gas and gas for discharging, suitable known gases can be used, and for example, rare gas elements such as helium, argon, neon and xenon can be used.

In the case when such film formation gas contains a raw material gas and a reaction gas, the ratio of the raw material gas to the reaction gas is preferably such a ratio that the ratio of the reaction gas is not too excess over the ratio of the amount of the reaction gas that is theoretically required for completely reacting the raw material gas and the reaction gas. When the ratio of the reaction gas is too excessive, the gas barrier layer 5 in the present invention is difficult to be obtained. Accordingly, in order to obtain performances as a desired barrier film, in the case when the above-mentioned film formation gas contains the above-mentioned organic silicon compound and oxygen, the oxygen amount is preferably equal to or less than a theoretical oxygen amount that is required for completely oxidizing the whole amount of the above-mentioned organic silicon compound in the above-mentioned film formation gas.

As typical examples, hexamethyldisiloxane (organic silicon compound: HMDSO, (CH₃)₆Si₂O) as a raw material gas and oxygen (O₂) as a reaction gas will be covered and explained below.

In the case when a silicon-oxygen-based thin film is formed by reacting a film formation gas containing hexamethyldisiloxane (HMDSO, (CH₃)₆Si₂O) as a raw material gas and oxygen (O₂) as a reaction gas by a plasma CVD process, a reaction represented by the following reaction formula (1) occurs by the film formation gas, thereby silicon dioxide is produced.

(CH₃)₆Si₂O+12O₂→6CO₂+9H₂O+2SiO₂ (1)

In such reaction, the amount of oxygen that is required for completely oxidizing 1 mol of hexamethyldisiloxane is 12 mol. Therefore, since a homogeneous silicon dioxide film is formed in the case when 12 mol or more of oxygen is incorporated in 1 mol of hexamethyldisiloxane in the film formation gas and reacted completely, an incomplete reaction is carried out by controlling the gas flow amount ratio of the raw material to be a flow amount that is equal to or less than the raw material ratio of the complete reaction, which is a theoretical ratio. In other words, it is necessary to set the oxygen amount with respect to 1 mol of hexamethyldisiloxane to be smaller than 12 mol, which is a stoichiometric ratio.

In addition, in an actual reaction in a plasma CVD chamber, the hexamethyldisiloxane as a raw material and oxygen as a reaction gas are fed from a gas feeding inlet to a film formation area and a film is formed. Therefore, even if the molar amount (flow amount) of the oxygen as a reaction gas is a molar amount (flow amount) that is 12-fold of the molar amount (flow amount) of hexamethyldisiloxane as a raw material, the reaction cannot be progressed completely from a practical perspective, and it is considered that the reaction is completed only after feeding a large excess content of oxygen over the stoichiometric ratio (for example, there are some cases in which the molar amount (flow amount) of the oxygen is set to be 20-fold or more of the molar amount (flow amount) of the hexamethyldisiloxane as a raw material so as to effect complete oxidation by a CVD process to thereby obtain a silicon oxide). Therefore, the molar amount (flow amount) of the oxygen against the molar amount (flow amount) of the hexamethyldisiloxane as a raw material is preferably an amount equal to or less than a 12-fold amount as a stoichiometric ratio (more preferably equal to or less than 10-fold).

By incorporating the hexamethyldisiloxane and oxygen at such ratio, the carbon atoms and hydrogen atoms of the hexamethyldisiloxane that has not been completely oxidized are taken into the gas barrier layer 5, whereby it becomes possible to form a desired gas barrier layer 5, and it becomes possible to allow the obtained gas barrier film to exert excellent barrier property and flex resistance.

Furthermore, the lower limit of the molar amount (flow amount) of the oxygen with respect to the molar amount (flow amount) of the hexamethyldisiloxane in the film formation gas is preferably in an amount that is more than 0.1-fold, more preferably in an amount that is more than 0.5-fold, of the molar amount (flow amount) of the hexamethyldisiloxane.

<Vacuum Degree>

The pressure (vacuum degree) in the vacuum chamber can be suitably adjusted depending on the kind of the raw material gas and the like, and is preferably in the range of from 0.5 to 100 Pa.

<Formation of Roller Film>

The electrical power to be applied to an electrode drum (this is installed in the film formation rollers 31 and 32 in this exemplary embodiment) that is connected to a power source for plasma generation 51 so as to discharge between the film formation rollers 31 and 32 in such plasma CVD process can be suitably adjusted depending on the kind of the raw material gas, the pressure in the vacuum chamber, and the like, and cannot be generally said, but is preferably in the range of from 0.1 to 10 kW.

When the applied electrical power is within such range, generation of particles is not seen, and the amount of the heat that generates in the film formation is also in control, and thus there are no thermal damage on the film substrate 4 and no generation of wrinkles during the film formation due to the raising of the temperature on the surface of the film. substrate 4 during the film formation. Furthermore, the possibility of damaging on the film formation rollers themselves by the melting of the film substrate 4 by heat to thereby cause generation of discharging of a high electrical current between the bare film formation rollers is small.

The transportation velocity (line velocity) of the film substrate 4 can be suitably adjusted depending on the kind of the raw material gas, the pressure of the vacuum chamber, and the like, and is preferably in the range of from 0.25 to 100 m/min, more preferably in the range of from 0.5 to 20 m/min. If the line velocity is within the above-mentioned range, wrinkles caused by heat of the film substrate 4 are difficult to generate, and the thickness of the formed gas barrier layer 5 can be sufficiently controlled.

<Second Gas Barrier Layer>

The gas barrier layer in the present invention is characterized by being constituted by at least two kinds of gas barrier layers that are different from each other in the composition or distribution state of the constitutional elements.

In the present invention, it is preferable to provide a second gas barrier layer on the first gas barrier layer in the present invention, wherein the second gas barrier layer is formed by providing a coating of a polysilazane-containing liquid of an application system, and conducting a modification treatment by irradiating with a vacuum ultraviolet ray (VUV ray) at a wavelength of 200 nm or less. It is preferable to provide the above-mentioned second gas barrier layer onto the gas barrier layer that has been provided by a CVD process, since the minute defects remaining on the gas barrier layer can be filled by the polysilazane gas barrier component from the upper part, and thus the gas barrier property and flexibility can further be improved.

The thickness of the second gas barrier layer is preferably in the range of from 1 to 500 nm, more preferably in the range of from 10 to 300 nm. When the thickness is thicker than 1 nm, a gas barrier performance can be exerted, and when the thickness is within 500 nm, cracks are difficult to generate on a dense silicon oxide film.

<Polysilazane>

In the second gas barrier layer in the present invention, a polysilazane represented by the above-mentioned general formula (A) can be used. From the viewpoint of the denseness of the obtained gas barrier layer as a film, a perhydropolysilazane wherein all of R¹, R² and R³ in the general formula (A) are hydrogen atoms is specifically preferable.

The second gas barrier layer can be formed by applying an application liquid containing polysilazane on the gas barrier layer by a CVD process, drying, and irradiating the application liquid with a vacuum ultraviolet ray.

As an organic solvent for preparing the application liquid containing polysilazane, it is preferable to avoid use of alcohol-based organic solvents, which easily react with polysilazane, and organic solvents containing moisture. For example, hydrocarbon solvents such as aliphatic hydrocarbons, alicyclic hydrocarbons and aromatic hydrocarbons, halogenated hydrocarbon solvents, and ethers such as aliphatic ethers and alicyclic ethers can be used, and specific examples include hydrocarbons such as pentane, hexane, cyclohexane, toluene, xylene, Solvesso and terbenes, halogen hydrocarbons such as methylene chloride and trichloroethane, ethers such as dibutyl ether, dioxane and tetrahydrofuran, and the like. These organic solvents are selected depending on the purposes such as the solubility of the polysilazane and the vaporization velocity of the solvent, and plural organic solvents may be mixed.

The concentration of the polysilazane in the application liquid containing polysilazane differs depending on the layer thickness of the gas barrier layer and the pot life of the application liquid, and is preferably about 0.2 to 35% by mass.

In order to promote modification to acid silicon nitride, amine catalysts, and metal catalysts such as Pt compounds such as Pt acetylacetonate, Pd compounds such as Pd propionate and Rh compounds such as Rh acetylacetonate can also be added to the application liquid. In the present invention, it is specifically preferable to use amine catalysts. Specific amine catalysts include N,N-diethylethanolamine, N,N-dimethylethanolamine, triethanolamine, triethylamine, 3-morpholinopropylamine, N,N,N′,N′-tetramethyl-1,3-diaminopropane, N,N,N′,N′-tetramethyl-1,6-diaminohexane and the like.

The addition amount of these catalysts with respect to the polysilazane is preferably in the range of from 0.1 to 10% by mass, more preferably in the range of from 0.2 to 5% by mass, further preferably in the range of from 0.5 to 2% by mass with respect to the entirety of the application liquid. By setting the addition amount of the catalyst to be within this range, formation of excess silanol and decrease in film density due to the rapid progress of the reaction, increase in film defects, and the like can be avoided.

As the method for applying the application liquid containing polysilazane, an optional suitable method can be adopted. Specific examples include a roll coat process, a flow coat process, an inkjet process, a spray coat process, a print process, a dip coat process, a casting film formation process, a bar coat process, a gravure printing process and the like.

The thickness of the coating can be suitably preset depending on the purpose. For example, the thickness of the coating is preferably in the range of from 50 nm to 2 μm, more preferably in the range of from 70 nm to 1.5 μm, further preferably in the range of from 100 nm to 1 μm as the thickness after drying.

<Excimer Treatment>

In the second gas barrier layer of the present invention, at least a part of the polysilazane is modified to acid silicon nitride in the step of irradiating the layer containing polysilazane with a vacuum ultraviolet ray.

Meanwhile, the assumed mechanism of the modification of the coating containing polysilazane to be a specific composition of SiOxNy in the step of irradiating with a vacuum ultraviolet ray will be explained with exemplifying perhydropolysilazane.

Perhydropolysilazane can be represented by the composition of “—(SiH₂—NH)n-”. In the case when representing with SiOxNy, x=0 and y=1. An outer oxygen source is required so as to achieve x>0, and (I) the oxygen and moisture contained in the polysilazane application liquid, (II) the oxygen and moisture that are taken into the coating from the atmosphere during the processes of the application and drying, (III) the oxygen and moisture that are taken into the coating from the atmosphere in the vacuum ultraviolet ray irradiation step, ozone, singlet oxygen, (IV) the oxygen and moisture that are transferred into the coating as an out gas from the side of the substrate by the heat that is applied during the vacuum ultraviolet ray irradiation step, and the like, (V) in the case when the vacuum ultraviolet ray irradiation step is conducted under a non-oxidative atmosphere, the oxygen and moisture that are taken from the atmosphere into the coating during the transfer from the non-oxidative atmosphere to the oxidative atmosphere, and the like serve as the oxygen source.

On the other hand, with respect to y, it is considered that the condition under which nitridation of Si proceeds is very special as compared to oxidation, and thus 1 is the upper limit in essence.

Furthermore, from the relationship of the bonds of Si, O and N, x and y are within the range of 2x+3y≦4 in essence. In the state of y=0 in which the oxidation has completely proceeded, there are some cases in which silanol groups are contained in the coating and x is in the range of 2<x<2.5.

The reaction mechanism in which acid silicon nitride, as well as silicon oxide are generated from the perhydropolysilazane in the vacuum ultraviolet ray irradiation step will be explained below.

(1) Dehydrogenation, and Formation of Si—N Bonds Associated with Dehydrogenation

It is considered that the Si—H bonds and N—H bonds in the perhydropolysilazane are cut in a relatively easy manner by the excitation due to the irradiation of a vacuum ultraviolet ray and the like, and are re-bonded as Si—N under an inert atmosphere (dangling bonds of Si are formed in some cases). In other words, the perhydropolysilazane is cured as a SiNy composition without being oxidized. In this case, the cleavage of the polymer main chain is not generated. The cleavage of the Si—H bonds and N—H bonds are promoted by the presence of a catalyst, and heating. The Hs that have been cleaved are released as H₂ out of the film.

(2) Formation of Si—O—Si Bonds by Hydrolysis/Dehydration Condensation

The Si—N bonds in the perhydropolysilazane are hydrolyzed by water, and the polymer main chain is cleaved to form Si—OHs. Two Si—OHs are dehydration-condensed to form a Si—O—Si bond, whereby curing is conducted. This is a reaction that also occurs in the air, and in the irradiation of a vacuum ultraviolet ray under an inert atmosphere, it is considered that the water vapor that generates as an out gas from the substrate by the heat of the irradiation becomes a major moisture source. When the moisture is in excess, the Si—OHs that have not been dehydration-condensed remain, and a cured film having a composition represented by SiO_{2.1 to 2.3} and having a low gas barrier property is formed.

(3) Direct Oxidation and Formation of Si—O—Si Bonds by Singlet Oxygen

During the irradiation of a vacuum ultraviolet ray, when a suitable amount of oxygen is present under the atmosphere, singlet oxygen, which has very strong potential of oxidation, is formed. The H and N in the perhydropolysilazane are replaced with O to form Si—O—Si bonds, whereby curing is conducted. It is considered that there is also a case when the bonds are recombined by the cleavage of the polymer main chain.

(4) Oxidation Accompanying Cleavage of Si—N Bonds by Irradiation of Vacuum Ultraviolet Ray and Excitation

It is considered that, since the energy of the vacuum ultraviolet ray is higher than the bonding energy of the Si—N in the perhydropolysilazane, the Si—N bonds are cleaved, and when oxygen sources such as oxygen, ozone and water are present in the surrounding area, the Si—N bonds are oxidized to form Si—O—Si bonds and Si—O—N bonds. It is considered that there is also a case when the bonds are recombined by the cleavage of the polymer main chain.

The composition of the acid silicon nitride of the layer formed by irradiating the layer containing polysilazane with a vacuum ultraviolet ray can be adjusted by controlling the oxidation state by suitably combining the oxidation mechanisms of the above-mentioned (1) to (4).

In the step of irradiation of a vacuum ultraviolet ray in the present invention, the illuminance of the vacuum ultraviolet ray on the coating surface received by the polysilazane layer coating is preferably in the range of from 30 to 200 mW/cm², more preferably in the range of from 50 to 160 mW/cm². 30 mW/cm² or more is preferable since decrease in the modification efficiency is not concerned, and 200 mW/cm² or less is preferable since abrasion does not occur on the coating and the substrate is not damaged.

The amount of the irradiation energy of the vacuum ultraviolet ray on the polysilazane layer coating surface is preferably in the range of from 200 to 10,000 mJ/cm², more preferably in the range of from 500 to 5,000 mJ/cm². At 200 mJ/cm² or more, the modification can be conducted sufficiently, and at 10,000 mJ/cm² or less, the modification is not excessive, and cracks are not generated and the substrate is not deformed by heat.

As a vacuum ultraviolet ray source, a rare gas excimer lamp is preferably used. Since atoms of rare gases such as Xe, Kr, Ar and Ne and the like do not form molecules by chemical bonding, they are referred to as inert gases.

However, excited atoms that have obtained energy by discharging or the like of a rare gas can make molecules by binding with other atoms. In the case when the rare gas is Xe (xenon),

e+Xe→Xe*

Xe*+2Xe→Xe₂*+Xe

Xe₂*→Xe+Xe+hν (172 nm),

and excimer light of 172 nm is emitted when Xe₂*, which is an excited excimer molecule, transits to a ground state.

The characteristics of the excimer lamp include that the excimer lamp has a high efficiency since radiations are concentrated in one wavelength, and lights other than necessary lights are radiated little. Furthermore, since excess lights are not radiated, the temperature of an object can be kept relatively low. In addition, a long time is not necessary for starting and restarting, instant lighting and blinking are possible.

In order to obtain excimer light emission, a method using dielectric-barrier discharge is known. Dielectric-barrier discharge is discharge called as micro discharge, which looks like thunder and is very thin, and generates by disposing a gas space through a dielectric such as transparent quartz between the two electrodes, and applying a high frequency-high voltage of several ten kHz to the electrodes, and when a streamer of the micro discharge reaches a tube wall (derivative), an electrical charge is stored on the surface of the dielectric, and the micro discharge disappears.

This micro discharge is discharge that spreads on the whole tube wall and repeats generation and disappearance. Therefore, flickering of light, which can also be confirmed by the naked eyes, is generated. Furthermore, since a streamer having a very high temperature reaches the tube wall locally and directly, there is a possibility that the deterioration of the tube wall is accelerated.

As a method for efficiently obtaining excimer light emission, non-electrode electric field discharge is also possible besides dielectric-barrier discharge. This is non-electrode electric field discharge by capacitive bonding, and is also called by another name, RF discharging. The lamp, electrodes and the arrangement thereof may be essentially the same as those of dielectric-barrier discharge, but the high frequency wave applied to between the two electrodes is lighted at several MHz. Accordingly, since even discharging in terms of space and time can be obtained in the non-electrode electric field discharge, a lamp having a long lifetime with no flickering can be obtained.

In the case of dielectric-barrier discharge, since micro discharge is generated only between electrodes, the outer electrode should be one that covers the whole outer surface and allows transmission of light so as to extract light outside, in order to conduct discharging by the entirety of the discharge space.

Therefore, an electrode obtained by forming a thin metal wire into a net-shape is used. Since this electrode uses a wire that is as thin as possible so that light is not blocked, this electrode is easily damaged by ozone and the like generated by a vacuum ultraviolet ray light in an oxygen atmosphere. In order to prevent this, it is necessary to put the surrounding of the lamp, i.e., the inside of the irradiation device, into an atmosphere of an inert gas such as nitrogen, and to provide a window of synthesis quartz and extract the irradiated light. As well as being an expensive consumable supply, the window of synthesis quartz causes loss in light.

Since a double cylindrical lamp has an outer diameter of about 25 mm, the difference in distance to the irradiation surface cannot be neglected at immediately below the lamp axis and the side surface of the lamp, and a significant difference in illuminance occurs. Therefore, even if lamps are arranged in close contact with one another, an even illuminance distribution cannot be obtained. If an irradiation device provided with a window of synthesis quartz is used, the distances in the oxygen atmosphere can be made even, and an even illuminance distribution can be obtained.

In the case when non-electrode electric field discharge is used, it is not necessary to form the outer electrode into a net shape. By only providing an outer electrode to a part of the outer surface of the lamp, glow discharge spreads over the whole discharge space. As the outer electrode, an electrode made of an aluminum block, which also serves as a light reflection plate, is generally used on the back surface of the lamp. However, since the outer diameter of the lamp is large as in the case of dielectric-barrier discharge, synthetic quartz is required so as to give an even illuminance distribution.

The most notable characteristic of a thin tube excimer lamp is that it has a simple structure. The structure is only such that the both ends of a quartz tube are closed, and a gas for conducting excimer light emission is enclosed therein.

The outer diameter of the thin tube lamp is about 6 nm to 12 mm, and if the outer diameter is too large, a high voltage is required for starting.

As the form of the discharge, either of dielectric-barrier discharge and non-electrode electric field discharge can be used. The shape of the electrode may be such that the surface in contact with the lamp is a plane, but if the shape is formed into a shape in conformity with the curved surface of the lamp, the lamp can be fixed tightly, and the discharge becomes more stable since the electrodes are tightly attached to the lamp. Furthermore, if the curved surface is formed into a mirror surface with aluminum, the curved surface also serves as a light reflecting plate.

An Xe excimer lamp radiates an ultraviolet ray at a short wavelength of 172 nm by a single wavelength, and thus is excellent in light emission efficiency. This light has a large absorbance coefficiency of oxygen, and thus can generate radical oxygen atom species and ozone with a minute amount of at a high concentration.

Furthermore, it is known that the energy of a light at 172 nm having a short wavelength has a high ability to allow the bonding of organic substances to dissociate. By the high energy possessed by this active oxygen, ozone and ultraviolet irradiation, the modification of the polysilazane layer can be attained within a short time.

Therefore, as compared to a low pressure mercury lamp that emits at wavelengths of 185 nm and 254 nm and plasma washing, it is possible to shorten a processing time associated with a high throughput, decrease the surface area of the facilities, and irradiation to organic materials, plastic substrates and the like that are easily damaged by heat.

Since an excimer lamp has a high light generate efficiency, it can be lighted by inputting a low electrical power. Furthermore, the excimer lamp does not emit a light with a long wavelength, which causes temperature rising by light, but irradiate an energy at the ultraviolet region, i.e., a short wavelength, and thus has a characteristic that the raising of the surface temperature of an exposure subject is suppressed. Therefore, the excimer lamp is suitable for flexible film materials such as PET, which are deemed to be easily affected by heat.

Although oxygen is necessary for the reaction during ultraviolet irradiation, the efficiency in the ultraviolet irradiation step of the vacuum ultraviolet ray is easily decreased due to the absorption by oxygen. Therefore, it is preferable that the vacuum ultraviolet ray is irradiated under a state in which the oxygen concentration is as low as possible. Specifically, the oxygen concentration during the irradiation of the vacuum ultraviolet ray is preferably in the range of from 10 to 10,000 ppm, more preferably in the range of from 50 to 5,000 ppm, further preferably in the range of from 1,000 to 4,500 ppm.

The gas that satisfies the irradiation atmosphere used during the irradiation of the vacuum ultraviolet ray is preferably a dry inert gas, and specifically preferably a dry nitrogen gas from the viewpoint of costs. The oxygen concentration can be adjusted by measuring the flow amounts of the oxygen gas and the inert gas to be introduced into an irradiation chamber, and changing the ratio of the flow amounts.

<Film Substrate>

Examples of the film substrate 4 on which the transparent electrode 2 is to be formed include, but are not limited to, the following resin films and the like. As the film substrates 4 that are preferably used, transparent resin films can be exemplified.

Examples of the resin films include polyesters such as polyethylene telephthalate (PET) and polyethylene naphthalate (PEN), polyethylene, polypropylene, cellophane, cellulose esters such as cellulose diacetate, cellulose triacetate (TAC), cellulose acetate butyrate, cellulose acetate propionate (CAP), cellulose acetate phthalate and cellulose nitrate or derivatives thereof, polyvinylidene chloride, polyvinyl alcohol, polyethylene vinyl alcohol, syndiotactic polystyrene, polycarbonate, norbornene resins, polymethylpentene, polyetherketone, polyimides, polyethersulfone (PES), polyphenylenesulfide, polysulfones, polyetherimides, polyetherketoneimides, polyamides, fluorine resins, nylons, polymethyl methacrylate, acrylics or polyarylates, cycloolefin-based resins such as ARTON (commercial product name, manufactured by JSR Corporation) or APEL (commercial product name, manufactured by Mitsui Chemicals, Inc.), and the like.

[Other Constitutional Factors of Organic Electroluminescent Element]

### <Electrodes>

The organic electroluminescence (organic EL element) of the present invention has a light emitting unit, which has an organic functional layer that is sandwiched by a pair of electrodes including the following anode and cathode. The electrodes will be explained below in detail.

<<Anode (Transparent Electrode)>>

As the anode in the organic EL element, an anode including a metal, an alloy, an electroconductive compound and a mixture thereof having a large work function (4 eV or more) as an electrode substance is preferably used. Specific examples of such electrode substance include metals such as Au and Ag, and electroconductive transparent materials such as CuI, indium tin oxide (Indium Tin Oxide: ITO), SnO₂ and ZnO.

Furthermore, a material that is amorphous and capable of preparing a transparent electroconductive film such as IDIXO (In₂O₃—ZnO) may also be used. These electrode substances may be formed into a thin film by a method such as deposition or sputtering, and a pattern of a desired shape may be formed on the anode by a photolithography process, or in the case when a high pattern accuracy is not necessary (about 100 μm or more), a pattern may be formed through a mask having a desired shape during the deposition or sputtering of the above-mentioned electrode substance.

Alternatively, in the case when a substance that can be applied such as an organic electroconductive compound is used, a wet film formation process such as a printing system, a coating system or the like can also be used. In the case when light emission is extracted from this anode, it is desirable that the transmittance is preset to be more than 10%, and the sheet resistance of the anode is preferably several hundreds Ω/sq. or less. Furthermore, the film thickness is selected in the range of generally from 10 to 1,000 nm, preferably from 10 to 200 nm depending on the material.

In the organic EL element of the present invention, it is preferable to use the transparent electrode 2 of the aspect as shown in FIG. 1 as the anode.

As shown in FIG. 1, the transparent electrode 2 has a two-layered structure in which a primer layer 2a and the electrode layer 2b formed on the upper part thereof are stacked in this order from the side of the film substrate 4. Of these, the electrode layer 2b is a layer that is constituted by using silver or an alloy containing silver as a major component, and the primer layer 2a is a layer that is constituted by using, for example, a compound containing a nitrogen atom.

The transparent in the transparent electrode 2 refers to that the light transmittance at a wavelength of 550 nm is 50% or more.

(1) Primer Layer

The primer layer 2a is a layer that is disposed on the side of the film substrate 4 of the electrode layer 2b. The material constituting the primer layer 2a is not specifically limited, and may be any material that can suppress the flocculation of silver in the film formation of the electrode layer 2b that is formed of silver or an alloy containing silver as a major component, and for example, a compound containing a nitrogen atom and a sulfur atom, and the like are exemplified.

In the case when the primer layer 2a is formed of a low-refractive index material (having a refractive index of less than 1.7), the upper limit of the layer thickness should be less than 50 nm, and is preferably less than 30 nm, more preferably less than 10 nm, and specifically preferably less than 5 nm. By setting the layer thickness to be less than 50 nm, optical loss can be suppressed to the minimum. On the other hand, the lower limit of the layer thickness should be 0.05 nm or more, and is preferably 0.1 nm or more, specifically preferably 0.3 nm or more. By setting the layer thickness to be 0.05 nm or more, the film formation of the primer layer 2a can be even, and the effect thereof (suppression of the flocculation of silver) can be even.

In the case when the primer layer 2a is formed of a high-refractive index material (having a refractive index of 1.7 or more), the upper limit of the layer thickness thereof is not specifically limited, and the lower limit of the layer thickness is similar to that in the case when the primer layer 2a is formed of the above-mentioned low-refractive index material.

However, as a mere function of the primer layer 2a, it is sufficient as long as the primer layer is formed by a layer thickness that is required for obtaining a homogeneous film formation.

As the method for the film formation of the primer layer 2a, methods using wet processes such as an application process, an inkjet process, a coating process and a dipping process, and methods using dry processes such as deposition processes (resistance heating, an EB process and the like), a sputtering process and a CVD process, and the like are exemplified. Among these, the deposition process is preferably applied.

The compound containing a nitrogen atom which constitutes the primer layer 2a is not specifically limited as long as it is a compound containing a nitrogen atom in the molecule, and is preferably a compound having a heterocyclic ring having a nitrogen atom as a hetero atom. As the heterocyclic ring having a nitrogen atom as a hetero atom, azilidine, aziline, azetidine, azeto, azolidine, azole, azinane, pyridine, azepane, azepine, imidazole, pyrazole, oxazole, thiazole, imidazoline, pyrazine, morpholine, thiazine, indole, isoindole, benzimidazole, purine, quinoline, isoquinoline, quinoxaline, cinnoline, pteridine, acridine, carbazole, benzo-C-cinnoline, porphyrin, chlorin, choline and the like are exemplified.

(2) Electrode Layer

The electrode layer 2b is a layer that is constituted by using silver or an alloy containing silver as a major component, and formed by film formation on the primer layer 2a.

As such method for film formation of the electrode layer 2b, methods using wet processes such as an application process, an inkjet process, a coating process and a dip process, methods using dry processes such as deposition processes (resistance heating, an EB process and the like), a sputtering process and a CVD process, and the like are exemplified. Among these, the deposition process is preferably applied.

Furthermore, although the electrode layer 2b is characterized in that it has sufficient electroconductivity without a high temperature annealing process and the like after the film formation of the electrode layer 2b, by being formed on the primer layer 2a, a high temperature annealing process and the like may be conducted after the film formation as necessary.

Examples of the alloy containing silver (Ag) as a major component which constitutes the electrode layer 2b include silver-magnesium (AgMg), silver-copper (AgCu), silver-palladium (AgPd), silver-palladium-copper (AgPdCu), silver-indium (AgIn) and the like.

Where necessary, the electrode layer 2b as mentioned above may have a constitution in which the layer of silver or an alloy containing silver as a major component is divided into plural layers and stacked.

Furthermore, this electrode layer 2b preferably has a layer thickness within the range of from 4 to 9 nm. In the case when the layer thickness is thinner than 9 nm, the absorbable component or reflectable component in the layer is small, and thus the transmittance of the transparent electrode increases. Furthermore, in the case when the layer thickness is thicker than 4 nm, the electroconductivity of the layer can be sufficiently ensured.

In addition, in the transparent electrode 2 having the stacked structure formed of the primer layer 2a and the electrode layer 2b formed thereon as mentioned above, the upper part of the electrode layer 2b may be covered with a protection film, or another electrode layer may be stacked on the electrode layer 2b. In this case, it is preferable that the protection film and another electrode layer have a light transmission property so that the light transmission property of the transparent electrode 2 is not lost.

Furthermore, the transparent electrode 2 having the constitution as mentioned above has, for example, a constitution in which the electrode layer 2b formed of silver or an alloy containing silver as a major component is disposed on the primer layer 2a constituted by using the compound containing a nitrogen atom. By this way, during the film formation of the electrode layer 2b on the upper part of the primer layer 2a, the silver atoms constituting the electrode layer 2b interacts with the compound containing a nitrogen atom constituting the primer layer 2a, and the diffusion distance of the silver atoms on the surface of the primer layer 2a is decreased, and thus the flocculation of the silver is suppressed.

Meanwhile, in general, since a thin film grows in a nucleation growth type (Volumer-Weber: VW type) in the film formation of the electrode layer 2b containing silver as a major component, the silver particles are easily isolated in insular shapes, and thus it is difficult to obtain electroconductivity when the layer thickness is thin, and the sheet resistance value increase. Therefore, it is necessary to increase the layer thickness in order to ensure electroconductivity, but the light transmittance is decreased when the layer thickness is increased, and thus the electrode layer was not suitable as a transparent electrode.

However, according to the transparent electrode 2, since the flocculation of silver is suppressed on the primer layer 2a as mentioned above, a thin film grows in a monolayer growth type (Frank-van der Merwe: FM type) in the film formation of the electrode layer 2b containing silver or an alloy containing silver as a major component.

Furthermore, the transparency of the transparent electrode 2 refers to that the light transmittance at a wavelength of 550 nm is 50% or more, but the above-mentioned respective materials used as the primer layer 2a are films having sufficiently fine light transmission properties as compared to the electrode layer 2b formed of silver or an alloy containing silver as a major component. On the other hand, the electroconductivity of the transparent electrode 2 is ensured mainly by the electrode layer 2b. Therefore, as mentioned above, the electroconductivity of the electrode layer 2b formed of silver or an alloy containing silver as a major component is ensured at a thicker layer thickness, and thus it becomes possible to attain improvement of the electroconductivity of the transparent electrode 2 and improvement of the light transmission property at the same time.

<<Cathode>>

The cathode (counter electrode) 6 is an electrode film that functions as a cathode for supplying electrons to the light emitting unit 3. As the cathode, cathodes including metals having a small work function (4 eV or less) (these are referred to as electron injection metals), alloys, electroconductive compounds and mixtures thereof as electrode substances are used.

Specific examples of such electrode substances include sodium, sodium-potassium alloy, magnesium, lithium, magnesium/copper mixture, magnesium/silver mixture, magnesium/aluminum mixture, magnesium/indium mixture, aluminum/aluminum oxide (Al₂O₃) mixture, indium, lithium/aluminum mixture, rare earth metals and the like. Among these, mixtures of an electron injection metal and a second metal that has a larger work function value and is more stable than the electron injection metal such as magnesium/silver mixture, magnesium/aluminum mixture, magnesium/indium mixture, aluminum/aluminum oxide (Al₂O₃) mixture, lithium/aluminum mixture, aluminum and the like are preferable from the viewpoints of electron injection property and durability against oxidation and the like.

The cathode can be prepared by forming these electrode substances into a thin film by a method such as deposition or sputtering. Furthermore, the sheet resistance as a cathode is preferably several hundreds of Ω/sq. or less, and the film thickness is selected within a range of generally from 10 nm to 5 μm, preferably from 50 to 200 nm. In addition, in order to allow the transmission of the emitted light, it is convenient if either one of the anode or cathode of the organic EL element is transparent or translucent, since the light emitting luminance is improved.

Furthermore, a transparent or translucent cathode can be prepared by preparing the above-mentioned metal at a film thickness of from 1 to 20 nm on the cathode, and preparing the electroconductive transparent material that is exemplified in the explanation of the anode thereon, and an element in which both an anode and a cathode have permeability can be prepared by applying this.

In addition, in the case when this organic EL element 100 is such that the emitted light h is extracted also from the side of the cathode (counter electrode) 6, the counter electrode 6 may be constituted by selecting an electroconductive material having a fine light transmission property among the above-mentioned electroconductive materials.

<Auxiliary Electrode>

The auxiliary electrode 15 is provided for the purpose of decreasing the resistance of the transparent electrode 2, and is preferably disposed in contact with the electrode layer 2b of the transparent electrode 2. As the material for forming the auxiliary electrode 15, metals having a low resistance such as gold, platinum, silver, copper and aluminum are preferable. Since these metals have a low light transmission property, a pattern is formed in the scope that is not affected by the extraction of the emitted light h from a light extraction surface 13a.

As the method for forming such auxiliary electrode 15, a deposition process, a sputtering process, a printing process, an inkjet process, an aerosol jet process and the like are exemplified. The line width of the auxiliary electrode 15 is preferably 50 μm or less from the viewpoint of an aperture ratio for extraction of light, and the thickness of the auxiliary electrode 15 is preferably 1μ or more from the viewpoint of electroconductivity.

<Extraction Electrode>

The extraction electrode 16 electrically connects the transparent electrode 2 and the outer power source, and the material thereof is not specifically limited, and known materials are preferably used, and for example, metal films such as a MAM electrode (Mo/Al—Nd alloy/Mo) formed of a three-layer structure can be used.

<Light Emitting Unit>

The light emitting unit in the present invention refers to a light emitting body (unit) that is constituted by at least organic functional layers such as a light emitting layer, a hole transport layer and an electron transport layer which contain various organic compounds as major components. The light emitting body is sandwiched between a pair of electrodes formed of an anode and a cathode, and positive holes (holes) fed from the anode and electrons fed from the cathode bind again in the light emitting body to emit light.

The light emitting unit 3 used in the present invention is exemplified by, for example, a constitution in which the hole injection layer 3a/the hole transport layer 3b/the light emitting layer 3c/the electron transport layer 3d/the electron injection layer 3e are stacked in this order from the side of the transparent electrode 2 as an anode. The respective layers will be explained below in detail.

<Light Emitting Layer>

The light emitting layer 3c used in the present invention contains a phosphorescent compound as a light emitting material.

This light emitting layer 3c is a layer in which light is emitted by the re-bonding of electrons that are injected from the electrode or electron transport layer 3d and holes that are injected from the hole transport layer 3b, and the part where light is emitted may be either in the layer of the light emitting layer 3c or at the interface between the light emitting layer 3c and the adjacent layer.

The constitution of such light emitting layer 3c is not specifically limited as long as the light emitting material included therein satisfies requirements of light emission. Furthermore, there may be plural layers having the same light emission spectrum and the same light emitting local maximum wavelength. In this case, it is preferable that the respective light emitting layers 3c have a non-luminescent intermediate layer (not illustrated) therebetween.

The sum of the layer thicknesses of the light emitting layers 3c is preferably in the range of from 1 to 100 nm, and more preferably in the range of from 1 to 30 nm since a lower driving voltage can be obtained.

In the case when non-luminescent intermediate layers are present between the light emitting layers 3c, the sum of the layer thicknesses of the light emitting layers 3c is a layer thickness including the intermediate layers.

In the case of the light emitting layers 3c having a constitution in which plural layers are stacked, the layer thickness of the individual light emitting layer is preferably adjusted to be within the range of from 1 to 50 nm, more preferably adjusted to be within the range of from 1 to 20 nm. In the case when the stacked plural light emitting layers correspond to respective colors of light emission of blue, green and red, the relationship of the layer thicknesses of the respective light emitting layers of blue, green and red is not specifically limited.

The light emitting layer 3c as mentioned above can be formed by film formation of a light emitting material and a host compound, which are mentioned below, by a known method for forming thin film such as, vacuum vapor deposition, a spin coat process, a cast thin film process, An LB process or an inkjet process.

Furthermore, the light emitting layer 3c may be such that plural light emitting materials are mixed, or may be used by mixing a phosphorescent material and a fluorescence material (also referred to as a fluorescence dopant or a fluorescence compound) in the same light emitting layer 3c.

The constitution of the light emitting layer 3c preferably contains a host compound (also referred to as a light emitting host or the like) and a light emitting material (also referred to as a light emitting dopant) and emits light from the light emitting material.

(1) Host Compound

The host compound to be contained in the light emitting layer 3c is preferably a compound having a phosphorescence quantum yield of phosphorescence at room temperature (25° C.) of less than 0.1. More preferably, the phosphorescence quantum yield is less than 0.01. Furthermore, it is preferable that the host compound has a volume ratio in the light emitting layer 3c of 50% or more in the compounds contained in the layer.

As the host compound, a known host compound can be used singly, or plural known host compounds can be used. It is possible to adjust the transfer of the electrical charge by using plural kinds of host compounds, and the efficiency of the organic EL element 100 can be increased. Furthermore, it becomes possible to mix different emitted light by using the plural kinds of light emitting materials mentioned below, whereby an arbitrary color of light emission can be obtained.

The host compound to be used may be either a conventionally-known low molecular weight compound or a polymer compound having repeating units, or a low molecular compound having a polymerizable group such as a vinyl group or an epoxy group (deposition-polymerizable light emitting host).

As the known host compound, a compound that has hole transportability and electron transportability, and prevents the increase in the wavelength of light emission and has a high Tg (glass transition temperature) is preferable.

The glass transition point (Tg) herein is a value obtained by a method based on JIS K 7121 by using DSC (Differential Scanning Colorimetry).

As specific examples of the known host compound, the compounds described in the following documents can be used. For example, JP 2010-251675 A, JP 2001-257076 A, JP 2002-308855 A, JP 2001-313179 A, JP 2002-319491 A, JP 2001-357977 A, JP 2002-334786 A, JP 2002-8860 A, JP 2002-334787 A, JP 2002-15871 A, JP 2002-334788 A, JP 2002-43056 A, JP 2002-334789 A, JP 2002-75645A, JP 2002-338579 A, JP 2002-105445 A, JP 2002-343568 A, JP 2002-141173 A, JP 2002-352957 A, JP 2002-203683 A, JP 2002-363227 A, JP 2002-231453A, JP 2003-3165 A, JP 2002-234888 A, JP 2003-27048 A, JP 2002-255934 A, JP 2002-260861 A, JP 2002-280183 A, JP 2002-299060 A, JP 2002-302516 A, JP 2002-305083 A, JP 2002-305084 A, JP 2002-308837 A and the like are exemplified.

(2) Light Emitting Material

As the light emitting material that can be used in the present invention, phosphorescent light emitting compounds (also referred to as phosphorescent compounds or phosphorescent materials) and fluorescent light emitting compounds (also referred to as fluorescent compounds or fluorescent materials) are exemplified.

<<Phosphorescent Light Emitting Compound>>

The phosphorescent light emitting compound is a compound in which light emission from an excited triplet is observed, and is specifically defined as a compound that emits phosphorescent light at room temperature (25° C.) and has a phosphorescence quantum yield of 0.01 or more at 25° C., and a preferable phosphorescence quantum yield is 0.1 or more.

The above-mentioned phosphorescence quantum yield can be measured by the method described in The Fourth Series of Experimental Chemistry, Vol. 7, Spectroscopy II, page 398 (1992 edition, Maruzen). The phosphorescence quantum yield in the solution can be measured by using various solvents, and in the case when a phosphorescent compound is used in the present invention, it is sufficient that the above-mentioned phosphorescence quantum yield (0.01 or more) is achieved in any optional solvent.

There are two kinds of principles of the light emission of a phosphorescent light emitting compound. One is an energy transfer type in which an excitation state of a host compound in which a carrier is transferred is generated on the host compound by the re-bonding of the carrier, and the energy thereof is transferred to a phosphorescent light emitting compound, whereby light emission from the phosphorescent light emitting compound is obtained, and the other is a carrier trap type in which re-bonding of a carrier occurs on a phosphorescent light emitting compound by the action of the phosphorescent light emitting compound as a carrier trap, whereby light emission from the phosphorescent light emitting compound is obtained. In either case, the condition is such that the energy of the excited state of the phosphorescent light emitting compound is lower than the energy of the excited state of the host compound.

The phosphorescent light emitting compound can be suitably selected from known phosphorescent light emitting compounds that are used in a light emitting layer of a general organic EL element, and used, and compounds based on complexes containing metals of Groups 8 to 10 of the periodic table of elements are preferable, and iridium compounds, osmium compounds or platinum compounds (platinum complex-based compounds) or rare earth complexes are more preferable, and among these, iridium compounds are the most preferable.

In the present invention, at least one of the light emitting layers 3c may contain two or more kinds of phosphorescent light emitting compounds, and the concentration ratio of the phosphorescent light emitting compounds in the light emitting layer 3c may change in the thickness direction of the light emitting layer 3c.

The phosphorescent light emitting compound is preferably 0.1 volume % or more and less than 30 volume % with respect to the total amount of the light emitting layers 3c.

Furthermore, the phosphorescent light emitting compound can be suitably selected from known ones that are used in a light emitting layer of an organic EL element, and used.

As specific examples of the phosphorescent light emitting compound in the present invention, the compounds described in JP 2010-251675 A can be used, but the present invention is limited by these.

<<Fluorescent Light Emitting Compound>>

As the fluorescent light emitting compound, coumarin-based dyes, pyran-based dyes, cyanine-based dyes, chloconium-based dyes, squarylium-based dyes, oxobenzoanthracene-based dyes, fluorescein-based dyes, rhodamine-based dyes, pyrylium-based dyes, perylene-based dyes, stilbene-based dyes, polythiophene-based dyes or rare earth complex-based phosphors and the like are exemplified.

<Injection Layer: Hole Injection Layer and Electron Injection Layer>

The injection layer is a layer that is disposed between the electrode and the light emitting layer 3c for decreasing the driving voltage and for improving the light emitting luminance, and is described in detail in “Organic EL Elements And Industrialization Front Line Thereof (Nov. 30, 1998, published by NTS)”, 2^{nd} edition, Chapter 2, “Electrode Material” (pages 123 to 166), and there are the hole injection layer 3a and the electron injection layer 3e.

The injection layer can be provided as necessary. The hole injection layer 3a may be allowed to present between the anode and the light emitting layer 3c or the hole transport layer 3b, and the electron injection layer 3e may be allowed to present between the cathode and the light emitting layer 3c or the electron transport layer 3d.

The details of the hole injection layer 3a are also described in JP 9-45479 A, JP 9-260062 A and JP 8-288069 A and the like, and specific examples include phthalocyanine layers as represented by copper phthalocyanine, oxide layers as represented by vanadium oxide, amorphous carbon layers, polymer layers using electroconductive polymers such as polyaniline (emeraldine) and polythiophene, and the like.

The details of the electron injection layer 3e are also described in JP 6-325871 A, JP 9-17574 A and JP 10-74586 A and the like, and specific examples include metal layers as represented by strontium, aluminum and the like, alkali metal halide layers as represented by potassium fluoride, alkali earth metal compound layers as represented by magnesium fluoride, oxide layers as represented by molybdenum oxide, and the like. It is desirable that the electron injection layer 3e in the present invention is a layer formed of a quite thin film, and the layer thickness thereof is preferably within the range of from 1 nm to 10 μm depending on the material thereof.

<Hole Transport Layer>

The hole transport layer 3b is formed of a hole transport material that has a function to transport holes, and the hole injection layer 3a and the electron blocking layer are also encompassed in the hole transport layer 3b in a broad sense. The hole transport layer 3b can be provided as a single layer or plural layers.

The hole transport material has either a property to inject or transport holes, or a barrier property against electrons, and may either an organic substance or an inorganic substance. Examples include triazole derivatives, oxadiazole derivatives, imidazole derivatives, polyarylalkane derivatives, pyrazoline derivatives and pyrazolone derivatives, phenylenediamine derivatives, arylamine derivatives, amino-substituted calcone derivatives, oxazole derivatives, styrylanthracene derivatives, fluorenone derivatives, hydrazone derivatives, stilbene derivatives, silazane derivatives, aniline-based copolymers, oligomers of electroconductive polymers, specifically thiophene oligomer, and the like.

As the hole transport material, the above-mentioned hole transport materials can be used, and it is preferable to use porphyrin compounds, aromatic tertiary amine compounds and styrylamine compounds, specifically aromatic tertiary amine compounds.

Typical examples of the aromatic tertiary amine compound and styrylamine compounds include N,N,N′,N′-tetraphenyl-4,4′-diaminophenyl, N,N′-diphenyl-N,N′-bis(3-methylphenyl)-[1,1′-biphenyl]-4,4′-diamine (TPD), 2,2-bis(4-di-p-tolylaminophenyl)propane, 1,1-bis(4-di-p-tolylaminophenyl)cyclohexane, N,N,N′,N∝0-tetra-p-tolyl-4,4′-diaminobiphenyl, 1,1-bis(4-di-p-tolylaminophenyl)-4-phenylcyclohexane, bis(4-dimethylamino-2-methylphenyl)phenylmethane, bis(4-di-p-tolylaminophenyl)phenylmethane, N,N′-diphenyl-N,N′-di(4-methoxyphenyl)-4,4′-diaminobiphenyl, N,N,N′,N′-tetraphenyl-4,4′-diaminodiphenyl ether, 4,4′-bis(diphenylamino)quadryphenyl, N,N,N-trip-tolyl)amine, 4-(di-p-tolylamino)-4′-[4-(di-p-tolylamino)styryl]stilbene, 4-N,N-diphenylamino-(2-diphenylvinyl)benzene, 3-methoxy-4′-N,N-diphenylaminostilbenzene, N-phenylcarbazole, and those having two condensed aromatic rings in the molecule described in U.S. Pat. No. 5,061,569 A such as 4,4′-bis[N-(1-naphthyl)-N-phenylamino]biphenyl (NPD), 4,4′,4″-tris [N-(3-methylphenyl)-N-phenylamino]triphenylamine (MTDATA) in which three triphenylamine units are connected in a starburst form described in JP 4-308688 A, and the like.

Furthermore, polymer materials in which these materials are introduced in the polymer chain or using these materials as the polymer main chain can also be used. Furthermore, inorganic compounds such as p-type-Si and p-type-SiC can also be used as the hole injection material and the hole transport material.

Furthermore, so-called p-type hole transport materials as described in JP 11-251067 A and J. Huang et. al., Applied Physics Letters, 80 (2002), p. 139 can also be used. In the present invention, it is preferable to use these materials since a light emitting element having a higher efficiency can be obtained.

The hole transport layer 3b can be formed by forming the above-mentioned hole transport material into a thin film by a known method such as vacuum vapor deposition, a spin coat process, a cast process, a printing process including an inkjet process or An LB process. The layer thickness of the hole transport layer 3b is not specifically limited, and is generally within the range of from about 5 nm to 5 μm, preferably from 5 to 200 nm. This hole transport layer 3b may have a monolayer structure formed of one kind or two or more kinds of the above-mentioned materials.

Furthermore, the p-property can be increased by doping the material of the hole transport layer 3b with an impurity. The examples thereof include those described in JP 4-297076A, JP 2000-196140 A and JP 2001-102175 A, J. Appl. Phys., 95, 5773 (2004), and the like.

It is preferable to increase the p-property of the hole transport layer 3b by this way since an element that consumes a lower electrical power can be prepared.

<Electron Transport Layer>

The electron transport layer 3d is formed of a material having a function to transport electrons, and the electron injection layer 3e and the hole blocking layer (not illustrated) are also encompassed in the electron transport layer 3d in a broad sense. The electron transport layer 3d can be provided as a monolayer structure or a stack structure of plural layers.

In the electron transport layer 3d having a monolayer structure and the electron transport layer 3d having a stacked structure, as the electron transport material that constitutes the layer part that is adjacent to the light emitting layer 3c (this also serves as a hole blocking material), it is sufficient to have a function to transmit electrons that are injected from the cathode to the light emitting layer 3c. Such material can be optionally selected from conventionally-known compounds and used.

Examples include nitro-substituted fluorene derivatives, diphenylquinone derivatives, thiopyrandioxide derivatives, carbodiimide, fluorenylidene methane derivatives, anthraqunodimethane, anthrone derivatives and oxadiazole derivatives, and the like. Furthermore, in the above-mentioned oxadiazole derivatives, thiadiazole derivatives in which the oxygen atom of the oxadiazole ring has been substituted with a sulfur atom, and quinoxaline derivatives having a quinoxaline ring, which is known as an electron withdrawing group, can also be used as the materials for the electron transport layer 3d. In addition, polymer materials in which these materials have been introduced in the polymer chain, or polymer materials using these materials as the polymer main chain can also be used.

Furthermore, metal complexes of 8-quinolinol derivatives such as tris(8-quinolinol)aluminum (Alq₃), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum, bis(8-quinolinol)zinc (Znq) and the like, and metal complexes in which the center metals in these metal complexes have been replaced with In, Mg, Cu, Ca, Sn, Ga or Pb can also be used as the materials for the electron transport layer 3d.

In addition, metal-free or metal phthalocyanines, or metal-free or metal phthalocyanines whose terminals have been substituted with alkyl groups, sulfonic acid groups or the like can also be preferably used as the materials for the electron transport layer 3d. Furthermore, distyrylpyrazine derivatives, which are also used as the materials for the light emitting layer 3c, can also be used as the materials for the electron transport layer 3d, and inorganic semiconductors such as n-type-Si and n-type-SiC can also be used as the materials for the electron transport layer 3d as in the hole injection layer 3a and hole transport layer 3b.

The electron transport layer 3d can be formed by forming the above-mentioned material into a thin film by a known method such as vacuum vapor deposition, a spin coat process, a cast process, print processes including an inkjet process, and an LB process. The layer thickness of the electron transport layer 3d is not specifically limited, and is generally within the range of from about 5 nm to 5 μm, preferably from 5 to 200 nm. The electron transport layer 3d may also be a monolayer structure formed of one kind or two or more kinds of the above-mentioned materials.

Furthermore, an impurity can be doped on the electron transport layer 3d to increase the n-property. Examples thereof include those described in JP 4-297076 A, JP 10-270172 A, JP 2000-196140 A, JP 2001-102175 A, J. Appl. Phys., 95, 5773 (2004) and the like. Furthermore, it is also preferable that the electron transport layer 3d contains potassium, a potassium compound or the like. As the potassium compound, for example, potassium fluoride and the like can be used. By increasing the n-property of the electron transport layer 3d by this way, an element that consumes a lower electrical power can be prepared.

Furthermore, as the material (electron transporting compound) for the electron transport layer 3d, a material that is similar to the material that constitutes the above-mentioned primer layer 2a can be used. The same applies to the electron transport layer 3d that also acts as the electron injection layer 3e, and a material that is similar to the material that constitutes the above-mentioned primer layer 2a may also be used.

<Blocking Layer: Hole Blocking Layer, Electron Blocking Layer>

As mentioned above, the blocking layer is provided as necessary besides the elemental constitution layers of the organic compound thin film. Examples include the hole block layers described in JP 11-204258 A and JP 11-204359 A, and page 237 of “Organic EL Elements And Industrialization Front Line Thereof (Nov. 30, 1998, published by NTS)”, and the like.

The hole blocking layer has the function of the electron transport layer 3d in a broad sense. The hole blocking layer is formed of a hole blocking material that has a function to transport electrons and a significantly small ability to transport holes, and thus can improve the probability of the re-bonding of electrons and holes by blocking holes while transporting electrons. Furthermore, the constitution of the electron transport layer 3d can be used as the hole blocking layer as necessary. It is preferable that the hole blocking layer is provided adjacent to the light emitting layer 3c.

On the other hand, the electron blocking layer has the function of the hole transport layer 3b in a broad sense. The electron blocking layer is formed of a material that has a function to transport holes and a significantly small ability to transport electrons, and thus can improve the probability of the re-bonding of electrons and holes by blocking electrons while transporting holes. Furthermore, the constitution of the hole transport layer 3b can be used as the electron blocking layer as necessary. The layer thickness of the hole blocking layer is preferably within the range of from 3 to 100 nm, further preferably within the range of from 5 to 30 nm.

<Sealing Material>

The sealing material 17 covers the organic EL element 100, and may be fixed on the side of the film substrate 4 by an adhesive 19 with a plate-shaped (film-shaped) seal element, or may be a seal film. Such sealing material 17 is provided in the state that the terminal parts of the transparent electrode 2 and the counter electrode 6 in the organic EL element 100 are exposed and at least the light emitting unit 3 is covered. Alternatively, the sealing material 17 may be constituted by providing an electrode to the sealing material 17 so that the terminal parts of the transparent electrode 2 and the counter electrode 6 of the organic EL element 100 and this electrode are in conduction.

Specific examples of the plate-shaped (film-shaped) sealing material 17 include glass substrates, polymer substrates, metal substrates and the like, and these substrate materials may further be formed into a thinner film shape and used. Specific examples of the glass substrate can include soda lime glass, barium-strontium-containing glass, lead glass, aluminosilicate glass, borosilicate glass, barium borosilicate glass, quartz and the like. Furthermore, examples of the polymer substrates can include polycarbonate, acrylic, polyethylene telephthalate, polyether sulfide, polysulfone and the like. Examples of the metal substrates include those formed of one or more kind of metals or alloys selected from the group consisting of stainless, iron, copper, aluminum, magnesium, nickel, zinc, chromium, titanium, molybdenum, silicon, germanium and tantalum.

Among these, polymer substrates and metal substrates that have been formed into thin film shapes can be preferably used as the sealing material since the element can be formed into a thin film.

Furthermore, it is preferable that the film-shaped polymer substrate has an oxygen permeation degree measured by a method based on JIS K 7126-1987 of 1×10⁻³ ml/m²·24 h·atm or less, and a water vapor permeation degree measured by a method based on JIS K 7129-1992 (25±0.5° C., relative humidity (90±2)% RH) of 1×10⁻³ g/m²·24 h or less.

Furthermore, the substrate material as mentioned above may also be used as the sealing material 17 by processing into a recessed plate-shape. In this case, the above-mentioned substrate element is subjected to a processing such as a sand blast processing or a chemical etching processing, whereby the recessed-shape is formed.

Furthermore, the adhesive 19 for fixing such plate-shaped sealing material 17 on the side of the film substrate 4 is used as a sealing agent for sealing the organic EL element 100 that is sandwiched between the sealing material 17 and the film substrate 4. Specific examples of such adhesive 19 can include adhesives such as photocurable and thermosetting adhesives having reactive vinyl groups such as acrylic acid-based oligomers and methacrylic acid-based oligomers, and moisture curable adhesives such as 2-cyanoacrylic acid ester.

Furthermore, examples of such adhesive 19 include thermal and chemical curable (two-liquid mixing) adhesives such as epoxy-based adhesives. Furthermore, hot-melt type polyamides, polyesters and polyolefins can also be exemplified. In addition, cation-curable ultraviolet curable epoxy resin adhesives can be exemplified.

Meanwhile, the organic materials that constitute the organic EL element 100 may be deteriorated by a heat treatment. Therefore, the adhesive 19 is preferably an adhesive being capable of adhesion and curing at from room temperature to 80° C. Furthermore, it is also preferable to disperse a desiccant in the adhesive 19 in advance.

A commercially available dispenser can be used for applying the adhesive 19 onto the adhesion part between the sealing material 17 and the film substrate 4, or the adhesive 19 can be printed as in screen printing.

Furthermore, in the case when gaps are formed between the plate-shaped sealing material 17 and film substrate 4, and the adhesive 19, it is preferable to inject inert gases such as nitrogen and argon, and inert liquids such as fluorohydrocarbons and silicon oils in between the gaps in gas and liquid phases. Furthermore, it is possible to make the gaps vacuum. Alternatively, it is also possible to enclose a hygroscopic compound inside.

Examples of the hygroscopic compound include metal oxides (for example, sodium oxide, potassium oxide, calcium oxide, barium oxide, magnesium oxide, aluminum oxide and the like), sulfate salts (for example, sodium sulfate, calcium sulfate, magnesium sulfate, cobalt sulfate and the like), metal halides (for example, calcium chloride, magnesium calcium, cesium fluoride, tantalum fluoride, cerium bromide, magnesium bromide, barium iodide, magnesium iodide and the like), perchloric acids (for example, barium perchlorate, magnesium perchlorate and the like) and the like, anhydrous salts are preferably used in the sulfate salts, metal halides and perchloric acids.

On the other hand, in the case when a seal film is used as the sealing material 17, a seal film is disposed on the film substrate 4 in the state that the light emitting unit 3 in the organic EL element 100 is completely covered and the terminal parts of the transparent electrode 2 and the counter electrode 6 in the organic EL element 100 are exposed.

Such seal film is constituted by using an inorganic material or an organic material. Specifically, the seal film is constituted by a material that has a function to suppress the entering of substances that lead to the deterioration of the light emitting unit 3 in the organic EL element 100 such as moisture and oxygen. As such material, for example, inorganic materials such as silicon oxide, silicon dioxide and silicon nitride are used. Furthermore, in order to improve the brittleness of the seal film, it is possible to form a stacked structure by using a film formed of an organic material together with films formed of these inorganic materials.

The method for forming these films is not specifically limited, and for example, vacuum vapor deposition, a sputtering process, a reactive sputtering process, a molecular beam epitaxy process, a cruster ion beam process, ion plating, a plasma polymerization process, an atmospheric pressure plasma polymerization process, a plasma CVD process, a laser CVD process, a thermal CVD process, a coating process and the like can be used.

<Protective Film, Protective Plate>

In addition, a protective film or a protective plate, the illustration herein is omitted, may also be provided with intervening the organic EL element 100 and the sealing material 17 between the protective film or protective plate and the film substrate 4. This protective film or protective plate is for mechanically protecting the organic EL element 100, and specifically in the case when the sealing material 17 is a seal film, since the mechanical protection against the organic EL element 100 is not sufficient, it is preferable to provide such protective film or protective plate.

As the protective film or protective plate as mentioned above, a glass plate, a polymer plate, a polymer film that is thinner than this polymer plate, a metal plate, a metal film that is thinner than this metal plate, or a polymer material film or a metal material film is applied. Among these, it is specifically preferable to use a polymer film since it is light and is a thin film.

<Method for Producing Organic EL Element>

Here, as an example, the method for producing the organic EL element 100 shown in FIG. 1 will be explained.

Firstly, a resin material solution in which particles having an average particle diameter of 0.2 μm or more are dispersed is applied onto the film substrate 4, and the light scattering layer 7 is formed. Subsequently, a resin material solution in which particles having an average particle diameter within the range of from 5 to 70 nm are dispersed is applied onto the light scattering layer 7, and the smooth layer 1 is prepared.

Subsequently, for example, the primer layer 2a formed of a compound containing a nitrogen atom is formed on the smooth layer 1 so as to have a layer thickness within the range of 1 μm or less, preferably from 10 to 100 nm, by a suitable method such as a deposition process.

Subsequently, the electrode layer 2b formed of silver (or an alloy containing silver as a major component) is formed on the primer layer 2a so as to have a layer thickness of 12 nm or less, preferably from 4 to 9 nm by a suitable method such as a deposition process, whereby the transparent electrode 2 as an anode is prepared. Simultaneously, the extraction electrode 16, which is connected to an outer power source, is formed on the end part of the transparent electrode 2 by a suitable method such as a deposition process.

Subsequently, the hole injection layer 3a, the hole transport layer 3b, the light emitting layer 3c, the electron transport layer 3d and the electron injection layer 3e are formed thereon in this order to thereby form the light emitting unit 3. As the formation of each of these layers, a spin coat process, a cast process, an inkjet process, a deposition process, a printing process and the like are exemplified, and vacuum vapor deposition or a spin coating process is specifically preferable from the points that a homogeneous film is easily obtained and pinholes are difficult to be formed. Furthermore, different film formation processes may be applied to every layer. In the case when a deposition process is adopted for the film formation of these respective layers, the deposition conditions differ depending on the kinds of the compounds used, and the like, and it is generally desirable to suitably select the respective conditions within the ranges of: a boat heating temperature of from 50 to 450° C., a vacuum degree of from 1×10⁻⁶ to 1×10⁻² Pa, a deposition velocity of from 0.01 to 50 nm/sec, a substrate temperature of from −50 to 300° C. and a layer thickness of from 0.1 to 5 μm.

After forming the light emitting unit 3 as mentioned above, the counter electrode 6, which becomes a cathode, is formed on the upper part thereof by a suitable film formation process such as a deposition process or a sputtering process. At this time, the counter electrode 6 is formed into a shape in which terminal parts are drawn from the upper side of the light emitting unit 3 on the peripheral edge of the film substrate 4 while an insulated state against the transparent electrode 2 is kept by the light emitting unit 3. By this way, the organic EL element 100 is obtained. Furthermore, subsequently, a sealing material 17 that covers at least the light emitting unit 3 is provided in the state that the terminal parts of the transparent electrode 2 (extraction electrode 16) and counter electrode 6 in the organic EL element 100 are exposed.

By the above-mentioned way, a desired organic EL element 100 is obtained on the film substrate 4. In the preparation of such organic EL element 100, it is preferable to prepare from the light emitting unit 3 to the counter electrode 6 in a consistent manner by a single vacuuming, but it is also possible to remove the film substrate 4 from the vacuum atmosphere in midstream and subject the film substrate 4 to a different film formation process. During that process, considerations such as conducting the operations under a dry inert gas atmosphere are required.

In the case when a direct current voltage is applied to the organic EL element 100 obtained by this way, when a voltage of about 2 to 40 V is applied with deeming that the transparent electrode 2 as an anode has polarity of + and the counter electrode 6 as a cathode has polarity of −, light emission can be observed. Alternatively, it is also possible to apply an alternate current voltage. The wave form of the alternate current to be applied may be arbitrary.

<Effect of Organic EL Element>

The preferable aspect of the organic EL element 100 of the present invention explained above is a constitution in which the gas barrier layer 5, the light scattering layer 7 and the smooth layer 1 are provided to between the transparent electrode 2 having both electroconductivity and light transmission property and the film substrate 4. By this way, the total reflection loss between the transparent electrode 2 and the film substrate 4 can be decreased, and thus the light emitting efficiency can be improved.

Furthermore, the organic EL element 100 has a constitution in which the transparent electrode 2 is used as an anode, and the light emitting unit 3 and the counter electrode 6 as a cathode are provided to the upper part of the transparent electrode 2. Therefore, it is possible to apply a sufficient voltage to between the transparent electrode 2 and the counter electrode 6 to thereby attain light emission at a high luminance in the organic EL element 100 and increase the luminance by the improvement of the extracting efficiency of the emitted light h from the side of the transparent electrode 2. Furthermore, it also becomes possible to improve a light emission lifetime by decreasing a driving voltage for obtaining a predetermined luminance.

<Use of Organic EL Element>

Since the organic EL element 100 having the above-mentioned each constitution is a plane light emitting body as mentioned above, it can be used as various light emission sources. Examples include, but are not limited to, lighting devices such as household lighting and in-car lighting, backlights for clocks and liquid crystals, lightings for signboard advertisement, light sources for traffic lights, light sources for optical memory media, light sources for electrophotographic copying machines, light sources for optical communication processors, light sources for light sensors, and the like, and specifically, the organic EL element 100 can be effectively used for use in backlights for liquid crystal display devices in combination with color filters, and use as light sources for lightings.

Furthermore, the organic EL element 100 of the present invention may be used as a kind of lamp such as a lamp for lighting and a light source for exposing to light, or may be used as a projection device of a type in which an image is projected, or a display device (display) of a type in which a still image or an active image is directly and visually recognized. In this case, according to the upsizing of lighting devices and displays in recent years, the surface area of a light emitting plane can be increased by joining light emitting panels provided with the organic EL elements 100 in a planar manner, so-called tiling.

The driving system in the case of use as a display device for video replay may be either a simple matrix (passive matrix) system or an active matrix system. Furthermore, it is possible to prepare a color or full-color display device by using two or more kinds of the organic EL elements 100 of the present invention having different colors of light emission.

A lighting device will be explained below as an example of use, and a lighting device with a light emitting plane whose surface area has been increased by tiling will be subsequently explained.

<Lighting Device>

The organic EL element 100 of the present invention can be applied to a lighting device.

The lighting device using the organic EL element 100 of the present invention may have a design in which each organic EL element in the above-mentioned constitution is provided with a resonator structure. Examples of the purposes of the organic EL element 100 constituted as a resonator structure include, but are not limited to, a light source for an optical memory medium, a light source for an electrophotographic copying machine, a light source for an optical communication processor, a light source for a light sensor, and the like. Furthermore, the organic EL element 100 may be used for the above-mentioned uses by conducting laser oscillation.

In addition, the material used in the organic EL element 100 of the present invention can be applied to an organic EL element that causes emission of substantially white light (also referred to as a white organic EL element). For example, emission of white light can also be obtained by mixing colors by simultaneously emitting colors of plural light emission by plural light emitting materials. The combination of plural colors of light emission may contain three light emitting local maximum wavelengths of three elementary colors of red, green and blue, or may contain two light emitting local maximum wavelengths utilizing the relationship of complementary colors such as blue and yellow, and blue green and orange.

Furthermore, the combination of the light emitting materials for obtaining plural colors of light emission may be either of a combination of plural materials that emit lights with plural phosphorescent lights or fluorescent lights, and a combination of a light emitting material that emits light with fluorescent light or phosphorescent light and a color material that emits light from a light emitting material as excited light, and plural light emitting dopants may be combined and mixed in the white organic EL element.

In such white organic EL element, the organic EL element itself emits white light, unlike a constitution in which emission of white light is obtained by individually disposing organic EL elements that emit lights of respective colors in parallel in an array form. Therefore, a mask is not required for the film formation of the most of the layers that constitute the element, and a film can be formed all over by a deposition process, a cast process, a spin coat process, an inkjet process, a printing process or the like, and the producibility is also improved.

Furthermore, the light emitting material used for the light emitting layer in such white organic EL element is not specifically limited, and for example, if it is a backlight in a liquid crystal display element, optionally materials may be selected from the above-mentioned metal complexes and known light emitting materials so as to conform to the wavelength range corresponding to CF (color filter) properties and combined to make the emitted light white.

If the white organic EL element explained above is used, it is possible to prepare a lighting device that emits substantially white light.

### EXAMPLES

The present invention will be specifically explained below with referring to Examples, but the present invention is not limited to these. In Examples, indication of “parts” or “%” is used, and unless specifically mentioned, the indication represents “parts by mass” or “% by mass”.

Furthermore, in the case when the smooth layer 1 is formed of a single material, the average refractive index of the smooth layer 1 is a refractive index of the single material, and in the case of a mixed system, the average refractive index is a calculated refractive index that is calculated from a combined value by multiplying the refractive indices that are inherent to the respective materials by a mixing ratio. When the light scattering layer 7 is formed of a single material, the binder refractive index of the light scattering layer 7 is the refractive index of the single material, and when the light scattering layer 7 is a mixed system, the binder refractive index is a calculated refractive index that is calculated from a combined value by multiplying the refractive indices that are inherent to the respective materials by a mixing ratio. Similarly to the particle refractive index of the light scattering layer 7, in the case when the light scattering layer 7 is formed of a single material, the particle refractive index is the refractive index of the single material, and in the case of a mixed system, the particle refractive index is a calculated refractive index that is calculated from a combined value by multiplying the refractive indices that are inherent to the respective materials by a mixing ratio. The average refractive index of the light scattering layer 7 is a calculated refractive index that is calculated from a combined value by multiplying the refractive indices that are inherent to the respective materials by a mixing ratio.

Furthermore, “total thickness” in Tables represents the total thickness of the smooth layer 1 and the light scattering layer 7. Furthermore, “particle diameter” of “light scattering layer” in Tables represents the average particle diameter of the particles used in the light scattering layer, and in the case when the light scattering layer is made by using plural kinds of particles, the particle diameter represents the average particle diameter of the particles having a larger average particle diameter.

### Example 1

### Light emitting panel No. 1

### Comparative Example

### Preparation of Sample

### (1) Preparation of Film Substrate and Gas Barrier Layer

(1-1) Film Substrate

As a film substrate, a biaxially-stretched polyethylene naphthalate film (a PEN film, thickness: 100 μm, width: 350 mm, manufactured by Teijin DuPont Films Japan Limited, commercial product name “Teonex Q65FA”) was used.

(1-2) Preparation of Primer Layer

A UV curable organic-inorganic hybrid hard coat material OPSTAR Z7501 manufactured by JSR Corporation was applied with a wire bar onto an easily-adhesive surface of a film substrate so that the dry layer thickness became 4 μm, dried under drying conditions; 80° C. and 3 min, and cured under an air atmosphere by using a high pressure mercury lamp at a curing condition; 1.0 J/cm², whereby a primer layer (also referred to as “primer layer”) was formed.

The maximum cross-sectional surface height Ra (p) that represents the surface roughness at that time was 5 nm.

The surface roughness (arithmetic average roughness Ra) was calculated from a cross-sectional surface curve of the recess-projection, which was continuously measured by a detector having a stylet with a minimum tip radius by using an AFM (Atomic Force Microscope: manufactured by Digital Instruments); the region in which the measurement direction was 30 μm was measured three times by the stylet with a minimum tip radius, and the surface roughness was obtained from an average roughness relating to the amplitude of the fine recess-projection.

(1-3) Preparation of First Gas Barrier Layer

A film substrate was attached to a CVD device, and a first gas barrier layer was prepared at a thickness of 300 nm on the film substrate 4 under the following film formation conditions (plasma CVD conditions) so as to have the respective element profiles shown in FIG. 5.

The first gas barrier layer satisfied the following properties.

(i) The silicon atomic ratio, the oxygen atomic ratio and the carbon atomic ratio have the following magnitude relationship from the surface to the area at a distance of 90% or more in the layer thickness direction of the above-mentioned first gas barrier layer.

(carbon atomic ratio)<(silicon atomic ratio)<(oxygen atomic ratio)

(ii) The carbon distribution curve has at least two extremal values.

(iii) The absolute value of difference between the maximum value and minimum value of the carbon atomic ratio in the carbon distribution curve is 5 at % or more.

(iv) In the oxygen distribution curve, the local maximum value of the oxygen distribution curve which is the closest to the surface of the first gas barrier layer at the side of the film substrate is the maximum value among the local maximum values of the oxygen distribution curve in the gas barrier layer.

<Conditions for Film Formation>

Feed amount of raw material gas (hexamethyldisilozane (HMDSO, (CH₃)₆SiO)): 50 sccm (Standard Cubic Centimeter per Minute)

Feed amount of oxygen gas (O₂): 500 sccm

Vacuum degree in vacuum chamber: 3 Pa

Electrical power applied from power source for plasma generation: 0.8 kW

Frequency of power source for plasma generation: 80 kHz

Transportation velocity of film: 0.5 to 1.66 m/min

(1-4) Preparation of Second Gas Barrier Layer

A 10% by mass dibutyl ether solution of perhydropolysilazane (AQUAMIKA NN120-10, catalyst-free type, manufactured by AZ Electronic Materials) was used as an application liquid.

The above-mentioned application liquid was applied by a wire bar so that the dried (average) layer thickness became 300 nm, dried by treating under an atmosphere at a temperature of 85° C. and a humidity of 55% RH for 1 minute, further retained under an atmosphere at a temperature of 25° C. and a humidity of 10% RH (dew point temperature −8° C.) for 10 minutes, and subjected to a dehumidication treatment, whereby a second gas barrier layer was formed.

The polysilazane layer formed as above was subjected to a silica-inversion treatment under an atmospheric pressure by using the following ultraviolet ray device.

<Ultraviolet Ray Irradiation Device>

Device: excimer irradiation MODEL manufactured by M. D. COM, Inc. MODEL: MECL-M-1-200

Irradiation wavelength: 172 nm

Gas enclosed in lamp: Xe

### <Conditions for Modification Treatment>

A modification treat was conducted under the following conditions on the substrate with the polysilazane layer formed thereon fixed on an operation stage, whereby a gas barrier layer was formed.

Excimer lamp light intensity: 130 mW/cm² (172 nm)

Distance between sample and light source: 1 mm

Stage heating temperature: 70° C.

Oxygen concentration in irradiation device: 1.0%

Excimer lamp irradiation time: 5 seconds

The compositions or distribution states of the respective constitutional elements of these first gas barrier layer and second gas barrier layer were different.

### (2) Preparation of Light Scattering Layer and Smooth Layer

(2-1) Preparation of Light Scattering Layer

As a substrate, a substrate obtained by cutting the film substrate obtained in (1) into 50×50 mm, washing with ultrapure water and drying with a clean drier was used.

Subsequently, a light scattering layer preparation liquid was formulated and designed at a ratio of 10 ml amount so that the solid content ratio of TiO₂ particles having a refractive index (np) of 2.4 and an average particle diameter of 0.25 μm (JR600A manufactured by TAYCA CORPORATION) to a resin solution (ED230AL (an organic-inorganic hybrid resin) manufactured by APM) became 30 vol %/70 vol %, the solvent ratio of n-propylacetate to cyclohexanone became 10% by mass/90% by mass, and the solid content concentration became 15% by mass.

Specifically, the above-mentioned TiO₂ particles and the solvent were mixed, and the mixture was dispersed in an ultrasonic dispersing machine (UH-50 manufactured by SMT CO., LTD.) under standard conditions of a microchip step (MS-3 manufactured by SMT CO., LTD., 3 mm in diameter) for 10 minutes while the mixture was cooled under an ordinary temperature, whereby a dispersion liquid of TiO₂ was prepared.

Subsequently, the above-mentioned resin solution was added in small portions under mixing while the TiO₂ dispersion liquid was stirred at 100 rpm, and after the addition was completed, the stirring velocity was increased to 500 rpm, and mixing was conducted for 10 minutes, whereby an application liquid for a light scattering layer was obtained.

Subsequently, the application liquid was filtered by a hydrophobic PVDF 0.45 μm filter (manufactured by Whatman), whereby an intended dispersion liquid was obtained.

The above-mentioned dispersion liquid was applied under rotation by spin application (500 rpm, 30 seconds) on the film substrate, subjected to simplified drying (80° C., 2 minutes) and further heated (120° C., 60 minutes), whereby a light scattering layer having a layer thickness of 0.5 μm was formed. The refractive index nb of the binder (resin) in the light scattering layer was 1.5, the particle refractive index np was 2.4, and the average refractive index ns was 1.77.

In the light emitting panel 1, the smooth layer 1 was not prepared.

### (3) Preparation of Anode (Transparent Electrode)

The film substrate obtained in the above-mentioned step of (2) was superposed with a mask having an opening of width 20 mm×50 mm and fixed on a substrate holder of a commercially available sputtering device, and the pressure in the vacuum bath was reduced to 4×10⁻⁴ Pa. Subsequently, the substrate was transferred to a first vacuum layer, Ar gas was introduced, and a surface treatment was conducted at RF-100 W for 30 seconds.

The treated substrate was then transferred under the same vacuum to a second vacuum bath in which a indium tin oxide (ITO) target had been installed, the pressure in the second vacuum bath was reduced to 4×10⁻⁴ Pa, deposition was conducted at DC-500 W for 130 seconds, whereby an ITO film was formed. By this way, a transparent electrode made of ITO with a pattern of 20×50 mm was prepared.

### (4) Preparation of Light Emitting Panel

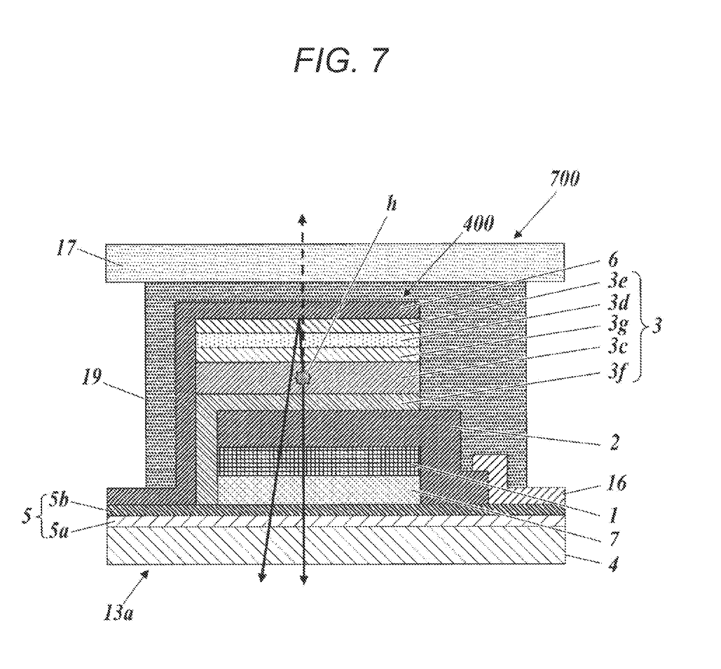

The procedures of the preparation will be explained below with referring to FIG. 7. An organic EL element 400 was prepared by using the transparent electrode prepared in the above-mentioned (3) as an anode, and providing a light emitting unit onto the anode. Furthermore, a sealing material 17 was adhered to the organic EL element 400, whereby a light emitting panel 700 was prepared. The organic EL element 400 shown in FIG. 7 is approximately similar to the organic EL element 100 shown in FIG. 1, and the different points will be explained below.

(4-1) Preparation of Light Emitting Panel

Firstly, the film substrate 4 on which the transparent electrode and the like had been provided, which was prepared in (3), was superposed with a mask having an opening of width 30 mm×30 mm on the center part, and fixed on a substrate holder of a commercially available vacuum deposition device. Furthermore, the respective materials for constituting the light emitting unit 3 were filled in respective heating boats in the vacuum deposition device at the optimal amounts for the film formation of the respective layers. As the heating boats, heating boats prepared by a material made of tungsten for resistance heating were used.

Subsequently, the pressure in the deposition chamber of the vacuum deposition device was reduced to a vacuum degree of 4×10⁻⁴ Pa, and the respective layers were formed as follows by sequentially heating the heating boats containing the respective materials therein by energization.

Firstly, the heating boat containing therein α-NPD, which is shown in the following structural formula, as a hole transport-injection material was heated by energization, whereby a hole transport-injection layer formed of α-NPD, which serves as a hole injection layer and a hole transport layer, was formed on the transparent electrode 2. At this time, the deposition velocity was 0.1 to 0.2 nm/sec, and the layer thickness was 20 nm.

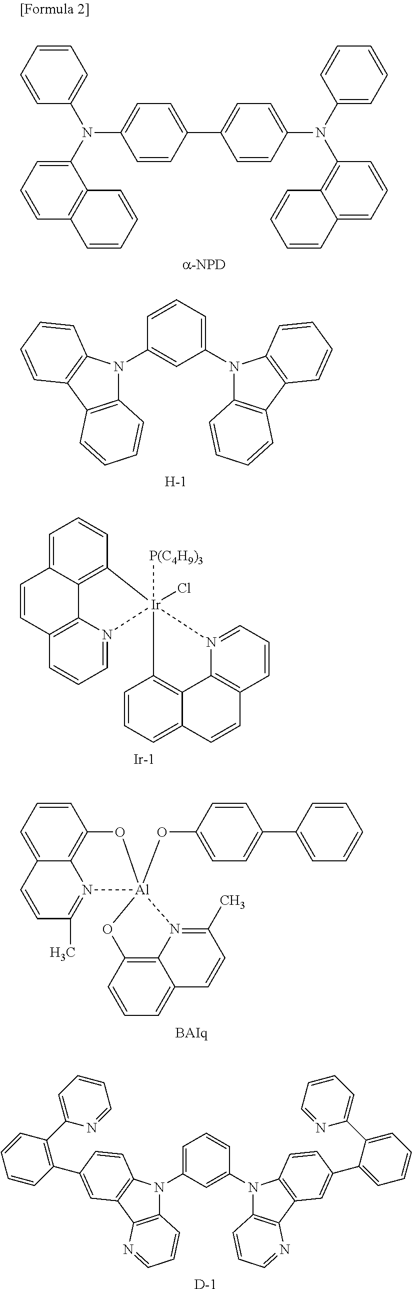

Subsequently, the heating boat containing therein host material H-1, which is shown in the above-mentioned structural formula, and the heating boat containing therein phosphorescent light emitting compound Ir-1, which is shown in the above-mentioned structural formula, were each independently energized, whereby a light emitting layer 3c formed of the host material H-1 and the phosphorescent light emitting compound Ir-1 was formed on a hole transport injection layer 3f. At this time, the energization of the heating boats was adjusted so that the deposition velocities became host material H-1:phosphorescent light emitting compound Ir-1=100:6. Furthermore, the layer thickness was set to 30 nm.

Subsequently, the heating boat containing therein BAlq, which is shown in the following structural formula, as a hole blocking material was heated by energization, whereby a hole blocking layer 3g formed of BAlq was formed on the light emitting layer 3c. At this time, the deposition velocity was 0.1 to 0.2 nm/sec, and the layer thickness was 10 nm.

Subsequently, the heating boat containing therein D-1, which is shown in the above-mentioned structural formula, as an electron transport material, and the heating boat containing therein potassium fluoride were each independently energized, whereby an electron transport layer 3d formed of D-1 and potassium fluoride was formed on the hole blocking layer 3g. At this time, the energization of the heating boats was adjusted so that the deposition velocities became D-1:potassium fluoride=75:25. Furthermore, the layer thickness was 30 nm.

Subsequently, the heating boat containing therein potassium fluoride as an electron injection material was heated by energization, whereby an electron injection layer 3e formed of potassium fluoride was formed on the electron transport layer 3d. At this time, the deposition velocity was 0.01 to 0.02 nm/sec, and the layer thickness was 1 nm.

Subsequently, the film substrate 4 on which the layers up to the electron injection layer 3e had been formed was transferred to a second vacuum bath to which a resistance heating boat made of tungsten containing aluminum (Al) therein had been attached, while the vacuum state was kept. The film substrate 4 was superposed with a mask having an opening of width 20 mm×50 mm, which was disposed so as to be orthogonal to the anode, and fixed. Subsequently, a reflective counter electrode 6 formed of Al having a layer thickness of 100 nm was formed as a cathode at a film formation velocity of 0.3 to 0.5 nm/sec in a treatment chamber.

Subsequently, the organic EL element 400 was covered with a sealing material 17 formed of a glass substrate having a size of 40×40 mm, a thickness of 700 μm and a center part of 34×34 mm and a depth 350 μm, and an adhesive 19 (sealant) was filled in between the sealing material 17 and the film substrate 4 in the state that the organic EL element 400 is surrounded. As the adhesive 19, an epoxy-based photocurable adhesive (Luxtrack LC0629B manufactured by Toagosei Co., Ltd.) was used. The adhesive 19 was cured by irradiating the adhesive 19 filled in between the sealing material 17 and the film substrate 4 with UV light from the side of the glass substrate (sealing material 17), whereby the organic EL element 400 was sealed.

In the formation of the organic EL element 400, a deposition mask was used for forming each layer, 2.0 cm×2.0 cm at the center on the film substrate 4 of 5 cm×5 cm was deemed as a light emitting area A, and a non-light emitting area B having a width of 1.5 cm was provided to the whole circumference of the light emitting area A. Furthermore, the transparent electrode 2 as an anode and the counter electrode 6 as a cathode were formed in the state that the electrodes were insulated by the light emitting unit 3 from the hole injection layer 3a to the electron injection layer 3e, in the form that the terminal parts had been drawn on the peripheral edge of the film substrate 4.

The organic EL element 400 was provided on the film substrate 4 as mentioned above in FIG. 7, whereby a light emitting panel 700 in which the organic EL element 400 was sealed with the sealing material 17 and the adhesive 19 (light emitting panel No. 1) was prepared.

### Light Emitting Panel No. 2

### Comparative Example

### (1) Preparation of Film Substrate and Gas Barrier Layer

With respect to light emitting panel No. 2, the preparation steps in the above-mentioned (1-1) to (1-3) were similarly conducted by using a similar film substrate to that of light emitting panel No. 1.

(1-4) Preparation of Second Gas Barrier Layer

A 10% by mass dibutyl ether solution of perhydropolysilazane (AQUAMIKA NN120-10, catalyst-free type, manufactured by AZ Electronic Materials) as an application liquid was applied by a wire bar so that the dried (average) layer thickness became 300 nm, dried by treating under an atmosphere at a temperature of 85° C. and a humidity of 55% RH for 1 minute, further retained under an atmosphere at a temperature of 25° C. and a humidity of 10% RH (dew point temperature −8° C.) for 10 minutes, and subjected to a dehumidication treatment, whereby a polysilazane layer was formed.

Subsequently, for the polysilazane layer formed as above, the following ultraviolet ray device was installed in a vacuum chamber, the pressure in the device was adjusted to the value shown in Table 1, and a silica-inversion treatment was conducted.

### <Ultraviolet Ray Irradiation Device>

Device: excimer irradiation MODEL manufactured by M. D. COM, Inc. MODEL: MECL-M-1-200

Irradiation wavelength: 172 nm

Gas enclosed in lamp: Xe

### <Conditions for Modification Treatment>

A modification treat was conducted on the substrate with the polysilazane layer formed thereon fixed on an operation stage, under the following conditions, whereby a second gas barrier layer was formed.

Excimer lamp light intensity: 130 mW/cm² (172 nm)

Distance between sample and light source: 1 mm

Stage heating temperature: 70° C.

Oxygen concentration in irradiation device: 1.0%

Excimer lamp irradiation time: 5 seconds

The compositions or distribution states of the respective constitutional elements of these first gas barrier layer and second gas barrier layer were different.

With respect to light emitting panel No. 2, a light emitting panel was prepared by conducting the steps of the above-mentioned (3) to (5) in similar manners to those for light emitting panel No. 1, without conducting the steps for preparing a light scattering layer in the above-mentioned (2) for light emitting panel No. 1.

### Light Emitting Panel No. 3

### Example

### (1) Preparation of Film Substrate and Gas Barrier Layer

With respect to light emitting panel No. 3, the treatments of (1-1) to (1-4) for light emitting panel No. 2 were similarly conducted by using a similar film substrate to that for light emitting panel No. 2.

### (2) Preparation of Light Scattering Layer and Smooth Layer

(2-1) Preparation of Light Scattering Layer

With respect to light emitting panel No. 3, the treatment of (2-1) was not conducted as in light emitting panel No. 2, and thus a light scattering layer was not prepared.

(2-2) Preparation of Smooth Layer

Subsequently, as a smooth layer preparation liquid, a resin solution (ED230AL (an organic-inorganic hybrid resin) manufactured by APM) was formulated and designed at a ratio of 10 ml amount so that the solvent ratio became 20% by mass/30% by mass/50% by mass of n-propylacetate, cyclohexanone and toluene, and the solid content concentration became 20% by mass.

Specifically, the resin was added in small portions under mixing while the solvent was stirred at 100 rpm, and after the addition was completed, the stirring velocity was increased to 500 rpm, and mixing was conducted for 10 minutes, whereby an application liquid for a smooth layer was obtained.

Subsequently, the application liquid was filtered by a hydrophobic PVDF 0.45 μm filter (manufactured by Whatman), whereby an intended dispersion liquid was obtained.

The above-mentioned dispersion liquid was applied under rotation by spin application (500 rpm, 30 seconds) on the light scattering layer, subjected to simplified drying (80° C., 2 minutes) and further heated (120° C., 30 minutes), whereby a smooth layer having a layer thickness of 0.7 μm was formed.

In addition, the average refractive index of the smooth layer was measured by irradiating the light with the shortest light emitting local maximum wavelength among the light emitting local maximum wavelengths of the light emitted from the light emitting unit under an atmosphere of 25° C. and using an Abbe refractive index meter (manufactured by ATAGO CO., LTD., DR-M2), and found to be 1.5.

Furthermore, the surface roughness (arithmetic average roughness Ra) was measured and found to be Ra=5 nm.

The surface roughness (arithmetic average roughness Ra) was calculated from an average roughness relating to the amplitude of the fine recess-projection by using an AFM (Atomic Force Microscope: manufactured by Digital Instruments), from a cross-sectional surface curve of the recess-projection which was continuously measured by a detector with a stylet having a quite small tip radius, by measuring three times in an area with a measurement direction of 30 μm by the stylet having a quite small tip radius. The surface roughness (arithmetic average roughness Ra) was obtained similarly in all of the following light emitting panels.

With respect to light emitting panel No. 3, a light emitting panel was prepared by conducting similar treatments to those in the above-mentioned (3) to (5) for light emitting panel No. 1.

### Light Emitting Panel No. 4

### Example

### (1) Preparation of Film Substrate and Gas Barrier Layer

With respect to light emitting panel No. 4, the preparation steps of (1-1) to (1-4) for light emitting panel No. 2 were similarly conducted by using a similar film substrate to that for light emitting panel No. 2.

### (2) Preparation of Light Scattering Layer and Smooth Layer

(2-1) Preparation of Light Scattering Layer

As a substrate, a substrate obtained by cutting the film substrate obtained in (1) into 50×50 mm, washing with ultrapure water and drying with a clean drier was used.

Subsequently, a light scattering layer preparation liquid was formulated and designed at a ratio of 10 ml amount so that the solid content ratio of TiO₂ particles having a refractive index (np) of 2.4 and an average particle diameter of 0.5 μm (JR600A manufactured by TAYCA CORPORATION) to a resin solution (ED230AL (an organic-inorganic hybrid resin) manufactured by APM) became 30 vol %/70 vol %, the solvent ratio of n-propylacetate to cyclohexanone became 10% by mass/90% by mass, and the solid content concentration became 9% by mass.

Specifically, the above-mentioned TiO₂ particles and solvent were mixed, and the mixture was dispersed in an ultrasonic dispersing machine (UH-50 manufactured by SMT CO., LTD.) under standard conditions of a microchip step (MS-3 manufactured by SMT CO., LTD., 3 mm in diameter) for 10 minutes while the mixture was cooled under an ordinary temperature, whereby a dispersion liquid of TiO₂ was prepared.

Subsequently, the resin was added in small portions under mixing while the TiO₂ dispersion liquid was stirred at 100 rpm, and after the addition was completed, the stirring velocity was increased to 500 rpm, and mixing was conducted for 10 minutes, whereby an application liquid for a light scattering layer was obtained.

Subsequently, the application liquid was filtered by a hydrophobic PVDF 0.75 μm filter (manufactured by Whatman), whereby an intended dispersion liquid was obtained.

The above-mentioned dispersion liquid was applied under rotation by spin application (500 rpm, 30 seconds) on the film substrate, subjected to simplified drying (80° C., 2 minutes) and further heated (120° C., 60 minutes), whereby a light scattering layer having a layer thickness of 0.3 μm was formed. The refractive index nb of the binder (resin) in the light scattering layer was 1.5, the particle refractive index np was 2.4, and the average refractive index ns was 1.77.

(2-2) Preparation of Smooth Layer

Subsequently, as a smooth layer preparation liquid, a resin solution (ED230AL (an organic-inorganic hybrid resin) manufactured by APM) was formulated and designed at a ratio of 10 ml amount so that the solvent ratio became 20% by mass/30% by mass/50% by mass of n-propylacetate, cyclohexanone and toluene, and the solid content concentration became 9% by mass.

Specifically, the resin was added in small portions under mixing while the solvent was stirred at 100 rpm, and after the addition was completed, the stirring velocity was increased to 500 rpm, and mixing was conducted for 10 minutes, whereby an application liquid for a smooth layer was obtained.

Subsequently, the application liquid was filtered by a hydrophobic PVDF 0.45 μm filter (manufactured by Whatman), whereby an intended dispersion liquid was obtained.

The above-mentioned dispersion liquid was applied under rotation by spin application (500 rpm, 30 seconds) on the light scattering layer, subjected to simplified drying (80° C., 2 minutes) and further heated (120° C., 30 minutes), whereby a smooth layer having a layer thickness of 0.3 μm was formed.

In addition, the average refractive index of the smooth layer was measured by irradiating the light with the shortest light emitting local maximum wavelength among the light emitting local maximum wavelengths of the light emitted from the light emitting unit under an atmosphere of 25° C. and using an Abbe refractive index meter (manufactured by ATAGO CO., LTD., DR-M2), and found to be 1.5.

Furthermore, the surface roughness (arithmetic average roughness Ra) was measured and found to be Ra=100 nm.

With respect to light emitting panel No. 4, a light emitting panel was prepared by conducting similarly to the preparation steps of the above-mentioned (3) to (5) for light emitting panel No. 1.

### Light Emitting Panel No. 5

### Example

### (1) Preparation of Film Substrate and Gas Barrier Layer

With respect to light emitting panel No. 5, the preparation steps of (1-1) to (1-4) for light emitting panel No. 2 were similarly conducted by using a similar film substrate to that for light emitting panel No. 2.

### (2) Preparation of Light Scattering Layer and Smooth Layer

(2-1) Preparation of Light Scattering Layer

With respect to light emitting panel No. 5, a light scattering layer having a layer thickness of 0.5 μm was formed by conducting treatments of (2-1) similarly to those for light emitting panel No. 1. The binder (resin) in the light scattering layer had a refractive index nb of 1.5, a particle refractive index np of 2.4, and an average refractive index ns of 1.77.

(2-2) Preparation of Smooth Layer

With respect to light emitting panel No. 5, a smooth layer having a layer thickness of 0.7 μm was formed by conducting the treatments of (2-2) similarly to those for light emitting panel No. 3.

In addition, the average refractive index of of the smooth layer was measured by irradiating the light with the shortest light emitting local maximum wavelength among the light emitting local maximum wavelengths of the light emitted from the light emitting unit under an atmosphere of 25° C. and using an Abbe refractive index meter (manufactured by ATAGO CO., LTD., DR-M2), and found to be 1.5.

Furthermore, the surface roughness (arithmetic average roughness Ra) was measured and found to be Ra=5 nm.

With respect to light emitting panel No. 5, a light emitting panel was prepared by conducting similarly to the preparation steps of the above-mentioned (3) to (5) for light emitting panel No. 1.

### Light Emitting Panel No. 6

### Example

### (1) Preparation of Film Substrate and Gas Barrier Layer

With respect to light emitting panel No. 6, the preparation steps of (1-1) to (1-4) for light emitting panel No. 2 were similarly conducted by using a similar film substrate to that for light emitting panel No. 2.

### (2) Preparation of Light Scattering Layer and Smooth Layer

(2-1) Preparation of Light Scattering Layer

As a substrate, a substrate obtained by cutting the film substrate obtained in (1) into 50×50 mm, washing with ultrapure water and drying with a clean drier was used.

Subsequently, a light scattering layer preparation liquid was formulated and designed at a ratio of 10 ml amount by adding a solution that was adjusted to have a solid content ratio of a nano TiO₂dispersion liquid having an average particle diameter of 0.02 μm (HDT-760T manufactured by TAYCA CORPORATION) to a resin solution (ED230AL (an organic-inorganic hybrid resin) manufactured by APM) of 34 vol %/66 vol %, SiO₂ particles having a refractive index of 1.5 and an average particle diameter of 0.1 μm (Sciqas manufactured by Sakai Chemical Industry Co., Ltd.) and a resin solution (ED230AL (an organic-inorganic hybrid resin) manufactured by APM), so that the solid content ratio became 10 vol %/90 vol %, the solvent ratio of n-propylacetate to cyclohexanone became 10% by mass/90% by mass, and the solid content concentration became 15% by mass.

Specifically, the above-mentioned TiO₂ particles and solvent were mixed, and the mixture was dispersed in an ultrasonic dispersing machine (UH-50 manufactured by SMT CO., LTD.) under standard conditions of a microchip step (MS-3 manufactured by SMT CO., LTD., 3 mm in diameter) for 10 minutes while the mixture was cooled under an ordinary temperature, whereby a dispersion liquid of TiO₂ was prepared.

Subsequently, the above-mentioned resin solution was added in small portions under mixing while the TiO₂ dispersion liquid was stirred at 100 rpm, and after the addition was completed, the stirring velocity was increased to 500 rpm, and mixing was conducted for 10 minutes, whereby an application liquid for a light scattering layer was obtained.

Subsequently, the application liquid was filtered by a hydrophobic PVDF 0.45 μm filter (manufactured by Whatman), whereby an intended dispersion liquid was obtained.

The above-mentioned dispersion liquid was applied under rotation by spin application (500 rpm, 30 seconds) on the film substrate, subjected to simplified drying (80° C., 2 minutes) and further heated (120° C., 60 minutes), whereby a light scattering layer having a layer thickness of 0.5 μm was formed. The refractive index nb of the binder (resin) in the light scattering layer was 1.8, the particle refractive index np was 1.5, and the average refractive index ns was 1.77.

(2-2) Preparation of Smooth Layer

Subsequently, a smooth layer preparation liquid was formulated and designed at a ratio of 10 ml amount so that the solid content ratio of a nano TiO₂ dispersion liquid having an average particle diameter of 0.02 μm (HDT-760T manufactured by TAYCA CORPORATION) to a resin solution (ED230AL (an organic-inorganic hybrid resin) manufactured by APM) became 39 vol %/61 vol %, the solvent ratio of n-propylacetate, cyclohexanone and toluene became 20% by mass/30% by mass/50% by mass, and the solid content concentration became 20% by mass.

Specifically, the above-mentioned nano TiO₂ dispersion liquid and the solvent was mixed, the resin was added in small portions under mixing while the mixture was stirred at 100 rpm, and after the addition was completed, the stirring velocity was increased to 500 rpm, and mixing was conducted for 10 minutes, whereby an application liquid for a smooth layer was obtained.

Subsequently, the application liquid was filtered by a hydrophobic PVDF 0.45 μm filter (manufactured by Whatman), whereby an intended dispersion liquid was obtained.

The above-mentioned dispersion liquid was applied under rotation by spin application (500 rpm, 30 seconds) on the light scattering layer, subjected to simplified drying (80° C., 2 minutes) and further heated (120° C., 30 minutes), whereby a smooth layer having a layer thickness of 0.7 μm was formed.

In addition, the refractive index of the smooth layer was measured by irradiating the light with the shortest light emitting local maximum wavelength among the light emitting local maximum wavelengths of the light emitted from the light emitting unit under an atmosphere of 25° C. and using an Abbe refractive index meter (manufactured by ATAGO CO., LTD., DR-M2), and found to be 1.85.

Furthermore, the surface roughness (arithmetic average roughness Ra) was measured and found to be Ra=5 nm.

With respect to light emitting panel No. 6, a light emitting panel was prepared by conducting similarly to the steps of the above-mentioned (3) to (5) for light emitting panel No. 1.

### Light Emitting Panel No. 7

### Example

### (1) Preparation of Film Substrate and Gas Barrier Layer

With respect to light emitting panel No. 7, the treatments of (1-1) to (1-4) for light emitting panel No. 2 were similarly conducted by using a similar film substrate to that for light emitting panel No. 2.

### (2) Preparation of Light Scattering Layer and Smooth Layer

(2-1) Preparation of Light Scattering Layer

As a substrate, a substrate obtained by cutting the film substrate obtained in (1) into 50×50 mm, washing with ultrapure water and drying with a clean drier was used.

Subsequently, a light scattering layer preparation liquid was formulated and designed at a ratio of 10 ml amount by adding a solution that was adjusted to have a solid content ratio of a nano TiO₂dispersion liquid having an average particle diameter of 0.02 μm (HDT-760T manufactured by TAYCA CORPORATION) to a resin solution (ED230AL (an organic-inorganic hybrid resin) manufactured by APM) of 22 vol %/78 vol %, TiO₂ particles having a refractive index (np) of 2.4 and an average particle diameter of 0.25 μm (JR600A manufactured by TAYCA CORPORATION) and a resin solution (ED230AL (an organic-inorganic hybrid resin) manufactured by APM), so that the solid content ratio became 10 vol %/90 vol %, the solvent ratio of n-propylacetate to cyclohexanone became 10% by mass/90% by mass, and the solid content concentration became 15% by mass.

Specifically, the above-mentioned TiO₂ particles and solvent were mixed, and the mixture was dispersed in an ultrasonic dispersing machine (UH-50 manufactured by SMT CO., LTD.) under standard conditions of a microchip step (MS-3 manufactured by SMT CO., LTD., 3 mm in diameter) for 10 minutes while the mixture was cooled under an ordinary temperature, whereby a dispersion liquid of TiO₂ was prepared.

Subsequently, the resin was added in small portions under mixing while the TiO₂ dispersion liquid was stirred at 100 rpm, and after the addition was completed, the stirring velocity was increased to 500 rpm, and mixing was conducted for 10 minutes, whereby an application liquid for a light scattering layer was obtained.

Subsequently, the application liquid was filtered by a hydrophobic PVDF 0.45 μm filter (manufactured by Whatman), whereby an intended dispersion liquid was obtained.

The above-mentioned dispersion liquid was applied under rotation by spin application (500 rpm, 30 seconds) on the film substrate, subjected to simplified drying (80° C., 2 minutes) and further heated (120° C., 60 minutes), whereby a light scattering layer having a layer thickness of 0.5 μm was formed. The refractive index nb of the binder (resin) in the light scattering layer was 1.7, the particle refractive index np was 2.4, and the average refractive index ns was 1.77.

(2-2) Preparation of Smooth Layer

With respect to light emitting panel No. 7, a smooth layer having a layer thickness of 0.7 μm was formed by conducting similarly to the steps of the above-mentioned (2-2) for light emitting panel No. 6.

In addition, the refractive index of the smooth layer was measured by irradiating the light with the shortest light emitting local maximum wavelength among the light emitting local maximum wavelengths of the light emitted from the light emitting unit under an atmosphere of 25° C. and using an Abbe refractive index meter (manufactured by ATAGO CO., LTD., DR-M2), and found to be 1.85.

Furthermore, the surface roughness (arithmetic average roughness Ra) was measured and found to be Ra=5 nm.

With respect to light emitting panel No. 7, a light emitting panel was prepared by conducting similarly to the steps of the above-mentioned (3) to (5) for light emitting panel No. 1.

### Light Emitting Panel No. 8

### Example

### (1) Preparation of Film Substrate and Gas Barrier Layer

With respect to light emitting panel No. 8, the preparation steps of (1-1) to (1-4) for light emitting panel No. 2 were similarly conducted by using a similar film substrate to that for light emitting panel No. 2.

### (2) Preparation of Light Scattering Layer and Smooth Layer

(2-1) Preparation of Light Scattering Layer

With respect to light emitting panel No. 8, a light scattering layer having a layer thickness of 0.5 μm was formed by conducting the preparation steps in (2-1) similarly to those for light emitting panel No. 1. The binder (resin) in the light scattering layer had a refractive index nb of 1.5, a particle refractive index np of 2.4 and an average refractive index ns of 1.77.

(2-2) Preparation of Smooth Layer

With respect to light emitting panel No. 8, a smooth layer having a layer thickness of 0.7 μm was formed by conducting similarly to the preparation steps of the above-mentioned (2-2) for light emitting panel No. 6.

In addition, the refractive index of the smooth layer was measured by irradiating the light with the shortest light emitting local maximum wavelength among the light emitting local maximum wavelengths of the light emitted from the light emitting unit under an atmosphere of 25° C. and using an Abbe refractive index meter (manufactured by ATAGO CO., LTD., DR-M2), and found to be 1.85.

Furthermore, the surface roughness (arithmetic average roughness Ra) was measured and found to be Ra=5 nm.

With respect to light emitting panel No. 8, a light emitting panel was prepared by conducting similar steps to those in the above-mentioned (3) to (5) for light emitting panel No. 1.

### Light Emitting Panel No. 9

### Example

### (1) Preparation of Film Substrate and Gas Barrier Layer

With respect to light emitting panel No. 9, the preparation step of (1-1) to (1-4) for light emitting panel No. 2 were similarly conducted by using a similar film substrate to that for light emitting panel No. 2.

### (2) Preparation of Light Scattering Layer and Smooth Layer

(2-1) Preparation of Light Scattering Layer

With respect to light emitting panel No. 9, a light scattering layer having a layer thickness of 0.5 μm was formed by conducting a similar preparation step to that of (2-1) for light emitting panel No. 1. The binder (resin) in the light scattering layer had a refractive index nb of 1.5, a particle refractive index np of 2.4, and an average refractive index ns of 1.77.

(2-2) Preparation of Smooth Layer

With respect to light emitting panel No. 9, a smooth layer having a layer thickness of 0.7 μm was formed by conducting a similar preparation step to that in the above-mentioned (2-2) for light emitting panel No. 6.

In addition, the refractive index of the smooth layer was measured by irradiating the light with the shortest light emitting local maximum wavelength among the light emitting local maximum wavelengths of the light emitted from the light emitting unit under an atmosphere of 25° C. and using an Abbe refractive index meter (manufactured by ATAGO CO., LTD., DR-M2), and found to be 1.85.

Furthermore, the surface roughness (arithmetic average roughness Ra) was measured and found to be Ra=5 nm.

With respect to light emitting panel No. 9, a light emitting panel was prepared by conducting similar steps to those in the above-mentioned (3) to (5) for light emitting panel No. 1.

### Light emitting panel No. 10

### Example

### (1) Preparation of Film Substrate and Gas Barrier Layer

With respect to light emitting panel No. 10, the preparation steps of (1-1) to (1-4) for light emitting panel No. 2 were similarly conducted by using a similar film substrate to that for light emitting panel No. 2.

### (2) Preparation of Light Scattering Layer and Smooth Layer

(2-1) Preparation of light scattering layer

As a substrate, a substrate obtained by cutting the film substrate obtained in (1) into 50×50 mm, washing with ultrapure water and drying with a clean drier was used.

Subsequently, a light scattering layer preparation liquid was formulated and designed at a ratio of 10 ml amount so that the solid content ratio of TiO₂ particles having a refractive index (np) of 2.4 and an average particle diameter of 0.5 μm (JR600A manufactured by TAYCA CORPORATION) to a resin solution (ED230AL (an organic-inorganic hybrid resin) manufactured by APM) became 30 vol %/70 vol %, the solvent ratio of n-propylacetate to cyclohexanone became 10% by mass/90% by mass, and the solid content concentration became 15% by mass.

Specifically, the above-mentioned TiO₂ particles and solvent were mixed, and the mixture was dispersed in an ultrasonic dispersing machine (UH-50 manufactured by SMT CO., LTD.) under standard conditions of a microchip step (MS-3 manufactured by SMT CO., LTD., 3 min diameter) for 10 minutes, while the mixture was cooled under an ordinary temperature, whereby a dispersion liquid of TiO₂ was prepared.

Subsequently, the resin was added in small portions under mixing while the TiO₂ dispersion liquid was stirred at 100 rpm, and after the addition was completed, the stirring velocity was increased to 500 rpm, and mixing was conducted for 10 minutes, whereby an application liquid for a light scattering layer was obtained.

Subsequently, the application liquid was filtered by a hydrophobic PVDF 0.45 μm filter (manufactured by Whatman), whereby an intended dispersion liquid was obtained.

The above-mentioned dispersion liquid was applied under rotation by spin application (1,500 rpm, 30 seconds) on the film substrate, subjected to simplified drying (80° C., 2 minutes) and further heated (120° C., 60 minutes), whereby a light scattering layer having a layer thickness of 0.3 μm was formed. The refractive index nb of the binder (resin) in the light scattering layer was 1.5, the particle refractive index np was 2.4, and the average refractive index ns was 1.77.

(2-2) Preparation of Smooth Layer

With respect to light emitting panel No. 10, a smooth layer was formed so that the layer thickness shown in Table 1 became 0.7 μm and the surface roughness (arithmetic average roughness Ra) became Ra=50 nm, by conducting similar treatments to those in (2-2) for light emitting panel No. 3.

In addition, the average refractive index of the smooth layer was measured by irradiating the light with the shortest light emitting local maximum wavelength among the light emitting local maximum wavelengths of the light emitted from the light emitting unit under an atmosphere of 25° C. and using an Abbe refractive index meter (manufactured by ATAGO CO., LTD., DR-M2), and found to be 1.5.

With respect to light emitting panel No. 10, a light emitting panel was prepared by conducting similarly to the preparation steps of (3) to (5) for light emitting panel No. 1.

### Light emitting panel No. 11

### (1) Preparation of Film Substrate and Gas Barrier Layer

With respect to light emitting panel No. 11, the preparation steps of (1-1) to (1-4) for light emitting panel No. 2 were similarly conducted by using a similar film substrate to that for light emitting panel No. 2.

### (2) Preparation of Light Scattering Layer and Smooth Layer

(2-1) Preparation of Light Scattering Layer

With respect to light emitting panel No. 11, a light scattering layer having a layer thickness of 0.5 μm was formed by conducting the treatments of (2-1) similarly to those for light emitting panel No. 1. The binder (resin) in the light scattering layer had a refractive index nb of 1.5, a particle refractive index np of 2.4 and an average refractive index ns of 1.77.

(2-2) Preparation of Smooth Layer

Subsequently, a smooth layer preparation liquid was formulated and designed at a ratio of 10 ml amount so that the solid content ratio of a zirconia sol having an average particle diameter of 0.02 μm (OZ-S30M manufactured by Nissan Chemical Industries, Ltd.) to a resin solution (ED230AL (an organic-inorganic hybrid resin) manufactured by APM) became 30 vol %/70 vol %, the solvent ratio of n-propylacetate, cyclohexanone and toluene became 20% by mass/30% by mass/50% by mass, and the solid content concentration became 20% by mass.

Specifically, the above-mentioned nano TiO₂ dispersion liquid and solvent were mixed, the resin was added in small portions under mixing while the TiO₂ dispersion liquid was stirred at 100 rpm, and after the addition was completed, the stirring velocity was increased to 500 rpm, and mixing was conducted for 10 minutes, whereby an application liquid for a smooth layer was obtained.

Subsequently, the application liquid was filtered by a hydrophobic PVDF 0.45 μm filter (manufactured by Whatman), whereby an intended dispersion liquid was obtained.

The above-mentioned dispersion liquid was applied under rotation by spin application (500 rpm, 30 seconds) on the light scattering layer, subjected to simplified drying (80° C., 2 minutes) and further heated (120° C., 30 minutes), whereby a smooth layer having a layer thickness of 0.7 μm was formed.

In addition, the average refractive index of the smooth layer was measured by irradiating the light with the shortest light emitting local maximum wavelength among the light emitting local maximum wavelengths of the light emitted from the light emitting unit under an atmosphere of 25° C. and using an Abbe refractive index meter (manufactured by ATAGO CO., LTD., DR-M2), and found to be 1.65.

Furthermore, the surface roughness (arithmetic average roughness Ra) was measured and found to be Ra=5 nm.

With respect to light emitting panel No. 11, a light emitting panel was prepared by conducting similarly to the preparation steps of (3) to (5) for light emitting panel No. 1.

### Light Emitting Panel No. 12

### (1) Preparation of Film Substrate and Gas Barrier Layer

With respect to light emitting panel No. 12, the treatments of (1-1) to (1-4) for light emitting panel No. 2 were similarly conducted by using a similar film substrate to that for light emitting panel No. 2.

### (2) Preparation of Light Scattering Layer and Smooth Layer

(2-1) Preparation of Light Scattering Layer

As a substrate, a substrate obtained by cutting the film substrate obtained in (1) into 50×50 mm, washing with ultrapure water and drying with a clean drier was used.

Subsequently, a light scattering layer preparation liquid was formulated and designed at a ratio of 10 ml amount so that the solvent ratio of a solution that was adjusted so that the solid content ratio of magnesium oxide particles having a refractive index (np) of 1.7 and an average particle diameter of 0.1 μm (SMO series manufactured by Sakai Chemical Industry Co., Ltd.) to a resin solution (ED230AL (an organic-inorganic hybrid resin) manufactured by APM) became 30 vol %/70 vol % to n-propylacetate and cyclohexanone became 10% by mass/90% by mass, and the solid content concentration became 15% by mass.

Specifically, the above-mentioned TiO₂ particles and solvent were mixed, and the mixture was dispersed in an ultrasonic dispersing machine (UH-50 manufactured by SMT CO., LTD.) under standard conditions of a microchip step (MS-3 manufactured by SMT CO., LTD., 3 mm in diameter) for 10 minutes while the mixture was cooled under an ordinary temperature, whereby a dispersion liquid of TiO₂ was prepared.

Subsequently, the resin was added in small portions under mixing while the TiO₂ dispersion liquid was stirred at 100 rpm, and after the addition was completed, the stirring velocity was increased to 500 rpm, and mixing was conducted for 10 minutes, whereby an application liquid for a light scattering layer was obtained.

Subsequently, the application liquid was filtered by a hydrophobic PVDF 0.45 μm filter (manufactured by Whatman), whereby an intended dispersion liquid was obtained.

The above-mentioned dispersion liquid was applied under rotation by spin application (500 rpm, 30 seconds) on the film substrate, subjected to simplified drying (80° C., 2 minutes) and further heated (120° C., 60 minutes), whereby a light scattering layer having a layer thickness of 0.5 μm was formed. The refractive index nb of the binder (resin) in the light scattering layer was 1.5, the particle refractive index np was 1.7, and the average refractive index ns was 1.56.

(2-2) Preparation of Smooth Layer

With respect to light emitting panel No. 12, a smooth layer having a layer thickness of 0.7 μm was formed by conducting similarly to the steps of the above-mentioned (2-2) for light emitting panel No. 6.

In addition, the refractive index of the smooth layer was measured by irradiating the light with the shortest light emitting local maximum wavelength among the light emitting local maximum wavelengths of the light emitted from the light emitting unit under an atmosphere of 25° C. and using an Abbe refractive index meter (manufactured by ATAGO CO., LTD., DR-M2), and found to be 1.85.

Furthermore, the surface roughness (arithmetic average roughness Ra) was measured and found to be Ra=5 nm.

With respect to light emitting panel No. 12, a light emitting panel was prepared by conducting similarly to the steps of the above-mentioned (3) to (5) for light emitting panel No. 1.

### Light Emitting Panel No. 13

### (1) Preparation of Film Substrate and Gas Barrier Layer

With respect to light emitting panel No. 13, the treatments of (1-1) to (1-4) for light emitting panel No. 2 were similarly conducted by using a similar film substrate to that for light emitting panel No. 2.

### (2) Preparation of Light Scattering Layer and Smooth Layer

(2-1) Preparation of Light Scattering Layer

As a substrate, a substrate obtained by cutting the film substrate obtained in (1) into 50×50 mm, washing with ultrapure water and drying with a clean drier was used.

Subsequently, a light scattering layer preparation liquid was formulated and designed at a ratio of 10 ml amount so that the solvent ratio of a solution that was adjusted to have a solid content ratio of magnesium oxide particles having a refractive index (np) of 1.7 and an average particle diameter of 0.1 μm (SMO series manufactured by Sakai Chemical Industry Co., Ltd.) to a resin solution (ED230AL (an organic-inorganic hybrid resin) manufactured by APM) became 50 vol %/50 vol % to n-propylacetate and cyclohexanone became 10% by mass/90% by mass, and the solid content concentration became 15% by mass.

Specifically, the above-mentioned TiO₂ particles and solvent were mixed, and the mixture was dispersed in an ultrasonic dispersing machine (UH-50 manufactured by SMT CO., LTD.) under standard conditions of a microchip step (MS-3 manufactured by SMT CO., LTD., 3 mm in diameter) for 10 minutes while the mixture was cooled under an ordinary temperature, whereby a dispersion liquid of TiO₂ was prepared.

Subsequently, the resin was added in small portions under mixing while the TiO₂ dispersion liquid was stirred at 100 rpm, and after the addition was completed, the stirring velocity was increased to 500 rpm, and mixing was conducted for 10 minutes, whereby an application liquid for a light scattering layer was obtained.

Subsequently, the application liquid was filtered by a hydrophobic PVDF 0.45 μm filter (manufactured by Whatman), whereby an intended dispersion liquid was obtained.

The above-mentioned dispersion liquid was applied under rotation by spin application (500 rpm, 30 seconds) on the film substrate, subjected to simplified drying (80° C., 2 minutes) and further heated (120° C., 60 minutes), whereby a light scattering layer having a layer thickness of 0.5 μm was formed. The refractive index nb of the binder (resin) in the light scattering layer was 1.5, the particle refractive index np was 1.7, and the average refractive index ns was 1.6.

(2-2) Preparation of Smooth Layer

With respect to light emitting panel No. 13, a smooth layer having a layer thickness of 0.7 μm was formed by conducting similarly to the steps of the above-mentioned (2-2) for light emitting panel No. 6.

In addition, the refractive index of the smooth layer was measured by irradiating the light with the shortest light emitting local maximum wavelength among the light emitting local maximum wavelengths of the light emitted from the light emitting unit under an atmosphere of 25° C. and using an Abbe refractive index meter (manufactured by ATAGO CO., LTD., DR-M2), and found to be 1.85.

Furthermore, the surface roughness (arithmetic average roughness Ra) was measured and found to be Ra=5 nm.

With respect to light emitting panel No. 13, a light emitting panel was prepared by conducting similar steps to those in the above-mentioned (3) to (5) for light emitting panel No. 1.

TABLE 1

| | Smooth layer | | | | | | | | | | | |
|---|---|---|---|---|---|---|---|---|---|---|---|---|
| | | Arith- | | | Light scatting layer | | | | | | | |
| | Aver- | metic | | | | | Aver- | Differ- | | | | |
| | age | average | | | Binder | Particle | age | ence | | | | |
| Light | refrac- | rough- | | Layer | refrac- | refrac- | refrac- | in | Particle | Layer | Total | |
| emitting | tive | ness | | thick- | tive | tive | tive | refractive | diam- | thick- | thick- | |
| panel | index | Ra | | ness | index | index | index | indices | eter | ness | ness | |
| No. | nf | [nm] | Particles | [nm] | nb | np | ns | \| nb − np \| | [nm] | [nm] | [nm] | Notes |
| 1 | — | — | — | 0 | 1.5 | 2.4 | 1.77 | 0.9 | 250 | 500 | 500 | Comparative |
| | | | | | | | | | | | | Example |
| 2 | — | — | — | 0 | — | — | — | — | — | 0 | 0 | Comparative |
| | | | | | | | | | | | | Example |
| 3 | 1.50 | 5 | — | 700 | — | — | — | — | — | 0 | 700 | Example |
| 4 | 1.50 | 100 | — | 300 | 1.5 | 2.4 | 1.77 | 0.9 | 500 | 300 | 600 | Example |
| 5 | 1.50 | 5 | — | 700 | 1.5 | 2.4 | 1.77 | 0.9 | 250 | 500 | 1200 | Example |
| 6 | 1.85 | 5 | TiO₂ | 700 | 1.8 | 1.5 | 1.77 | 0.3 | 100 | 500 | 1200 | Example |
| 7 | 1.85 | 5 | TiO₂ | 700 | 1.7 | 2.4 | 1.77 | 0.7 | 250 | 500 | 1200 | Example |
| 8 | 1.85 | 5 | TiO₂ | 700 | 1.5 | 2.4 | 1.77 | 0.9 | 250 | 500 | 1200 | Example |
| 9 | 1.85 | 5 | TiO₂ | 700 | 1.5 | 2.4 | 1.77 | 0.9 | 250 | 500 | 1200 | Example |
| 10 | 1.50 | 50 | — | 700 | 1.5 | 2.4 | 1.77 | 0.9 | 500 | 300 | 1000 | Example |
| 11 | 1.65 | 5 | ZrO₂ | 700 | 1.5 | 2.4 | 1.77 | 0.9 | 250 | 500 | 1200 | Example |
| 12 | 1.85 | 5 | TiO₂ | 700 | 1.5 | 1.7 | 1.56 | 0.2 | 100 | 500 | 1200 | Example |
| 13 | 1.85 | 5 | TiO₂ | 700 | 1.5 | 1.7 | 1.60 | 0.2 | 100 | 500 | 1200 | Example |

### Example 2

### (6) Evaluations

The following evaluations were conducted by using the obtained light emitting panels (lighting devices) Nos. 1 to 13.

(6-1) Total Luminous Flux

A luminous flux at a predetermined electrical current was measured by using an integrating sphere. Specifically, a total luminous flux was measured at a constant electrical current density of 20 A/m², and a relative value with respect to light emitting panel No. 2 was shown in Table 2.

(6-2) Storage Property Test Under High Temperature-High Humidity Atmosphere

The obtained light emitting panels Nos. 1 to 13 were each stored under an atmosphere at a temperature of 60° C./a relative humidity of 90% RH, and the light emitting state was observed. Specifically, the progress of the decrease of the light emitting surface area (shrink) after 500 hours compared to the light emitting surface area before the initiation of the test was observed, and the result was shown in Table 2. The case when 100 μm or more of the end part of the light emitting surface area shrank was deemed that shrinking was present, and the case when the shrinking was less than that value was deemed that shrinking was absent.

(6-3) Energization Test

For the obtained light emitting panels No. 1 to 13, each light emitting panel was driven at a predetermined electrical current (100 A/m²) by using five panels for each light emitting panel, and a continuous energization test was conducted. The number of the light emitting panels that were put into short-circuit before the initial luminance was decreased to half was shown in Table 2.

TABLE 2

| | | Storage | | |
|---|---|---|---|---|
| Light | Total luminous | property | Number of short- | |
| emitting | flux (relative | test (presence | circuit during | |
| panel | value for | or absence of | energization test | |
| No. | No. 2) | shrinkage) | (over 5 times) | Notes |
| 1 | 1.10 | absence | 4 | Compar- |
| | | | | ative |
| | | | | Example |
| 2 | 1.00 | absence | 2 | Compar- |
| | | | | ative |
| | | | | Example |
| 3 | 0.94 | absence | 0 | Example |
| 4 | 1.18 | absence | 1 | Example |
| 5 | 1.22 | absence | 0 | Example |
| 6 | 1.60 | absence | 0 | Example |
| 7 | 1.65 | absence | 0 | Example |
| 8 | 1.70 | absence | 0 | Example |
| 9 | 1.70 | absence | 0 | Example |
| 10 | 1.20 | absence | 0 | Example |
| 11 | 1.44 | absence | 0 | Example |
| 12 | 1.48 | absence | 0 | Example |
| 13 | 1.52 | absence | 0 | Example |

As is understood from Table 2, it was found that light emitting panel No. 3, which is an Example of the present invention, had a lower ratio of short-circuit as compared to those of light emitting panels Nos. 1 and 2, which are Comparative Examples. Furthermore, it was found that the respective light emitting panels including light emitting panels Nos. 4 to 13, which are Examples of the present invention, were superior to Comparative Examples in all of the total luminous flux and energization test. Furthermore, no shrinkage was seen in all of light emitting panels Nos. 1 to 13 in the storage property tests under a high temperature-high humidity atmosphere. Therefore, it was found that the light emitting panels of Examples were preferable for use as light emitting panels.

### INDUSTRIAL APPLICABILITY

According to the organic electroluminescent element of the present invention, an organic EL element that has a light emitting efficiency improved by suppressing the deterioration of storage property under a high temperature-high humidity atmosphere due to the recess-projection state of a surface of a gas barrier layer or a light scattering layer, or the like that is in contact with a light emitting unit, and the occurrence of a short-circuit can be obtained, and the organic EL element can be preferably utilized as a display device, a display, a household lighting, an in-car lighting, a backlight for a clock or a liquid crystal, a light source for signboard advertisement, a traffic light or an optical memory medium, a light source for an electrophotographic copying machine, a light source for an optical communication processor, a light source for a light sensor, or as wide variety of light sources for general household electric instruments that require display devices.

### REFERENCE SIGNS LIST

100, 400 Organic electroluminescent element (organic EL element)
1 Smooth layer
2 Anode (transparent electrode)
2a Primer layer
2b Electrode layer
3 Light emitting unit
4 Film substrate
5 Gas barrier layer
6 Cathode (counter electrode)
7 Light scattering layer
700 Lighting device (light emitting panel)

1. An organic electroluminescent element, comprising a film substrate, and at least, a gas barrier layer, a smooth layer, and a light emitting unit that is sandwiched between a pair of electrodes and has an organic functional layer, which are stacked in this order on the film substrate, wherein the gas barrier layer is constituted by at least two kinds of gas barrier layers that are different from each other in the composition or distribution state of the constitutional elements.

2. The organic electroluminescent element according to claim 1, wherein the surface on the side of the light emitting unit of the smooth layer has an arithmetic average roughness Ra in the range of from 0.5 to 50 nm.

3. The organic electroluminescent element according to claim 1, which has a light scattering layer between the gas barrier layer and the smooth layer.

4. The organic electroluminescent element according to claim 1, wherein the average refractive index of the smooth layer is 1.65 or more at the shortest light emitting local maximum wavelength among the light emitting local maximum wavelengths of the light emitted from the light emitting unit.

5. The organic electroluminescent element according to claim 1, wherein the smooth layer contains titanium dioxide.

6. The organic electroluminescent element according to claim 3, wherein the average refractive index of the light scattering layer is 1.6 or more at the shortest light emitting local maximum wavelength among the light emitting local maximum wavelengths of the light emitted from the light emitting unit.

7. The organic electroluminescent element according to claim 3, wherein the light scattering layer contains a binder that has a refractive index of 1.6 or less and inorganic particles that have a refractive index of 1.8 or more, at the shortest light emitting local maximum wavelength among the light emitting local maximum wavelengths of the light emitted from the light emitting unit.

8. The organic electroluminescent element according to claim 1, wherein one kind of gas barrier layer of the at least two kinds of gas barrier layers contains silicon dioxide that is a reaction product of an inorganic silicon compound.

9. The organic electroluminescent element according to claim 1, wherein either gas barrier layer of the at least two kinds of gas barrier layer contains a reaction product of an organic silicon compound.

10. A lighting device comprising the organic electroluminescent element according to claim 1.

11. The organic electroluminescent element according to claim 2, which has a light scattering layer between the gas barrier layer and the smooth layer.

12. The organic electroluminescent element according to claim 2, wherein the average refractive index of the smooth layer is 1.65 or more at the shortest light emitting local maximum wavelength among the light emitting local maximum wavelengths of the light emitted from the light emitting unit.

13. The organic electroluminescent element according to claim 2, wherein the smooth layer contains titanium dioxide.

14. The organic electroluminescent element according to claim 2, wherein one kind of gas barrier layer of the at least two kinds of gas barrier layers contains silicon dioxide that is a reaction product of an inorganic silicon compound.

15. The organic electroluminescent element according to claim 2, wherein either gas barrier layer of the at least two kinds of gas barrier layer contains a reaction product of an organic silicon compound.

16. A lighting device comprising the organic electroluminescent element according to claim 2.

17. The organic electroluminescent element according to claim 3, wherein the average refractive index of the smooth layer is 1.65 or more at the shortest light emitting local maximum wavelength among the light emitting local maximum wavelengths of the light emitted from the light emitting unit.

18. The organic electroluminescent element according to claim 3, wherein the smooth layer contains titanium dioxide.

19. The organic electroluminescent element according to claim 3, wherein one kind of gas barrier layer of the at least two kinds of gas barrier layers contains silicon dioxide that is a reaction product of an inorganic silicon compound.

20. The organic electroluminescent element according to claim 3, wherein either gas barrier layer of the at least two kinds of gas barrier layer contains a reaction product of an organic silicon compound.
